(19) United States
(12) Patent Application Publication
(10) Pub. No.: US 2011/0189618 A1
(43) Pub. Date: Aug. 4, 2011

(54) RESIST PROCESSING METHOD

(75) Inventors: Mitsuhiro Hata, Delmar, NY (US); Nobuo Ando, Osaka (JP); Satoshi Yamamoto, Hyogo (JP); Junji Shigematsu, Osaka (JP); Akira Kamabuchi, Hyogo (JP)

(73) Assignee: SUMITOMO CHEMICAL COMPANY, LIMITED, Tokyo (JP)

(21) Appl. No.: 13/062,180

(22) PCT Filed: Sep. 1, 2009
(86) PCT No.: PCT/JP2009/065272

§ 371 Date: Apr. 7, 2011

(30) Foreign Application Priority Data
Sep. 5, 2008 (JP) 2008-227817

(51) Int. Cl. G03F 7/20

(52) U.S. Cl. 430/325

(57) ABSTRACT

A resist processing method comprises the steps of: (1) forming a first resist film by applying a first resist composition comprising: a resin (A) having an acid-labile group, being insoluble or poorly soluble in alkali aqueous solution, and being rendered soluble in alkali aqueous solution through the action of an acid, a photo acid generator (B), a cross-linking agent (C) and an acid amplifier (D) onto a substrate and drying; (2) prebaking the first resist film; (3) exposing to the first resist film; (4) post-exposure baking of the first resist film; (5) developing with a first alkali developer to obtain a first resist pattern; (6) hard-baking the first resist pattern, (7) obtaining a second resist film by applying a second resist composition onto the first resist pattern, and drying; (8) pre-baking the second resist film; (9) exposing the second resist film; (10) post-exposure baking the second resist film; and (11) developing with a second alkali developer to obtain a second resist pattern.

### TECHNICAL FIELD

The present invention relates to a resist processing method, and in particular, relates to a resist processing method used in the formation of a micro resist pattern through a double patterning method or a double imaging method.

### BACKGROUND ART

In recent years, there is an increasing demand for miniaturization of micro-processing for semiconductors using lithographic techniques. A double patterning method (for example, JP-2007-311508-A) and a double imaging method (for example, Proceedings of SPIE. Vol. 6520, 65202F (2007)) have been proposed as processes that realize a line width in a resist pattern of 32 nm or less. A double patterning method as used herein represents a method which uses double the spacing of the target resist pattern to execute normal exposure, developing and etching steps thereby executing a first transcription and then, in the resulting spaces, executes again the same exposure, developing and etching steps thereby executing a second transcription, and obtain the target micro resist pattern. A double imaging method is a method which uses double the spacing of the target resist pattern to execute normal exposure, developing steps, and processes the resist pattern using a chemical solution termed a freezing agent, thereafter, executes again the same exposure and developing with the spaces thereby obtaining the target micro resist pattern.

### DISCLOSURE OF THE INVENTION

### Problem to be Solved

The present invention has the object of providing a method of resist processing that enables a double patterning method or a double imaging method.

### Means for Solving the Problem

The present invention includes following inventions.

[1] A resist processing method comprising the steps of:

(1) forming a first resist film by applying a first resist composition comprising:

a resin (A) having an acid-labile group, being insoluble or poorly soluble in alkali aqueous solution, and being rendered soluble in alkali aqueous solution through the action of an acid,

a photo acid generator (B),

a cross-linking agent (C) and

an acid amplifier (D)

onto a substrate and drying;

(2) prebaking the first resist film;

(3) exposing to the first resist film;

(4) post-exposure baking of the first resist film;

(5) developing with a first alkali developer to obtain a first resist pattern;

(6) hard-baking the first resist pattern,

(7) obtaining a second resist film by applying a second resist composition onto the first resist pattern, and drying;

(8) pre-baking the second resist film;

(9) exposing the second resist film;

(10) post-exposure baking the second resist film; and

(11) developing with a second alkali developer to obtain a second resist pattern.

[2] The resist processing method according to [1], wherein the cross-linking agent (C) is at least one selected from the group consisting of a urea cross-linking agent, an alkylene urea cross-linking agent and a glycoluril cross-linking agent.

[3] The resist processing method according to [1] or [2], wherein the content of the cross-linking agent (C) is 0.5 to 30 parts by weight relative to 100 parts by weight of the resin.

[4] The resist processing method according to any one of [1] to [3], wherein the acid-labile group of the resin (A) is a group having an alkyl ester group or lactone ring, in which a carbon atom that bonds to an oxygen atom of —COO— is a quaternary carbon atom, or a group having a carboxylate.

[5] The resist processing method according to any one of [1] to [4], wherein the photo acid generator (B) is a compound represented by the formula (I).

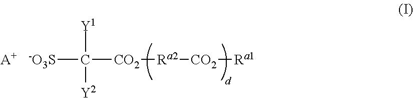

wherein, R^{a1} and R^{a2} independently represent a C₁ to C₃₀ linear or branched chain, or cyclic hydrocarbon, a 5 to 9 member heterocyclic group containing oxygen atom, or a group —R^{a1′}—O—R^{a2′}— (here, R^{a1′} and R^{a2′} independently represent a C₁ to C₂₉ linear or branched chain, or cyclic hydrocarbon, a 5 to 9 member heterocyclic group containing oxygen atom), the R^{a1}, R^{a2}, R^{a1′} and R^{a2′} may be substituted with at least one selected from the group consisting of an oxo group, a C₁ to C₆ alkyl group, a C₁ to C₆ alkoxy group, a C₁ to C₄ perfluoroalkyl group, a C₁ to C₆ hydroxylalkyl group, a hydroxy group and a cyano group;

A⁺ represents an organic counter ion;

Y¹ and Y² independently represent a fluorine atom or a C₁ to C₆ perfluoroalkyl group;

d represents 0 or an integer of 1.

[6] The resist processing method according to any one of [1] to [5], wherein the photo acid generator (B) is a compound represented by the formula (V) or the formula (VI).

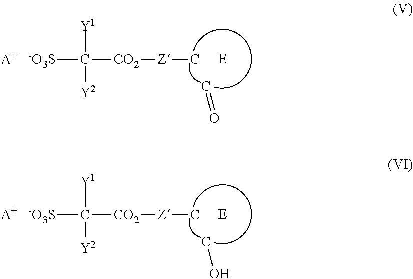

wherein a ring E represents an C₃ to C₃₀ cyclic hydrocarbon group, the ring E may be substituted with at least one selected from the group consisting of a C₁ to C₆ alkyl group, a C₁ to C₆ alkoxy group, a C₁ to C₄ perfluoroalkyl group, a C₁ to C₆ hydroxyalkyl group, a hydroxy group and a cyano group;

Z′ represents a single bond or a C₁ to C₄ alkylene group;

A⁺, Y¹ and Y² have the same meaning as defined above.

[7] The resist processing method according to any one of [1] to [6], wherein the photo acid generator (B) is a compound containing one or more cations selected from the group consisting of the formulae (IIa), (IIb), (IIc), (IId) and (IV).

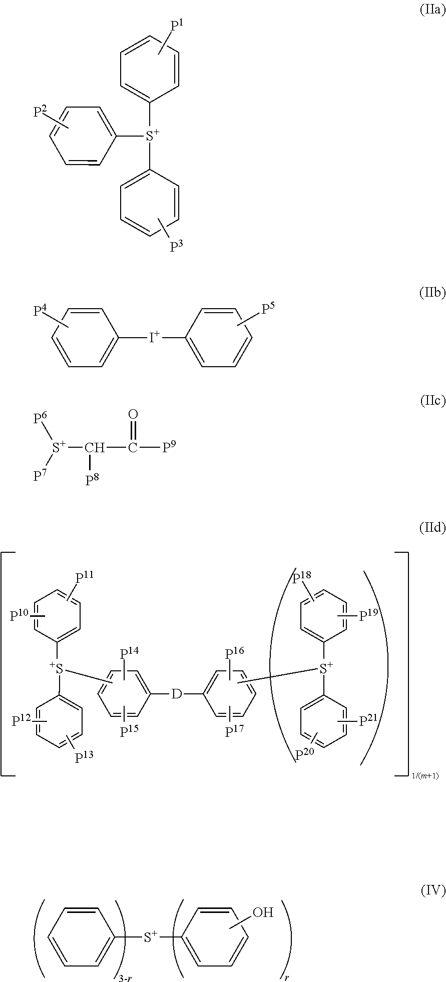

wherein P¹ to P⁵ and P¹⁰ to P²¹ independently represent a hydrogen atom, a hydroxy group, a C₁ to C₁₂ alkyl group or a C₁ to C₁₂ alkoxy group;

P⁶ and P⁷ independently represent a C₁ to C₁₂ alkyl group or a C₃ to C₁₂ cycloalkyl group, or P⁶ and P⁷ are bonded to form a C₃ to C₁₂ divalent hydrocarbon group;

P⁸ represents a hydrogen atom;

P⁹ represents a C₁ to C₁₂ alkyl group, a C₃ to C₁₂ cycloalkyl group or an optionally substituted aromatic group, or P⁸ and P⁹ are bonded to form a C₃ to C₁₂ divalent hydrocarbon group;

D represents a sulfur atom or an oxygen atom;

m represents 0 or 1;

r represents an integer of 1 to 3.

[8] The resist processing method of according to any one of [1] to [7], wherein the acid amplifier (D) is a compound represented by the formula (D1) or the formula (D2).

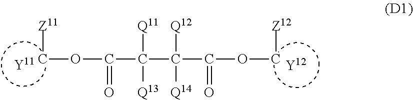

wherein Z¹¹ and Z¹² independently represent a hydrogen atom, a C₁ to C₁₂ alkyl group or a C₃ to C₁₂ cycloalkyl group, provided that at least one of Z¹¹ and Z¹² represent a C₁ to C₁₂ alkyl group or a C₃ to C₁₂ cycloalkyl group;

ring Y¹¹ and ring Y¹² independently represents an optionally substituted C₃ to C₂₀ alicyclic hydrocarbon group; and

Q¹¹, Q¹², Q¹³ and Q¹⁴ independently represent a fluorine atom or a C₁ to C₆ perfluoroalkyl group;

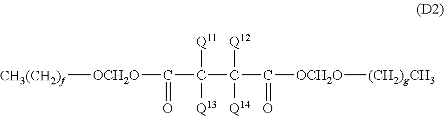

wherein Q¹¹, Q¹², Q¹³ and Q¹⁴ have the same meaning as defined above; and

f and g independently represent an integer of 0 to 5.

[9] The resist processing method according to any one of [1] to [8], wherein the first resist composition further comprised a thermal acid generator.

### Effect of the Invention

According to the method of resist processing of the present invention, double patterning method and a double imaging method are enabled, that is a first-layer resist pattern can be formed in a desire shape more accurately with reliability, as well as the shape of the first-layer resist pattern is maintained without deforming even through the processing of second and subsequent layers, as a result, an extremely fine pattern can be formed.

### DETAILED DESCRIPTION OF THE PREFERRED EMBODIMENTS

The resist composition used for the resist processing method of the present invention is characterized by mainly comprising a resin (A), a photo acid generator (B), a cross-linking agent (C) and an acid amplifier (D), and, in particular, the cross-linking agent (C) and the acid amplifier (D).

The resin in the resist composition of the present invention has an acid-labile group, and prior to exposure, is insoluble or poorly soluble in an alkali aqueous solution, the resin can be dissolved in an alkali aqueous solution as a result of cleaving through the catalytic action on the acid-labile groups in the resin by acid produced from the photo acid generator (B) during exposure. Meanwhile, in unexposed portions of the resin, alkali insolubility characteristics are retained. The resist composition enables formation of a positive-type resist pattern by subsequent development using an alkali aqueous solution. Here, “insoluble or poorly soluble in alkali aqueous solution” means a solubility wherein about 100 mL or more of alkali aqueous solution generally used as a developer is required, in order to generally dissolve 1 g or 1 mL of the resist composition, although this can vary, depending on the kinds of the alkali aqueous solutions, concentration thereof, and the like. “Soluble in alkali aqueous solution” means solubility wherein less than 100 mL of the alkali aqueous solution is enough to dissolve 1 g or 1 mL of the resist composition.

As described above, the acid-labile group in the resin (A) used in the present invention means a group which undergoes cleavage or tends to undergo cleavage by an acid produced from the photo acid generator (B) described below. There is no particular limitation on the group as long as the group includes such properties.

Examples thereof include;

a group having an alkyl ester group in which a carbon atom that bonds to the oxygen atom of —COO— is a quaternary carbon atom;

a group having a lactone ring in which a carbon atom that bonds to the oxygen atom of —COO— is a quaternary carbon atom;

a group having a carboxylate such as acetal type ester and alicyclic ester. Among these, preferred is a group giving a carboxyl group by the action of the acid which is produced from the photo acid generator (B) described below. Here a quaternary carbon atom means a carbon atom which bonds to substituents other than a hydrogen atom and does not bond to a hydrogen atom. In particular, the carbon atom of the carbon atom that bonds to an oxygen atom of —COO— is preferably a quaternary carbon atom bonding to three carbon atoms as the acid-labile group.

When a group having carboxylate, which is one of the acid-labile group, is exemplified as “R ester of —COOR”, examples include an alkyl ester in which a carbon atom that bonds to the oxygen atom of —COO— is a quaternary carbon atom such as a tert-butyl ester group, typically “—COO—C(CH₃)₃”;

an acetal type ester group or lactone ring-containing group, such as methoxymethyl ester, ethoxymethyl ester, 1-ethoxyethyl ester, 1-isobutoxyethyl ester, 1-isopropoxyethyl ester, 1-ethoxypropyl ester, 1-(2-methoxyethoxy)ethyl ester, 1-(2-acetoxyethoxy)ethyl ester, 1-[2-(1-adamantyloxy)ethoxy]ethyl ester, 1-[2-(1-adamantanecarbonyloxy)ethoxy]ethyl ester, tetrahydro-2-furyl ester and tetrahydro-2-pyranyl ester group;

an alicyclic ester group in which a carbon atom bonding to the oxygen atom of —COO— is quaternary carbon atom, such as an isobornyl ester, 1-alkylcycloalkyl ester, 2-alkyl-2-adamantyl ester and 1-(1-adamantyl)-1-alkylalkyl ester group.

Examples of such group having an carboxylate include a group having (meth)acrylate, norbornene carboxylate, tricyclodecene carboxylate, or tetracyclodecene caroxylate.

The resin (A) can be produced by addition polymerization of a monomer having an acid-labile group and an olefinic double bonds.

Monomers having a bulky group such as an alicyclic substructure, in particular, a bridged structure as an acid-labile group (e.g. a 2-alkyl-2-adamantyl group and 1-(1-adamantyl)-1-alkylalkyl group) are preferable as the monomer used, since resolution of the obtained resist has a tendency to be excellent. Examples of such monomer having the bulky group include a 2-alkyl-2-adamantyl(meth)acrylate, a 1-(1-adamantyl)-1-alkylalkyl(meth)acrylate, a 2-alkyl-2-adamantyl 5-norbornene-2-carboxylate, a 1-(1-adamantyl)-1-alkylalkyl 5-norbornene-2-carboxylate.

Particularly, the 2-alkyl-2-adamantyl(meth)acrylate as the monomer is preferably used because a resist composition having excellent resolution tends to be obtained.

Examples of the 2-alkyl-2-adamantyl(meth)acrylate include 2-methyl-2-adamantyl acrylate, 2-methyl-2-adamantyl methacrylate, 2-ethyl-2-adamantyl acrylate, 2-ethyl-2-adamantyl methacrylate, 2-isopropyl-2-adamantyl acrylate, 2-isopropyl-2-adamantyl methacrylate and 2-n-butyl-2-adamantyl acrylate, for example.

Among these, 2-ethyl-2-adamantyl(meth)acrylate or 2-isopropyl-2-adamantyl(meth)acrylate is preferably used because a resist composition having excellent sensitivity and heat resistance tends to be obtained.

The 2-alkyl-2-adamantyl(meth)acrylate can be usually produced by reacting a 2-alkyl-2-adamantanol or a metal salt thereof with an acrylic halide or a methacrylic halide.

One characteristic of the resin (A) used in the present invention is that it includes structural units having high-polarity substituents. Example of the structural units includes a structural unit derived from 2-norbornene to which one or more hydroxyl groups are bonded; a structural unit derived from (meth)acrylonitrile; a structural unit derived from a (meth)acrylic esters such as 1-adamantyl ester or an alkyl ester in which a carbon atom which bonds to an oxygen atom of —COO— is a secondary carbon atom or a tertiary carbon atom to which one or more hydroxy groups are bonded; a structural unit derived from a styrene monomer such as p- or m-hydroxystyrene; a structural unit derived from (meth)acryloyloxy-γ-butyrolactone in which the lactone ring may be substituted with an alkyl group. A 1-adamantyl ester, in which the carbon atom which bonds to an oxygen atom of —COO— is quaternary atoms, is an acid-stable group.

Specific examples of the monomer having the high-polarity substituent include 3-hydroxy-1-adamantyl(meth)acrylate; 3,5-dihydroxy-1-adamantyl(meth)acrylate; α-(meth)acryloyloxy-γ-butyrolactone; β-(meth)acryloyloxy-γ-butyrolactone; a monomer represented by the formula (a) below, a monomer represented by the formula (b), and hydroxystyrene.

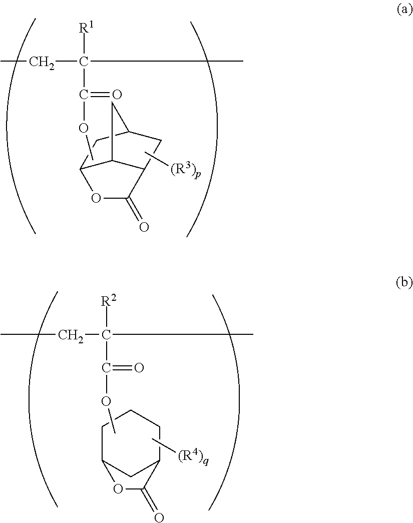

wherein R¹ and R² independently represent a hydrogen atom or a methyl group;

R³ and R⁴ independently represent a hydrogen atom, a methyl group or a trifluoromethyl or a halogen atom;

p and q represent an integer of 1 to 3, when p is 2 or 3, the plurality of R³ may be the different from each other, when q is 2 or 3, the plurality of R⁴ may be different from each other.

Among these, the resist obtained from a resin having any of the structural unit derived from 3-hydroxy-1-adamantyl(meth)acrylate, the structural unit derived from 3,5-dihydroxy-1-adamantyl(meth)acrylate, the structural unit derived from α-(meth)acryloyloxy-γ-butyrolactone, the structural unit derived from β-(meth)acryloyloxy-γ-butyrolactone, the structural unit represented by the formula (a), and the structural unit represented by the formula (b) is preferable because improvement of the adhesiveness of resist to a substrate and of the resolution of resist tends to be obtained.

The resin (A) used in the present invention may include other structural units. Example thereof include a structural unit derived from a monomer having a free carboxylic acid group such as acrylic acid or methacrylic acid, a structural unit derived from an aliphatic unsaturated dicarboxylic anhydride such as maleic anhydride, and itaconic anhydride, and a structural unit derived from 2-norbornene, a structural unit derived from (meth)acrylic esters such as an 1-adamantyl ester or alkyl ester in which a carbon atom which bonds to an oxygen atom of —COO— is a secondary carbon atom or a tertiary carbon atom. A 1-adamantyl ester, in which the carbon atom which bonds to an oxygen atom of —COO— is quaternary atoms, is an acid-stable group.

Monomers such as 3-hydroxy-1-adamantyl(meth)acrylate and 3,5-dihydroxy-1-adamantyl(meth)acrylate are commercially available, and they can also be produced, for example, by reacting a corresponding hydroxyadamantane with (meth)acrylic acid or its acid halide.

A monomer such as (meth)acryloyloxy-γ-butyrolactone can be produced by reacting α- or β-bromo-γ-butyrolactone in which the lactone ring may be substituted with a alkyl group with acrylic acid or methacrylic acid, or reacting α- or β-hydroxy-γ-butyrolactone in which the lactone ring may be substituted with a alkyl group with an acrylic halide or a methacrylic halide.

Monomers to give structural units represented by the formula (a) and the formula (b) include a (meth)acrylate of an alicyclic lactone having the hydroxyl group described below, and mixtures thereof. These esters can be produced, for example, by reacting a corresponding alicyclic lactone having the hydroxyl group with (meth)acrylic acid (see, for example, JP 2000-26446 A).

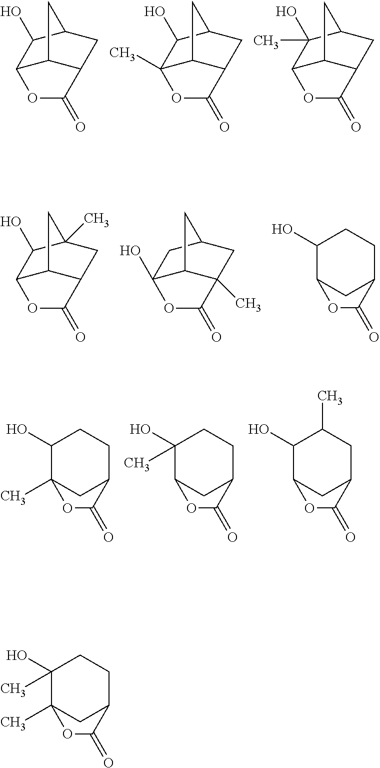

Examples of the (meth)acryloyloxy-γ-butyrolactone include

α-acryloyloxy-γ-butyrolactone, α-methacryloyloxy-γ-butyrolactone,
α-acryloyloxy-β,β-dimethyl-γ-butyrolactone,
α-methacryloyloxy-β,β-dimethyl-γ-butyrolactone,
α-acryloyloxy-α-methyl-γ-butyrolactone, α-methacryloyloxy-α-methyl-γ-butyrolactone,
β-acryloyloxy-γ-butyrolactone, β-methacryloyloxy-γ-butyrolactone and β-methacryloyloxy-α-methyl-γ-butyrolactone.

In the case of KrF excimer laser exposure, sufficient transmittance can be obtained even the structural unit derived from a styrene monomer such as p- or m-hydroxystrene is used as the structural unit of the resin. Such copolymerized resin can be obtained by radical-polymerizing with corresponding (meth)acrylic ester monomer, acetoxystyrene and styrene, and then de-acetylating with an acid.

The resin having a structural unit derived from 2-norbornene results in a sturdy structure because the main chain directly has an alicyclic backbone and allow dry etching resistance. The structural unit derived from 2-norbornene can be introduced into the main chain, for example, by radical polymerization with the combined use of an aliphatic unsaturated dicarboxylic anhydride such as maleic anhydride or itaconic anhydride in addition to the corresponding 2-norbornene. Accordingly, the structural unit formed upon the opening of the double bond in the norbornene structure can be represented by the formula (c), whereas structural unit formed upon the opening of the double bond of maleic anhydride and itaconic anhydride can be represented by the formulas (d) and (e), respectively.

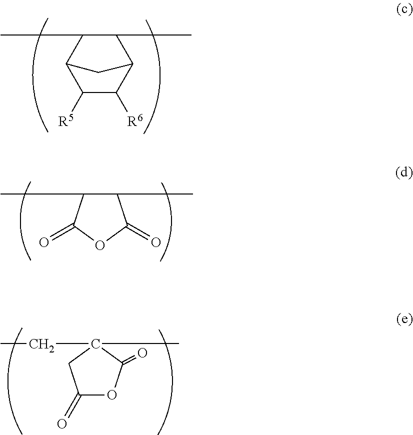

wherein R⁵ and/or R⁶ independently represent a hydrogen atom, a C₁ to C₃ alkyl group, a carboxyl group, a cyano group, or —COOU wherein U is an alcohol residue, or R⁵ and R⁶ are bonded together to form a carboxylic anhydride residue represented by —C(═O)OC(═O)—.

When R⁵ and/or R⁶ is —COOU group, it is an ester formed from carboxyl group. Examples of the alcohol residue corresponding to U include an optionally substituted C₁ to C₈ alkyl group, and 2-oxooxolan-3- or 4-yl group. The alkyl group may be substituted with a hydroxy group or an alicyclic hydrocarbon group.

Examples of the alkyl group include methyl group, ethyl group, n-propyl group, iso-propyl group, n-butyl group, sec-butyl group, tert-butyl group, pentyl group, hexyl group, octyl group and 2-ethylhexyl group.

Examples of a hydroxyl group-bound alkyl group, i.e., a hydroxylalkyl group include hydroxylmethyl group and 2-hydroxylethyl group.

Examples of the alicyclic hydrocarbon group include the group having about 3 to 30 carbon atoms, such as cyclopropyl, cyclobutyl, cyclopentyl, cyclohexyl, cycloheptyl, cyclodecyl, cyclohexenyl, bicyclobutyl, bicyclohexyl, bicyclooctyl and 2-norbonyl.

In the present specification, groups described above such as an alkyl group are exemplary of similar entities as described above in any of the chemical formulae, which may differ with respect to the number of carbon atoms, unless otherwise specified. Furthermore when a group enables both linear and branched chain structures, both structures are included (the same applies hereafter).

The followings can be specific examples of the norbornene structures represented by the formula (c), which are monomers giving an add-stable structure.
2-norbornene,
2-hydroxy-5-norbornene,
5-norbornene-2-carboxylic acid,
methyl 5-norbornene-2-carboxylate,
2-hydroxy-1-ethyl 5-norbornene-2-carboxylate,
5-norbornene-2-methanol, and
5-norbornene-2,3-dicarboxylic acid anhydride.

When the U of the —COOU of R⁵ and/or R⁶ in the formula (c) is an acid-labile group, such as an aliphatic ester in which a carbon atom bonded to the oxygen atom of —COO— is quaternary carbon atom, the group will be a structure unit having an acid-labile group, despite having a norbornene structure.

Examples of the monomer having a norbornene structure and an acid-labile group include t-butyl 5-norbornene-2-carboxylate, 1-cyclohexyl-1-methylethyl 5-norbornene-2-carboxylate, 1-methylcyclohexyl-5-norbornene-2-carboxylate, 2-methyl-2-adamantyl 5-norbornene-2-carboxylate, 2-ethyl-2-adamantyl 5-norbornene-2-carboxylate, 1-(4-methylcyclohexyl)-1-methylethyl 5-norbornene-2-carboxylate, 1-(4-hydroxycyclohexyl)-1-methylethyl 5-norbornene-2-carboxylate, 1-methyl-1-(4-oxocyclohexyl)ethyl 5-norbornene-2-carboxylate and 1-(1-adamantyl)-1-methylethyl 5-norbornene-2-carboxylate.

In the resin (A) of the resist composition used in the present invention, usually, the content of the structural unit(s) derived from a monomer having an acid-labile group is preferably adjusted in the range of 10 to 80 mol % though the content varies depending on the kind of radiation for patterning exposure, the kind of an acid-labile group, and the like.

When the structural unit derived from 2-alkyl-2-adamantyl(meth)acrylate or 1-(1-adamantyl)-1-alkylalkyl(meth)acrylate in particular is included as the structural unit derived from the monomer with the acid-labile group, adjusting the content to 15 mol % or more with respect to the total structural units constituting the resin is advantageous in terms of the dry etching resistance of the resulting resist because the resin will have an alicyclic group and will be a sturdy structure.

When an alicyclic compound and an aliphatic unsaturated dicarboxylic anhydride having an olefinic double bond in its molecule are used as the monomer, they are preferably used in excess amounts from the viewpoint of a tendency that the addition polymerization does not easily proceed.

Further, the monomers that are used may be a combination of monomers that have the same olefinic double bond moieties but different acid-labile groups, combinations of monomers with the same acid-labile groups and different olefinic double bond moieties, and combinations of monomers with different combinations of add-labile groups and olefinic double bond moieties.

There is no particular limitation on the photo acid generator (B) that is used in the present invention as long as an acid is produced by exposure, and any known substance in this technical field may be used.

For example, compounds represented by formula (I) may be used as the photo add generator (B).

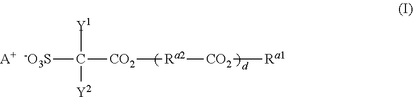

wherein, R^{a1} and R^{a2} independently represent a C₁ to C₃₀ linear or branched chain, or cyclic hydrocarbon, a 5 to 9 member heterocyclic group containing oxygen atom, or a group —R^{a1′}—O—R^{a2′}— (here, R^{a1′} and R^{a2′} independently represent a C₁ to C₂₉ linear or branched chain, or cyclic hydrocarbon, a 5 to 9 member heterocyclic group containing oxygen atom), the R^{a1}, R^{a2}, R^{a1′} and R^{a2′} may be substituted with at least one selected from the group consisting of an oxo group, a C₁ to C₆ alkyl group, a C₁ to C₆ alkoxy group, a C₁ to C₄ perfluoroalkyl group, a C₁ to C₆ hydroxyalkyl group, a hydroxy group and a cyano group;

A⁺ represents an organic counter ion;

Y¹ and Y² independently represent a fluorine atom or a C₁ to C₆ perfluoroalkyl group;

d represents 0 or an integer of 1.

Here, the cyclic hydrocarbon group includes an alicyclic or an aromatic group, a monocyclic or a bi- or more-cyclic condensed or bridged cyclic group, a plurality of cyclic hydrocarbon groups bonded via or not via a carbon atom, an aryl group or an aralkyl group.

More specifically, in addition to the alicyclic hydrocarbon group described above such as a C₄ to C₈ cycloalkyl or norbornyl, other examples include phenyl, indenyl, naphthyl, adamantyl, norbornenyl, tolyl and benzyl.

Examples of the heterocyclic group containing oxygen atom include the followings.

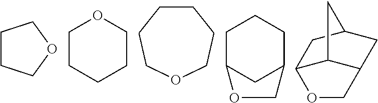

Examples of the alkoxyl group include methoxy, ethoxy, n-propoxy, isopropoxy, n-butoxy, sec-butoxy, tert-butoxy, pentoxy, hexoxy, octyloxy and 2-ethylhexyloxy groups.

Examples of the perfluoroalkyl group include perfluoromethyl, perfluoroethyl, perfluoropropyl and perfluorobutyl.

The photo acid generator (B) may be a compound represented by the formula (V) or the formula (VI).

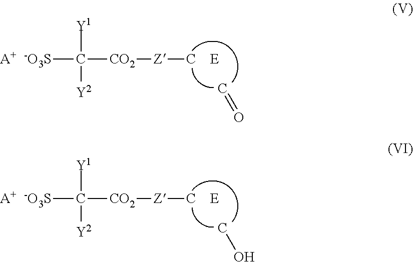

wherein a ring E represents a C₃ to C₃₀ cyclic hydrocarbon group, the ring E may be substituted with at least one selected from the group consisting of a C₁ to C₆ alkyl group, a C₁ to C₆ alkoxy group, a C₁ to C₁ perfluoroalkyl group, a C₁ to C₆ hydroxyalkyl group, a hydroxy group and a cyano group;

Z′ represents a single bond or a C₁ to C₄ alkylene group;

A⁺, Y¹ and Y² have the same meaning as defined above.

Examples of an alkylene group include the following groups represented by (Y-1) to (Y-12).

The photo acid generator (B) may be a compound represented by the formula (III).

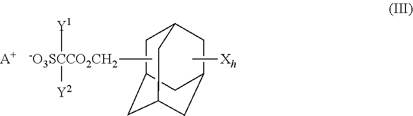

wherein Y¹ and Y² independently represent a fluorine atom or a C₁ to C₆ perfluoroalkyl group;

X represents —OH or —Y—OH, here Y represents C₁ to C₆ linear or branched chain alkylene group;

h represents an integer of 1 to 9;

A⁺ has the same meaning as defined above.

Y¹ or Y² is preferably a fluorine atom.

n is preferably an integer of 1 to 2.

Examples of the Y include, for example, the following groups represented by (Y-1) to (Y-12). Among there, (Y-1) and (Y-2) are preferable due to their ease of production.

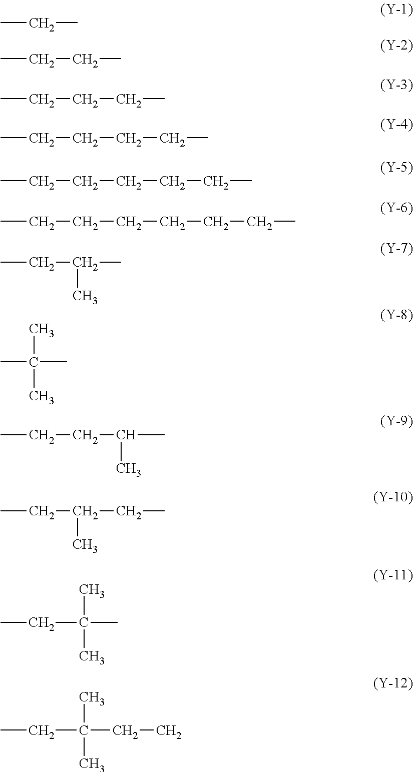

Examples of the anion in the compound represented by the formula (I), (III), (V) or (VI) include the following compounds.

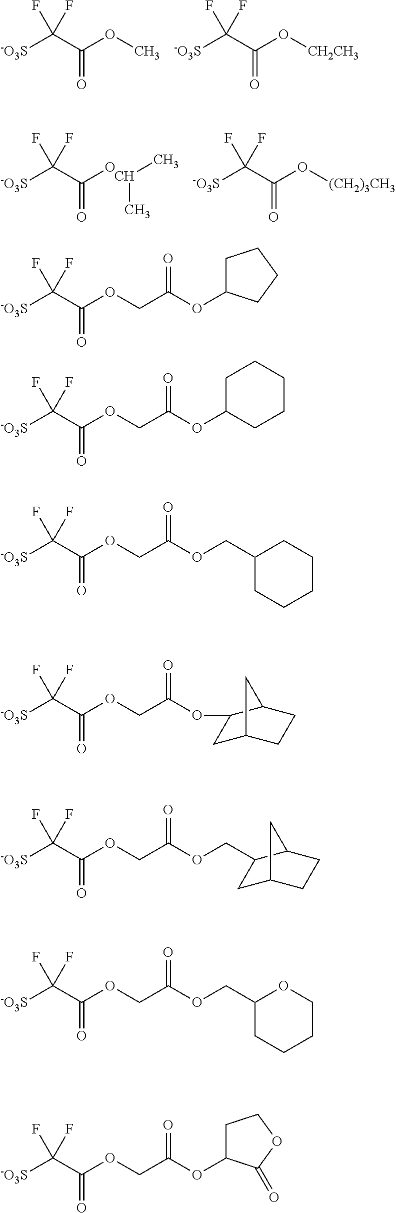

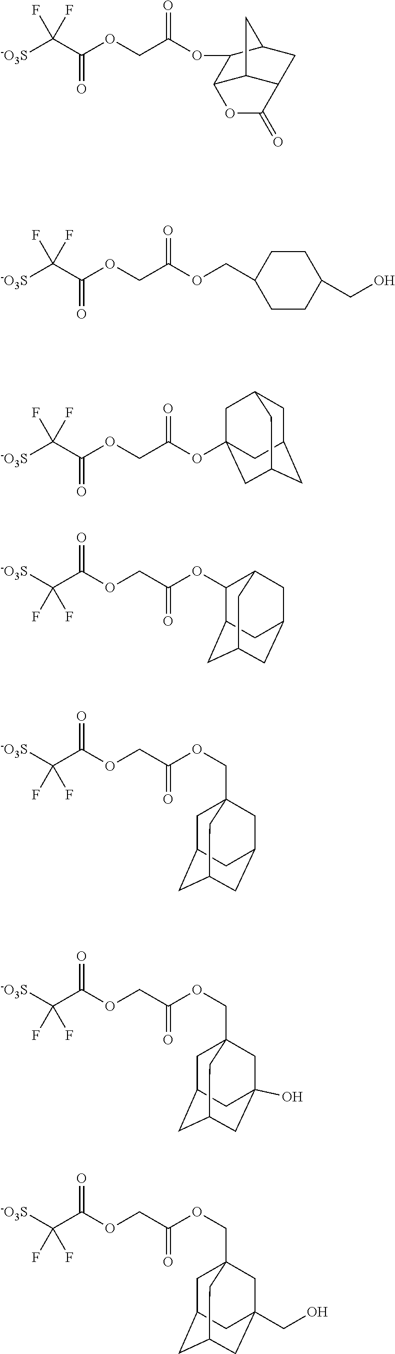

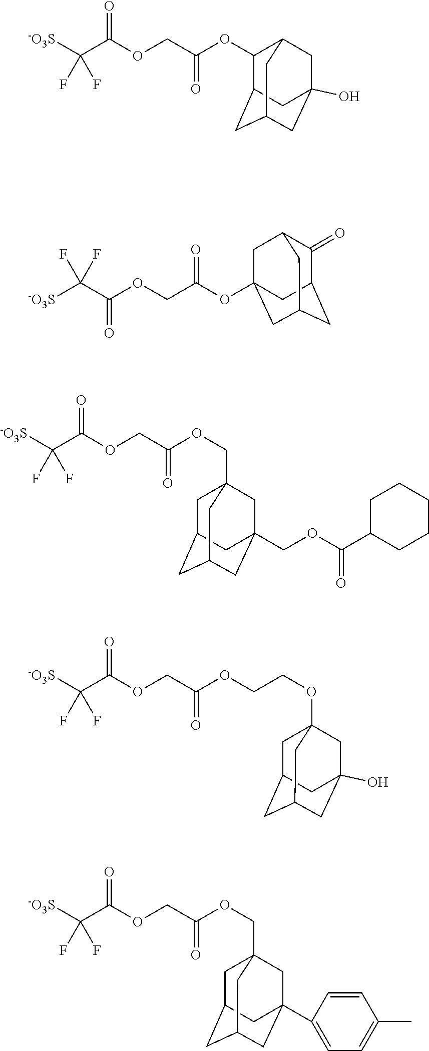

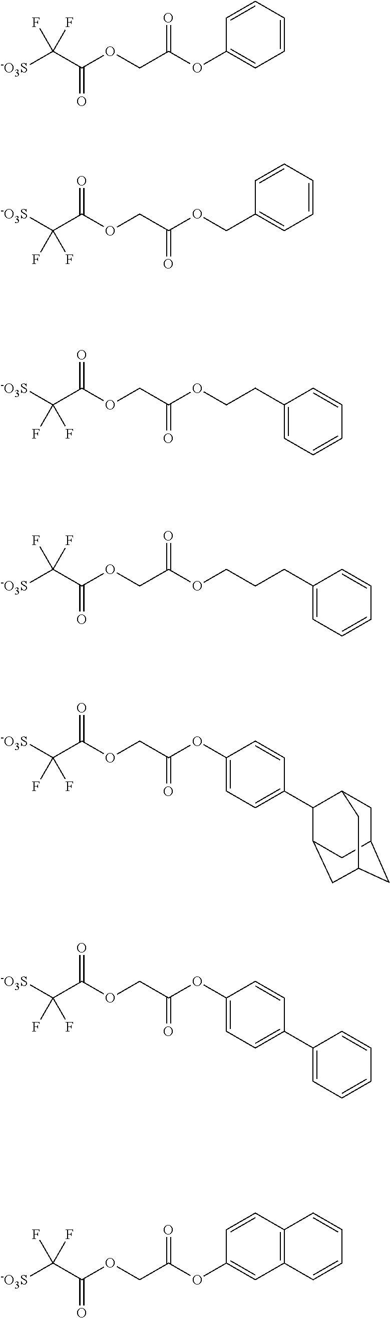

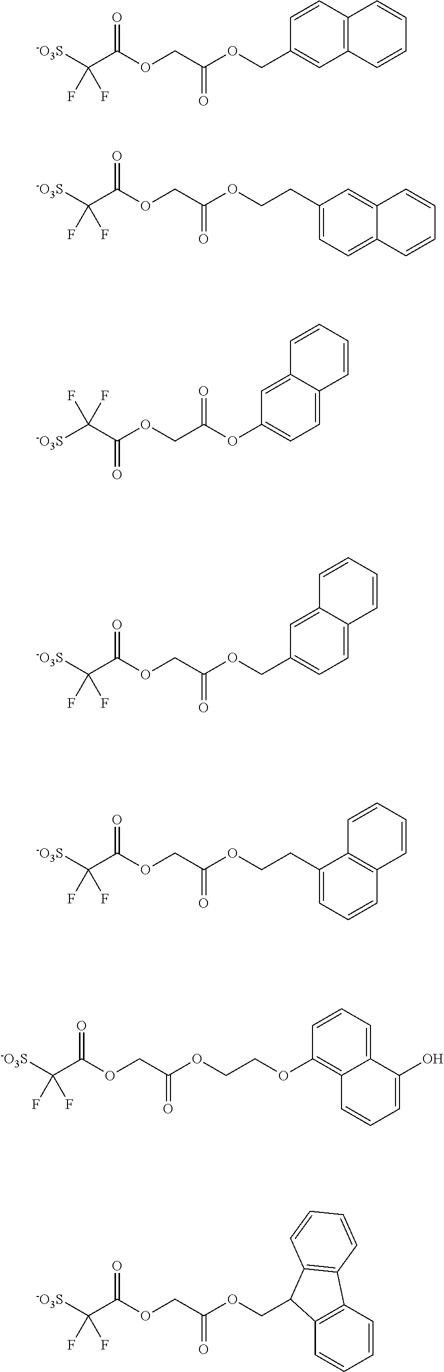

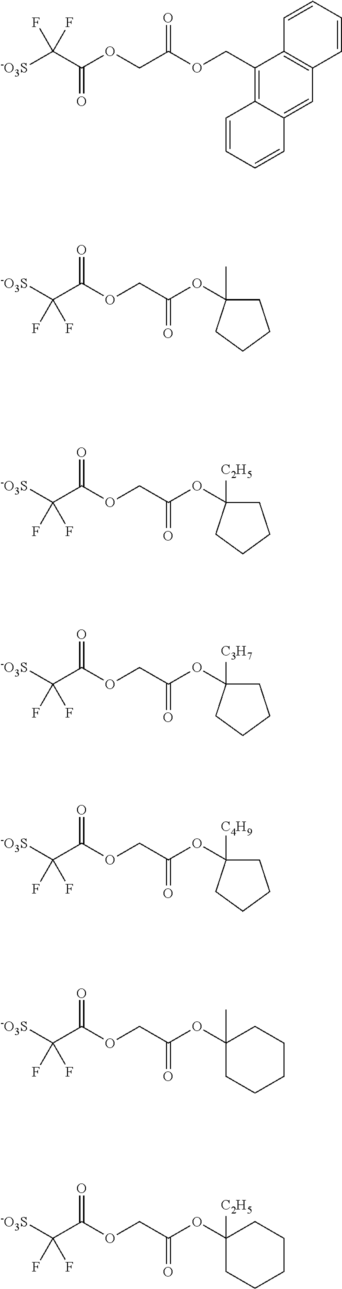

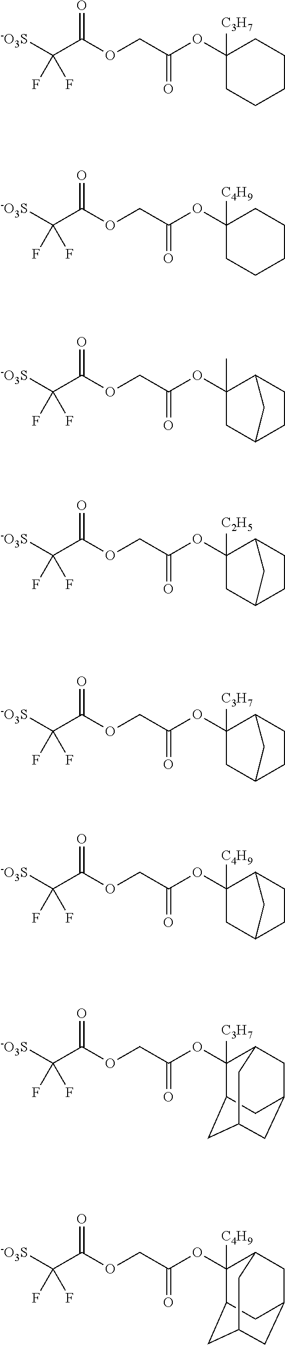

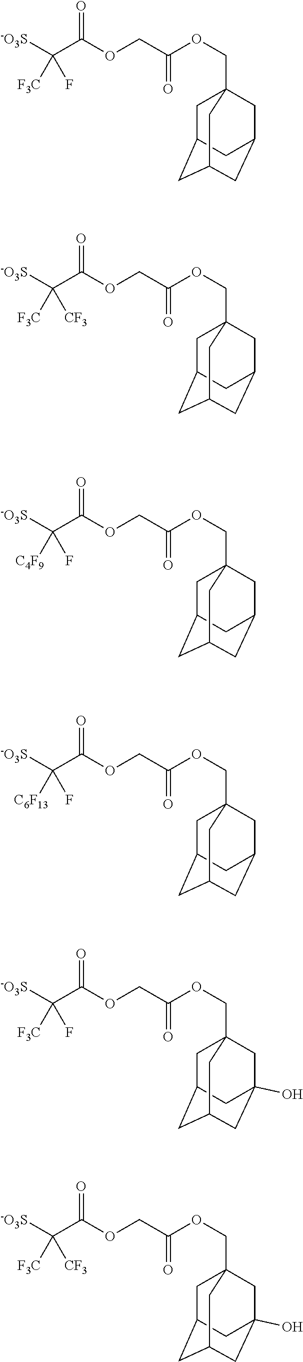

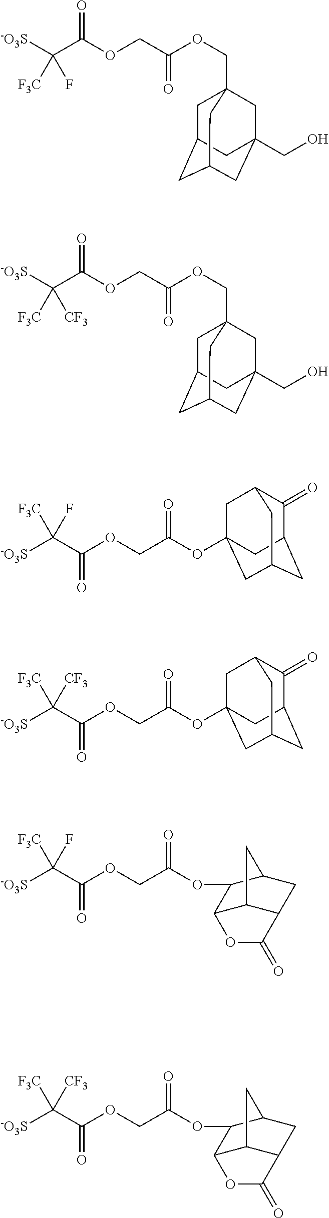

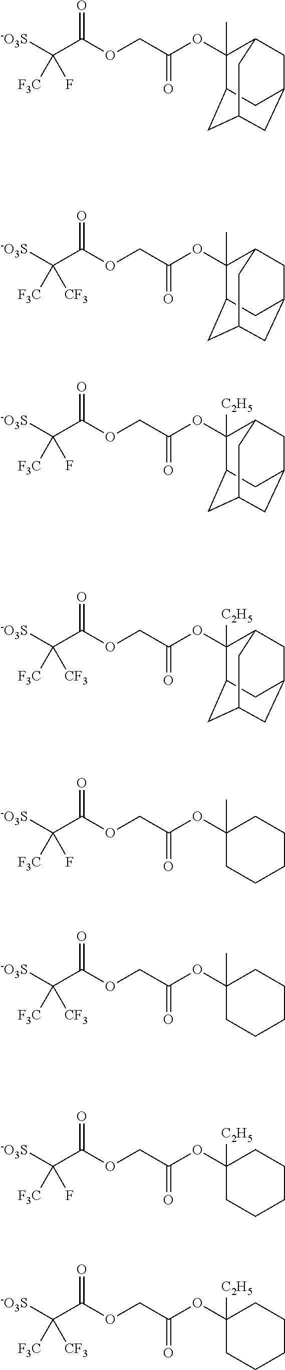

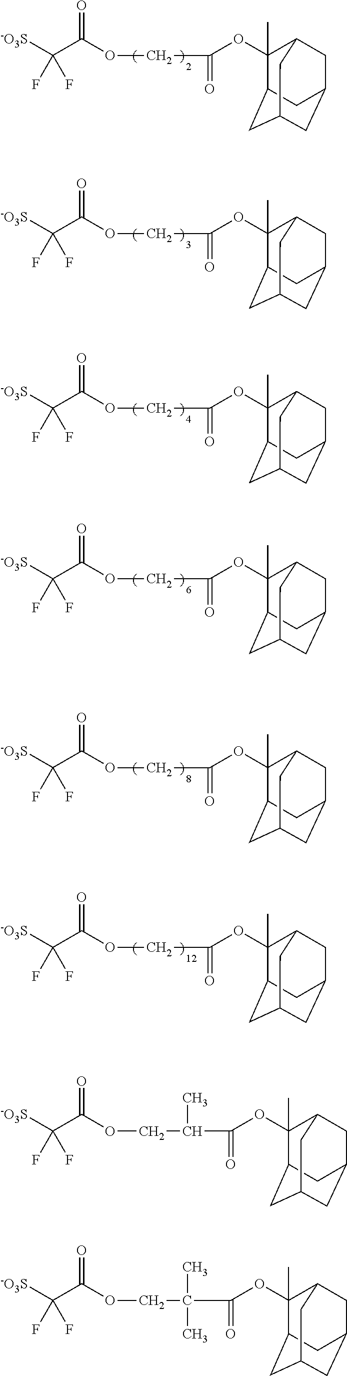

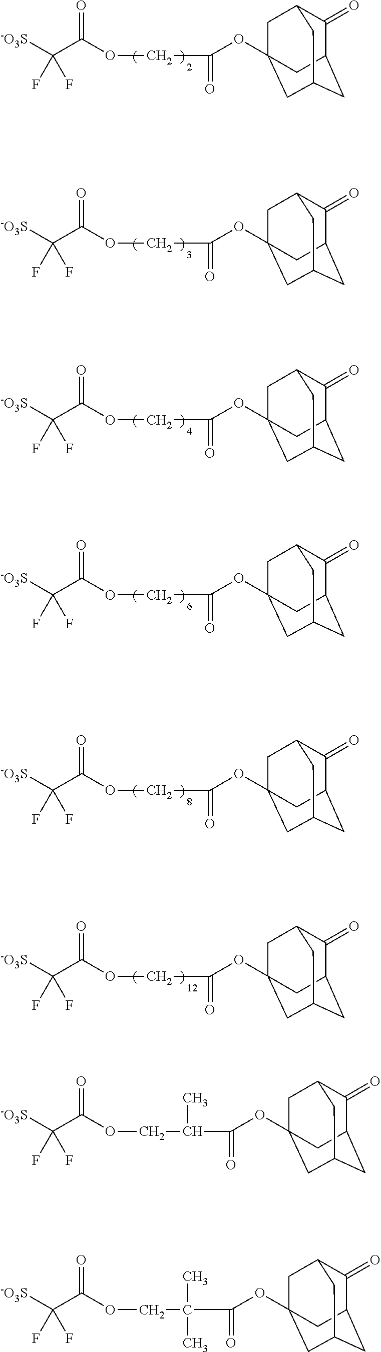

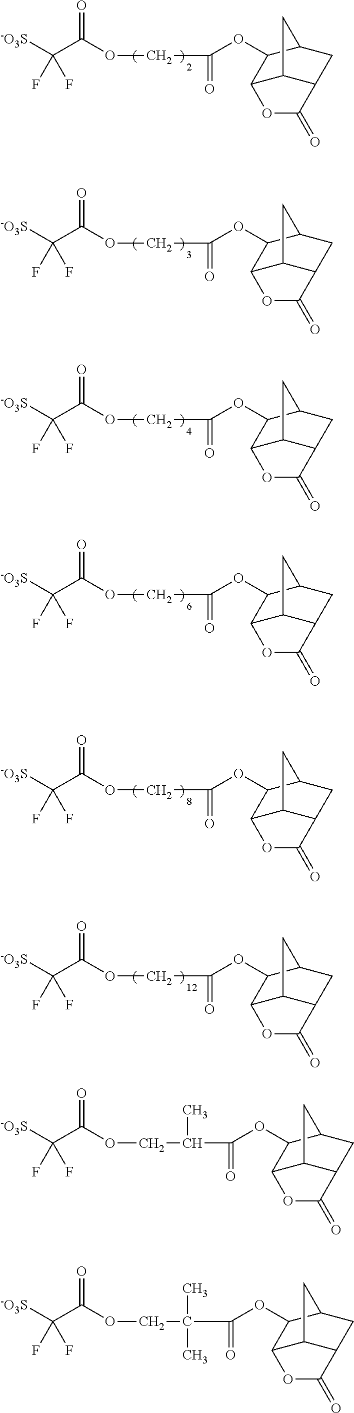

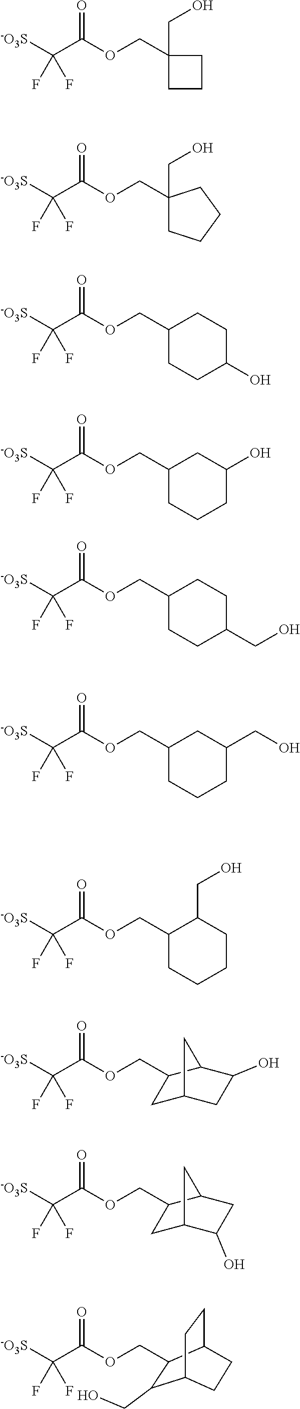

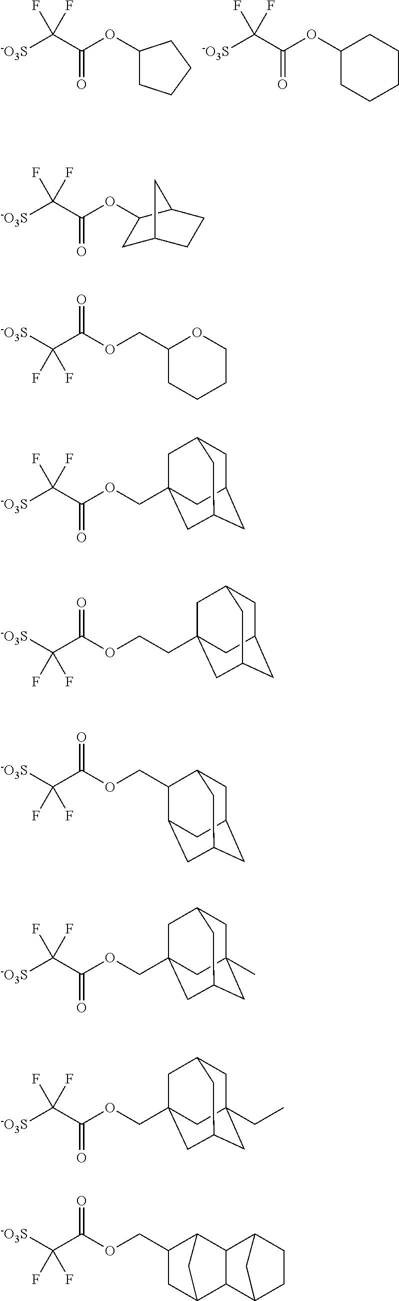

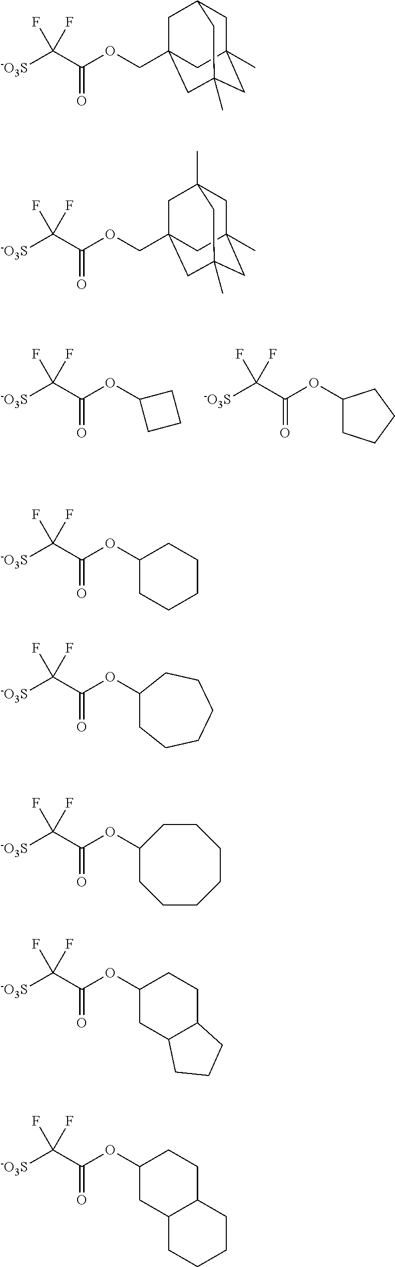

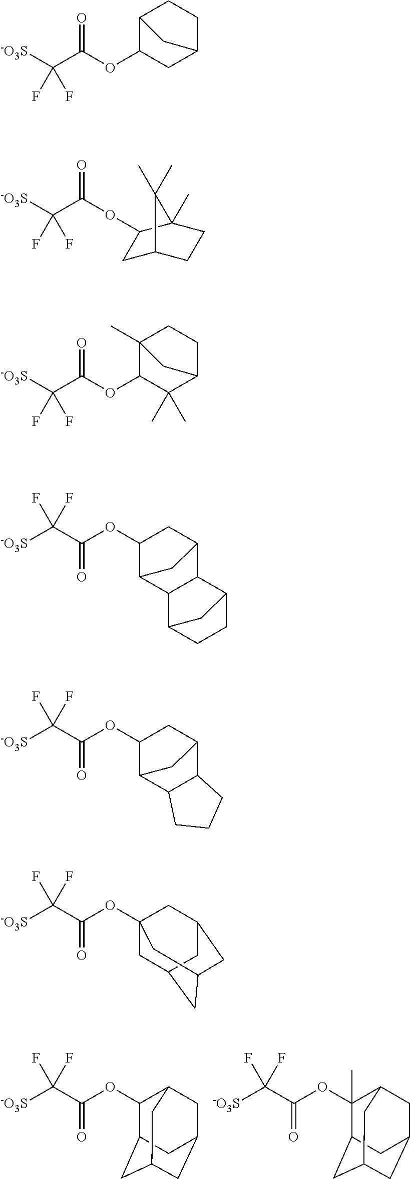

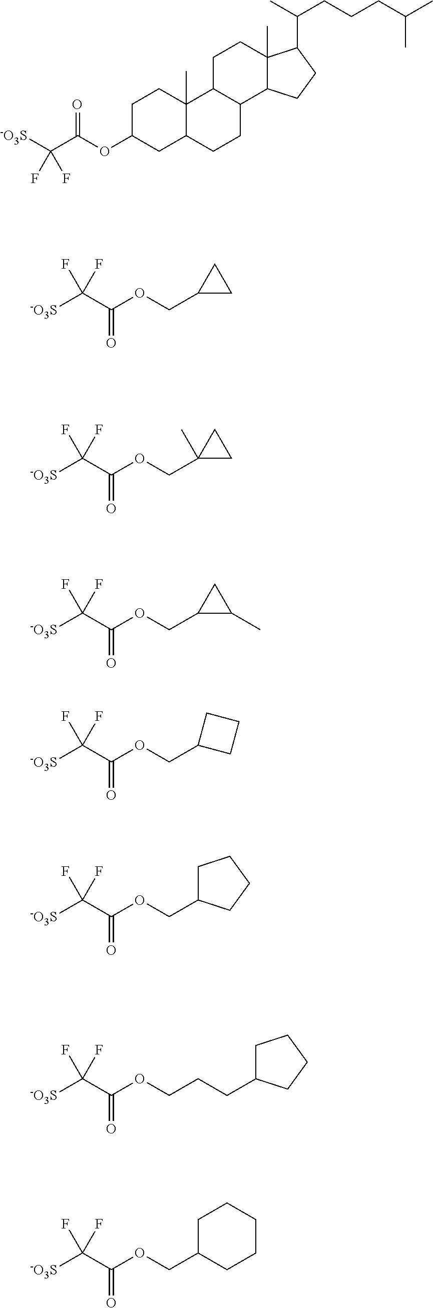

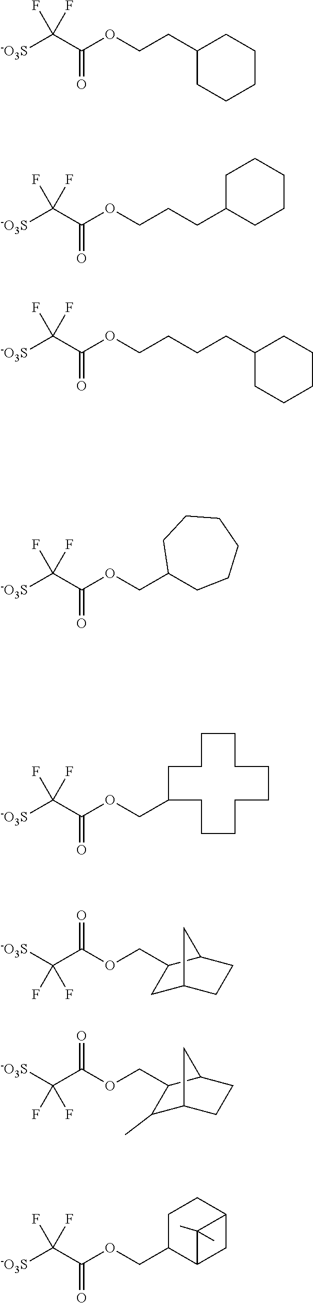

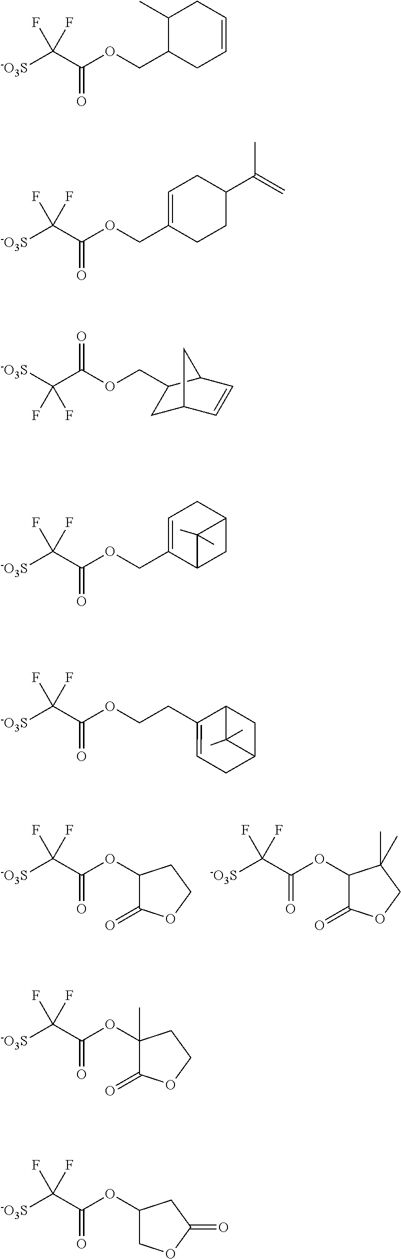

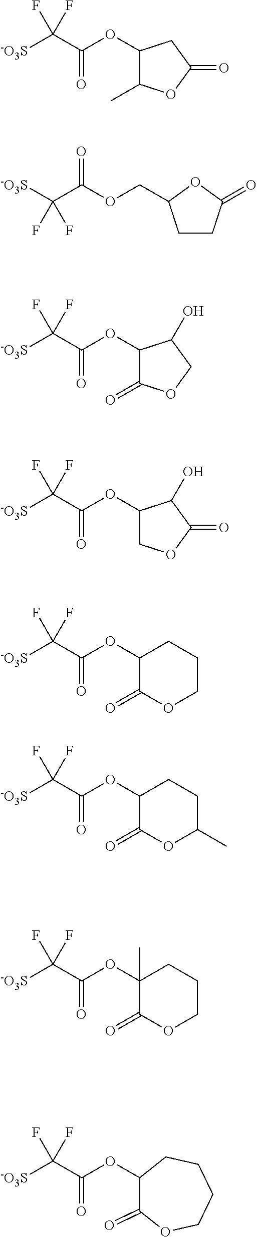

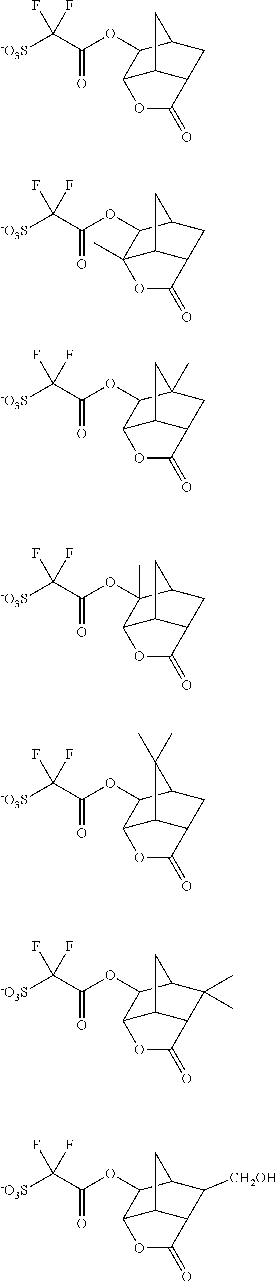

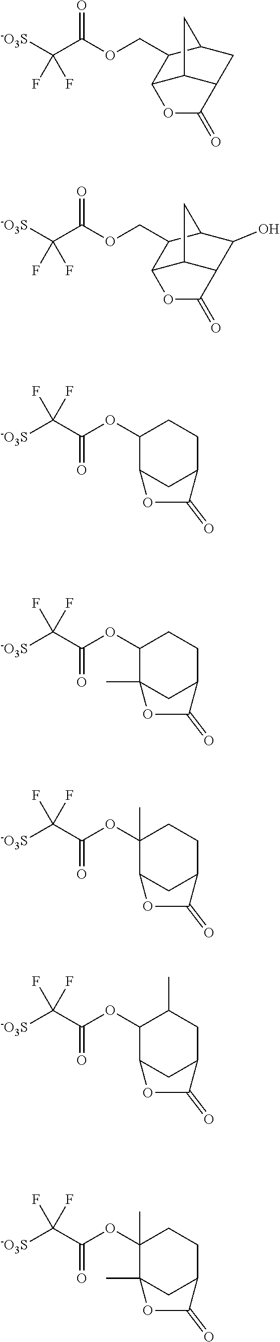

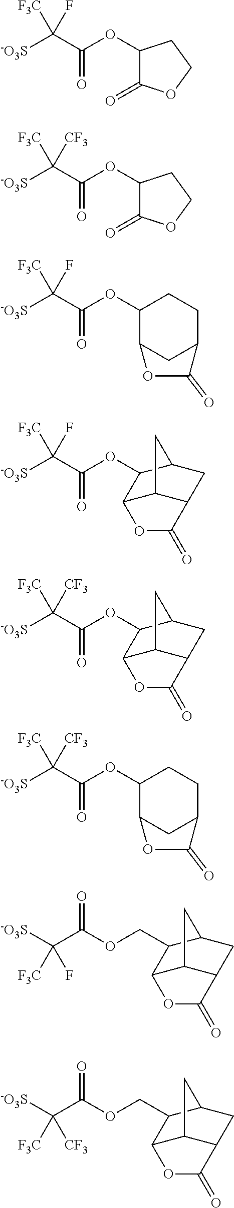

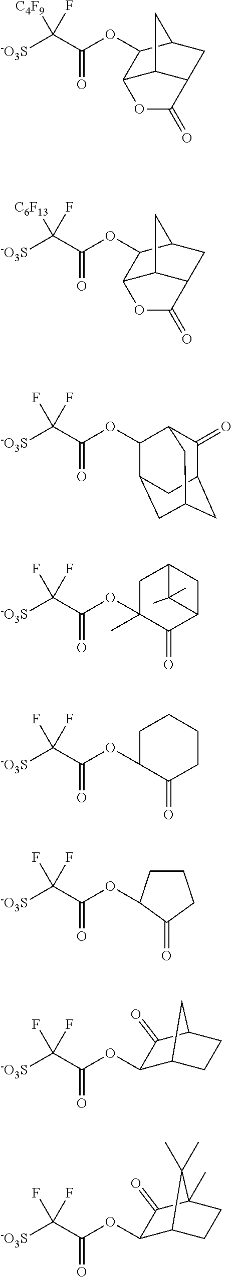

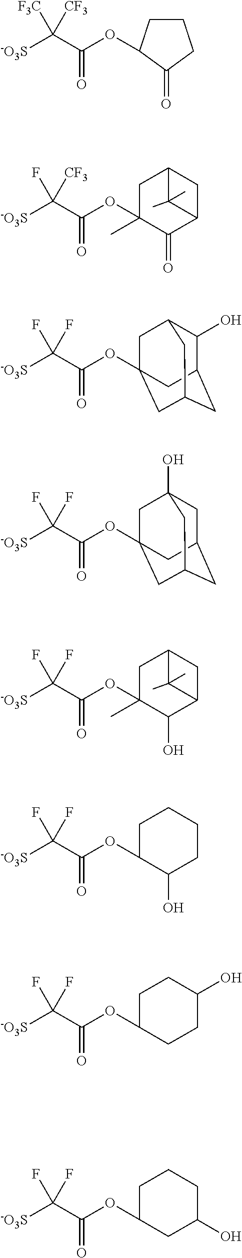

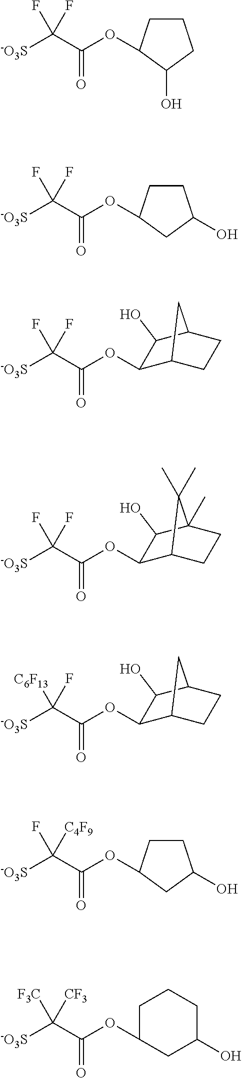

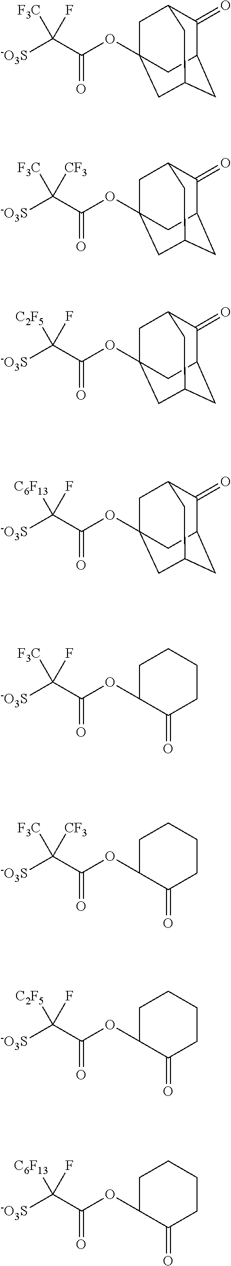

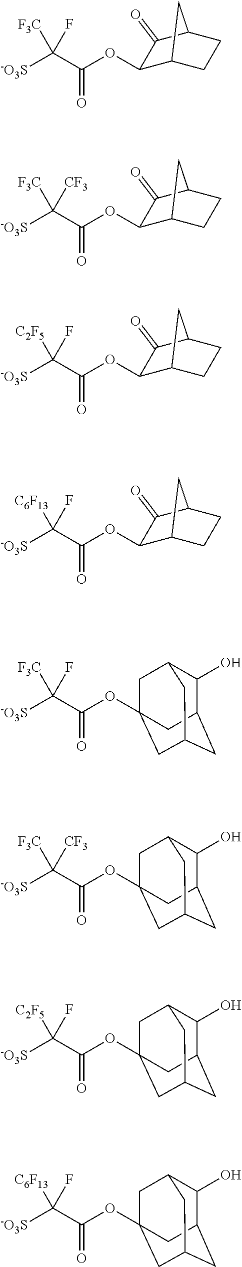

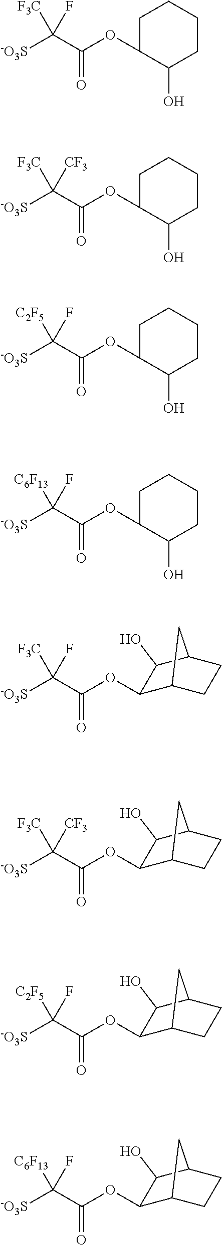

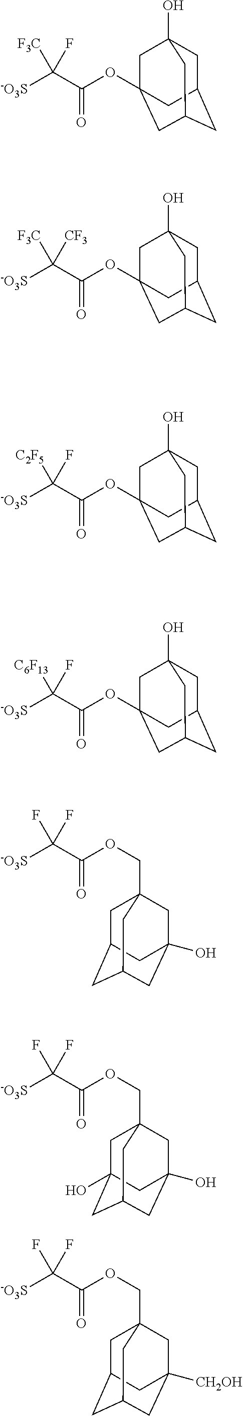

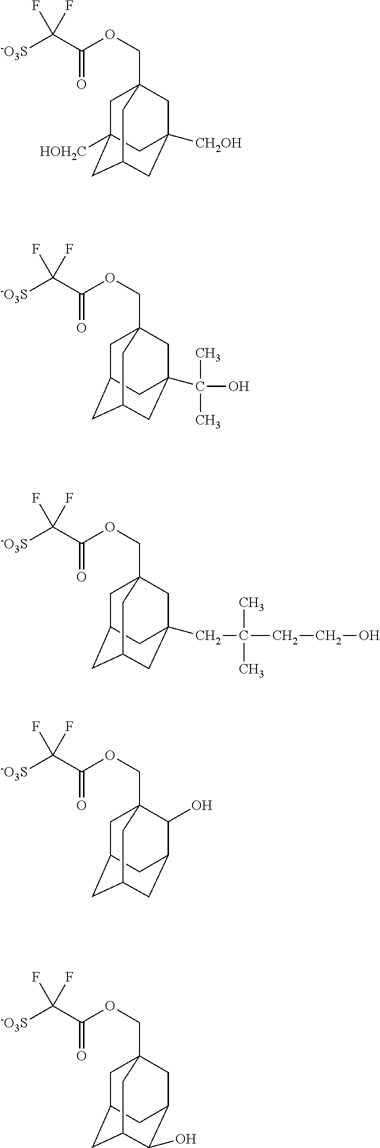

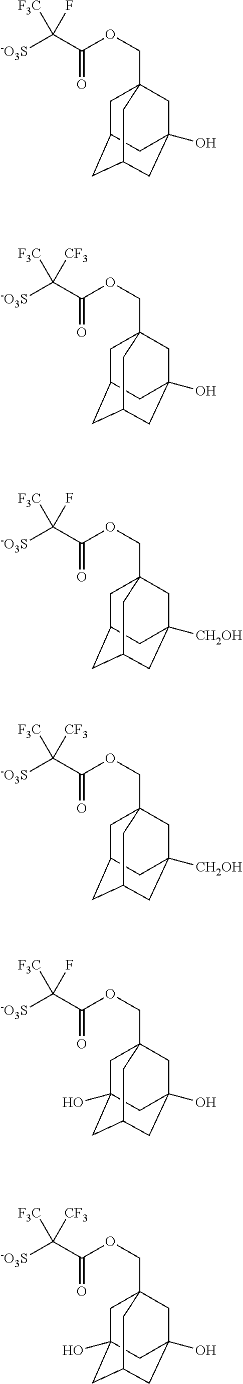

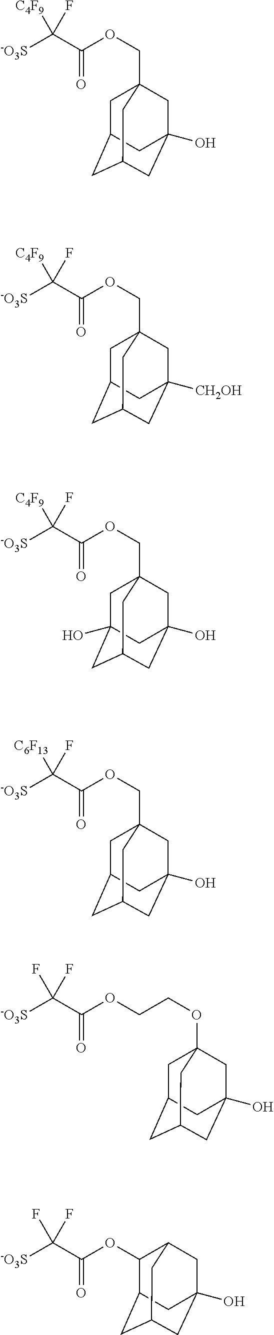

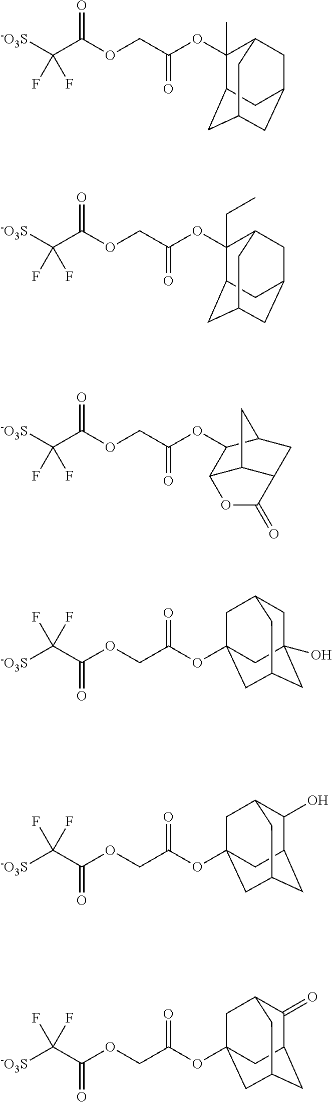

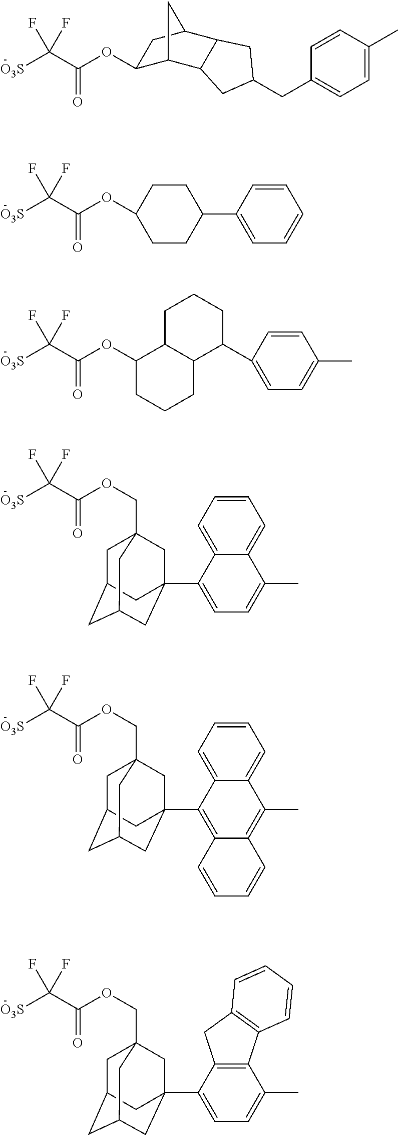

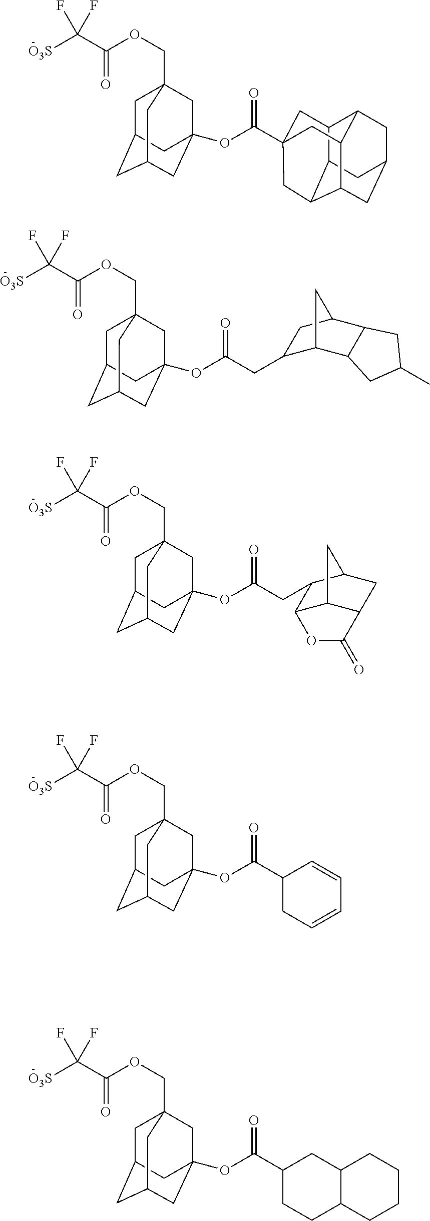

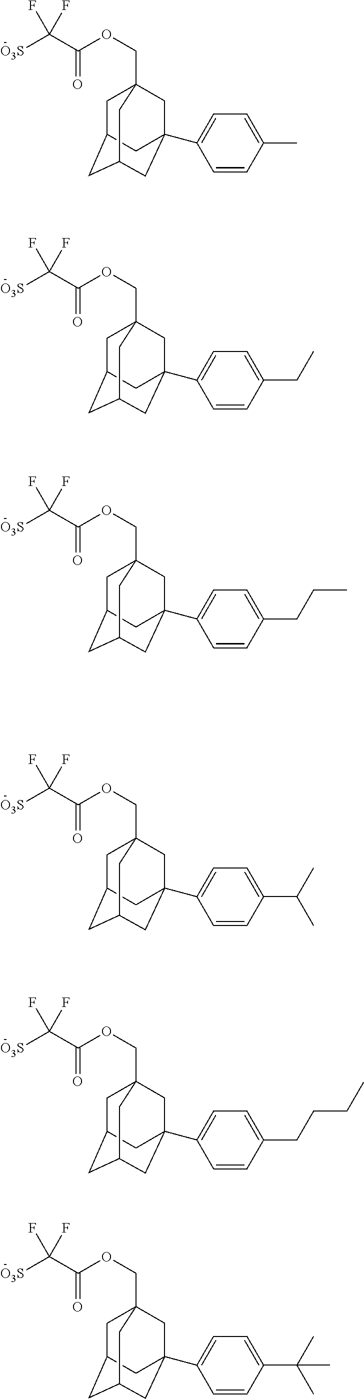

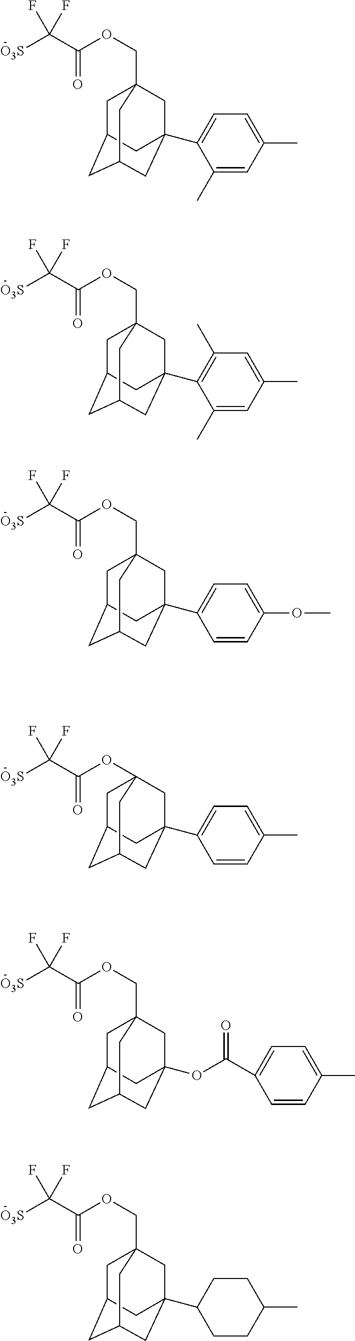

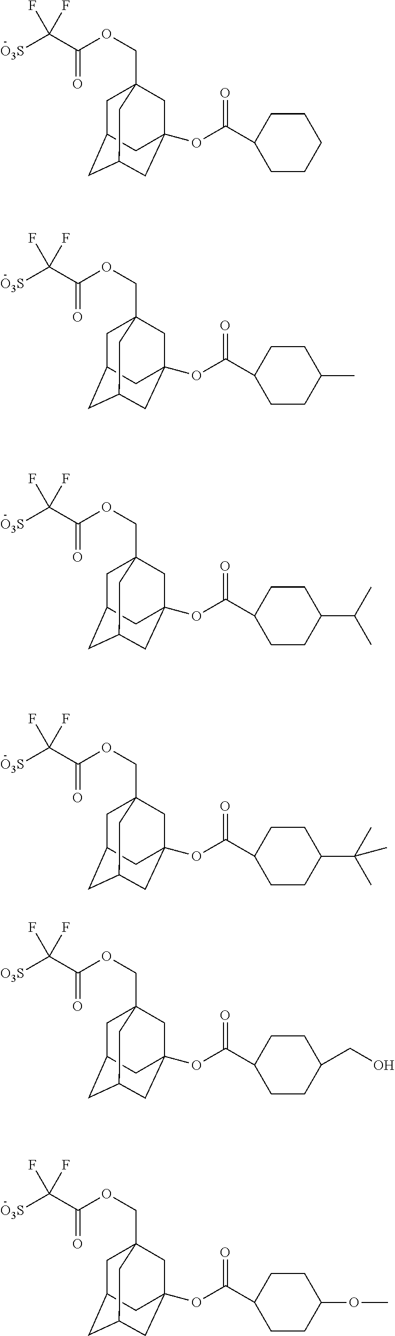

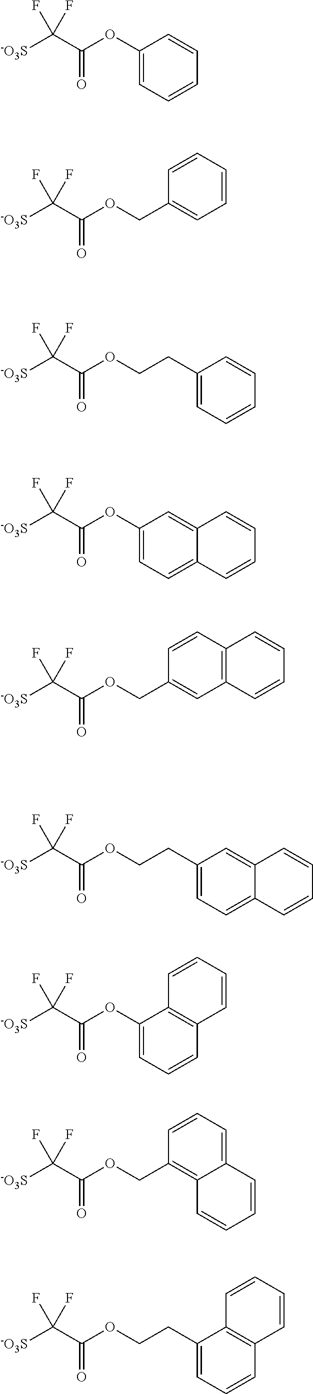

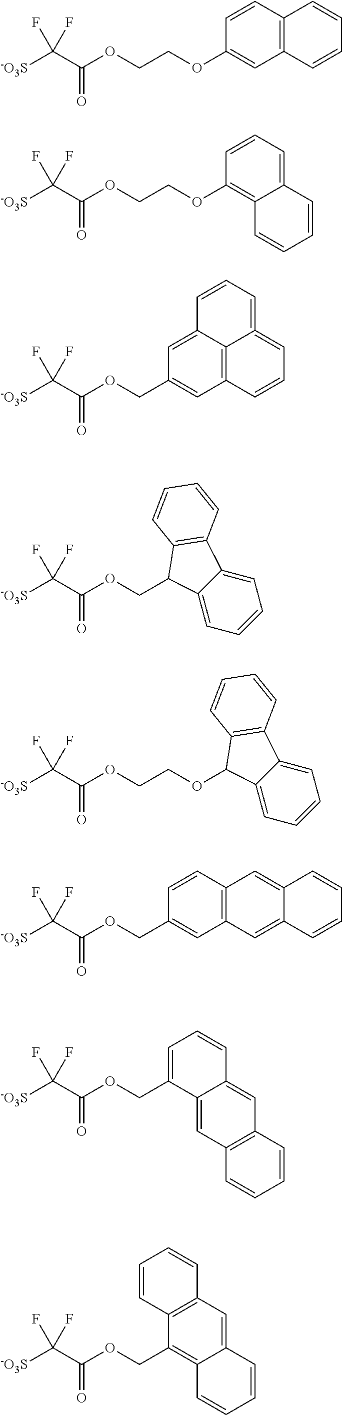

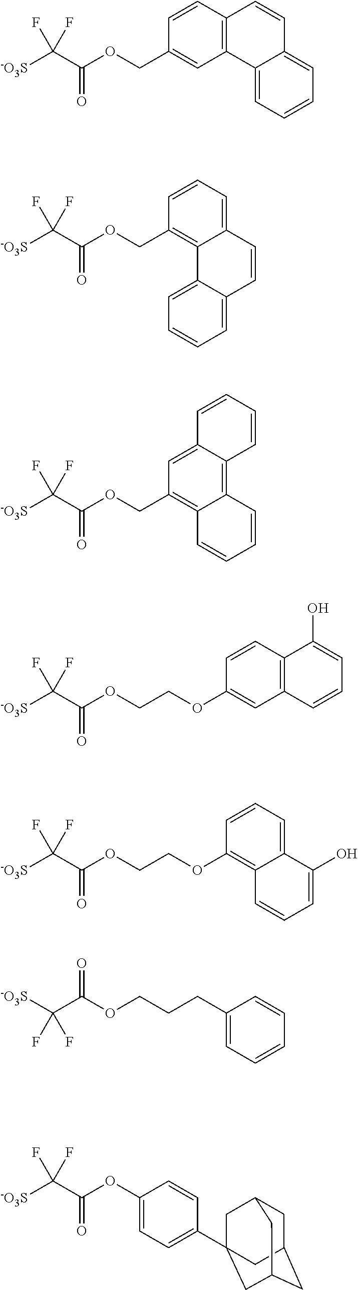

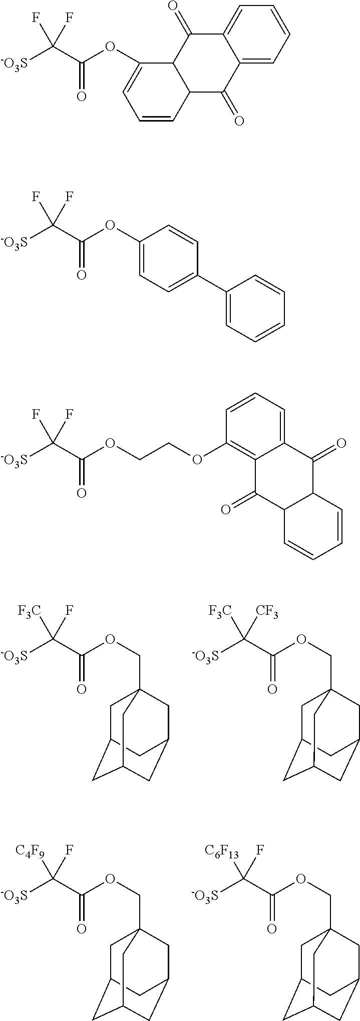

The photo acid generator may be a compound represented by the following formula (VII).

A⁺⁻O₃S—R^{b} (VII)

wherein R^{b} represents a C₁ to C₆ linear or branched chain alkyl group or a perfluoroalkyl group;

A⁺ has the same meaning as defined above.

R^{b} is preferably a C₁ to C₆ perfluoroalkyl group.

Specific examples of the anion of the formula (VII) include an ion such as trifluoromethanesulfonate, pentafluoroethanesulfonate, heptafluoropropansulfonate and perfluorobutanesulfonate.

Examples of the organic counter ion of A⁺ in the compounds represented by the formula (I), (III), (V) to (VII) include a cation represented by the formula (VIII).

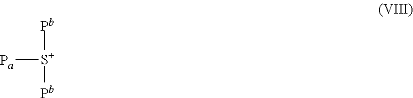

wherein P^{a} to P^{c} independently represent a C₁ to C₃₀ linear or branched chain alkyl group or a C₃ to C₃₀ cyclic hydrocarbon group; when P^{a} to P^{c} are alkyl groups, the groups may be substituted with one or more selected from the group consisting of a hydroxy group, a C₁ to C₁₂ alkoxy group, a C₃ to C₁₂ cyclic hydrocarbon group, an ether group, an ester group, a carbonyl group, a cyano group, an amino group, an amino group substituted with a C₁ to C₄ alkyl group and an amide group, when P^{a} to P^{c} are cyclic hydrocarbon groups, the groups may be substituted with at least one selected from the group consisting of a hydroxy group, a C₁ to C₁₂ alkyl group, a C₁ to C₁₂ alkoxy group, an ether group, an ester group, a carbonyl group, a cyano group, an amino group, an amino group substituted with a C₁ to C₄ alkyl group and an amide group.

In particular, the following cations represented by the formula (IIa), the formula (IIb), the formula (IIc) and the formula (IId) are exemplified.

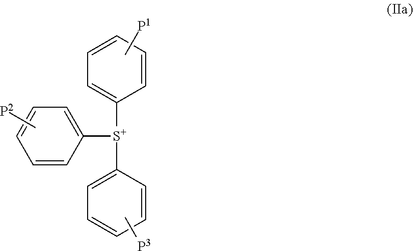

wherein P¹ to P³ independently represent a hydrogen atom, a hydroxy group, a C₁ to C₁₂ alkyl group, a C₁ to C₁₂ alkoxy group, an ether group, an ester group, a carbonyl group, a cyano group, an amino group optionally substituted with a C₁ to C₄ alkyl group and an amide group,

The alkyl group and the alkoxy group include the same examples as the above.

Among cations represented by the formula (IIa), a cation represented by the formula (IIe) is preferable due to its ease of production.

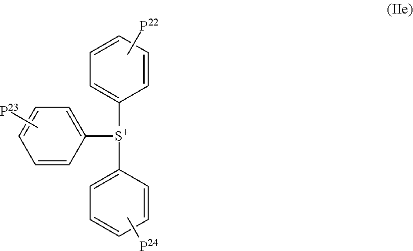

wherein P²² to P²⁴ independently represent a hydrogen atom or a C₁ to C₄ alkyl group. The alkyl group may be a linear or branched chain.

Further, the organic counter ion of A⁺ may be a cation represented by the formula (Ib) containing iodine cation.

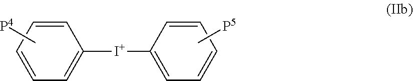

wherein P⁴ and P⁵ independently represent a hydrogen atom, a hydroxy group, a C₁ to C₁₂ alkyl group or a C₁ to C₁₂ alkoxy group.

Furthermore, the organic counter ion of A⁺ may be a cation represented by the formula (IIc).

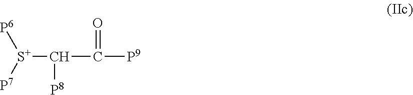

wherein P⁶ and P⁷ independently represent a C₁ to C₁₂ alkyl group or a C₃ to C₁₂ cycloalkyl group. The alkyl group may be a linear or branched chain.

Examples of the cycloalkyl group include cyclopropyl group, cyclobutyl group, cyclopentyl group, cyclohexyl group, cycloheptyl group and cyclodecyl group.

Also, P⁶ and P⁷ may be bonded together to form a C₃ to C₁₂ divalent hydrocarbon group. A carbon atom containing in the divalent hydrocarbon group can be replaced by a carbonyl group, an oxygen atom or a sulfur atom.

The divalent hydrocarbon group may be any of a saturated, unsaturated, chained or cyclic hydrocarbon. Among these, chained saturated hydrocarbon groups, and in particular, alkylene groups are preferred. Example of the alkylene group includes, for example, trimethylene, tetramethylene, pentamethylene and hexamethylene.

P⁸ represents a hydrogen atom, P⁹ represents a C₁ to C₁₂ alkyl group, a C₃ to C₁₂ cycloalkyl group or an optionally substituted aromatic group, or P⁸ and P⁹ are bonded together to form a C₃ to C₁₂ divalent hydrocarbon group.

The alkyl group, the cycloalkyl group and the divalent hydrocarbon group include the same examples as the above.

The aromatic group preferably has 6 to 20 carbon atoms, and for example, is preferably an aryl group or an aralkyl group, and more specifically, includes phenyl, tolyl, xylyl, biphenyl, naphthyl, benzyl, phenethyl and anthracenyl groups. Among these, phenyl group and benzyl group are preferred. A group which may be substituted in the aromatic group include a hydroxy group, a C₁ to C₆ alkyl group and a C₁ to C₆ hydroxyalkyl group.

Also, examples of the organic counter ion of A⁺ may be a cation represented by the formula (IId).

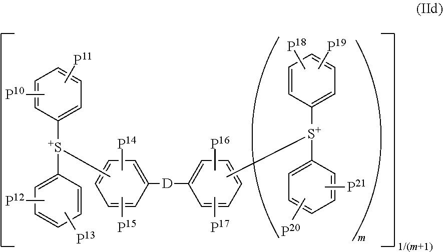

wherein P¹⁰ to P²¹ independently represent a hydrogen atom, a hydroxy group, a C₁ to C₁₂ alkyl group or a C₁ to C₁₂ alkoxy group.

The alkyl group and the alkoxy group include the same examples as the above.

D represents a sulfur atom or an oxygen atom.

m represents 0 or 1.

Specific examples of the cation A⁺ of the formula (IIa) include cations represented by the following formulae.

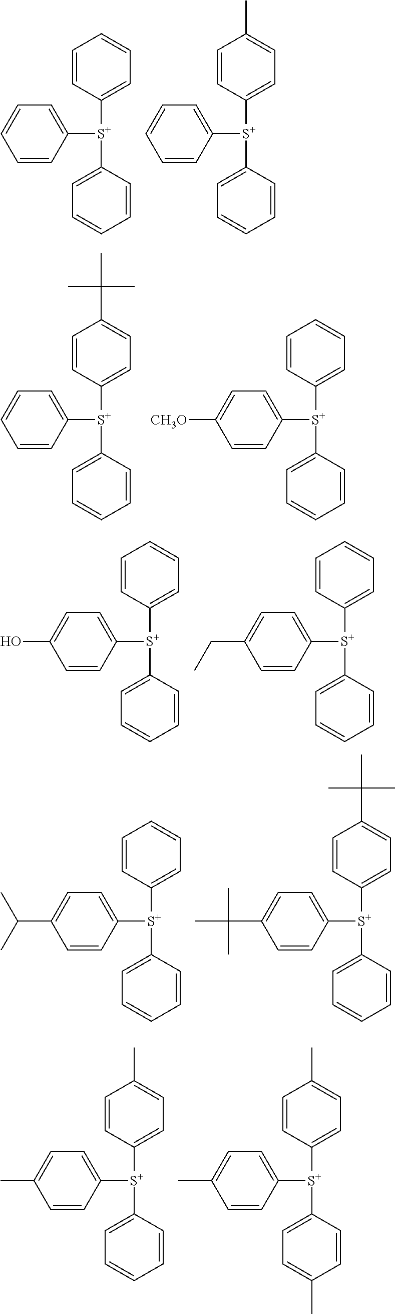

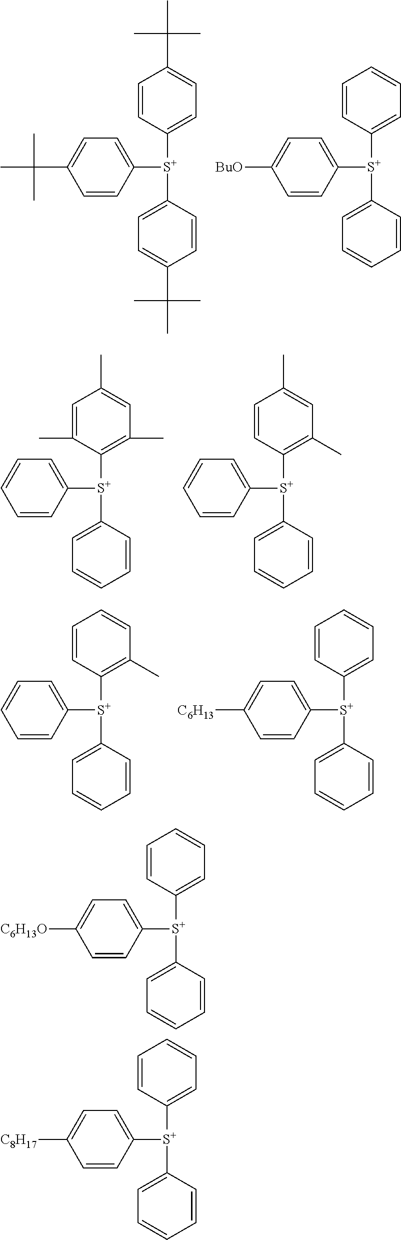

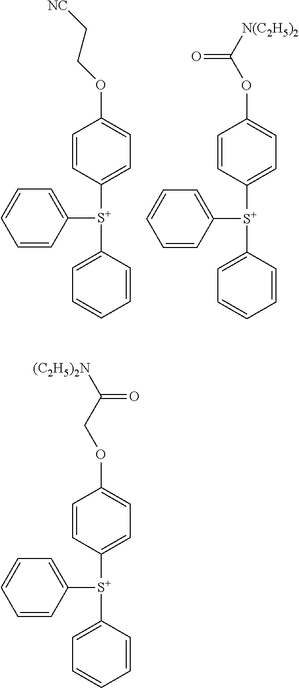

Specific examples of the cation A⁺ of the formula (IIb) include cations represented by the following formulae.

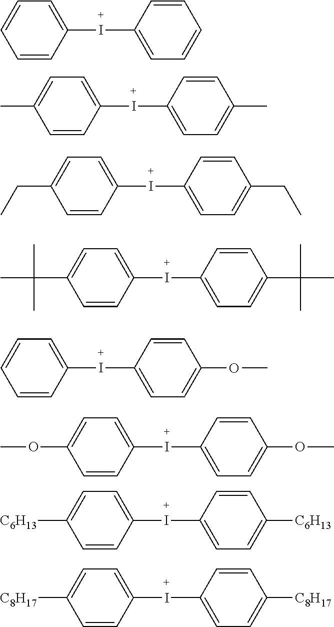

Specific examples of the cation A⁺ of the formula (IIc) include cations represented by the following formulae.

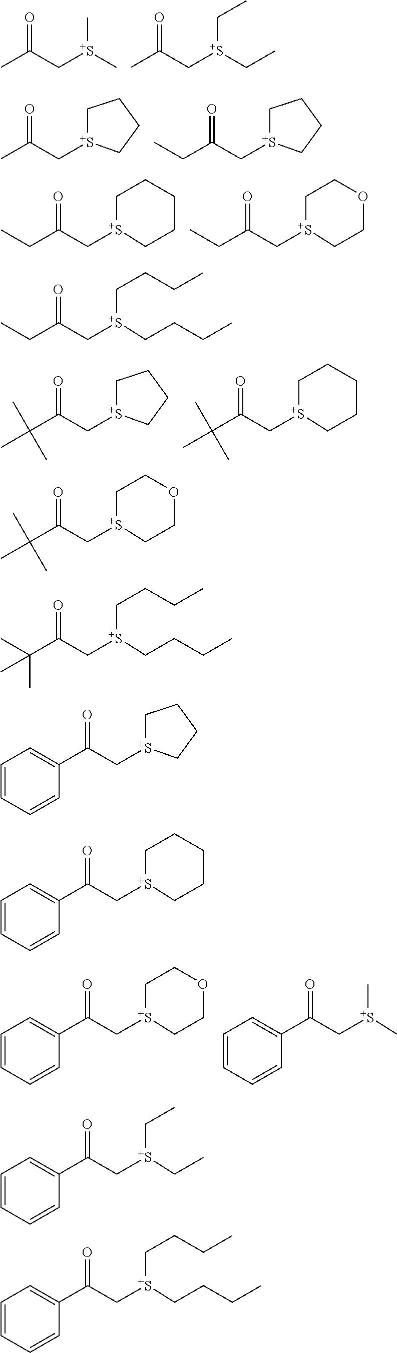

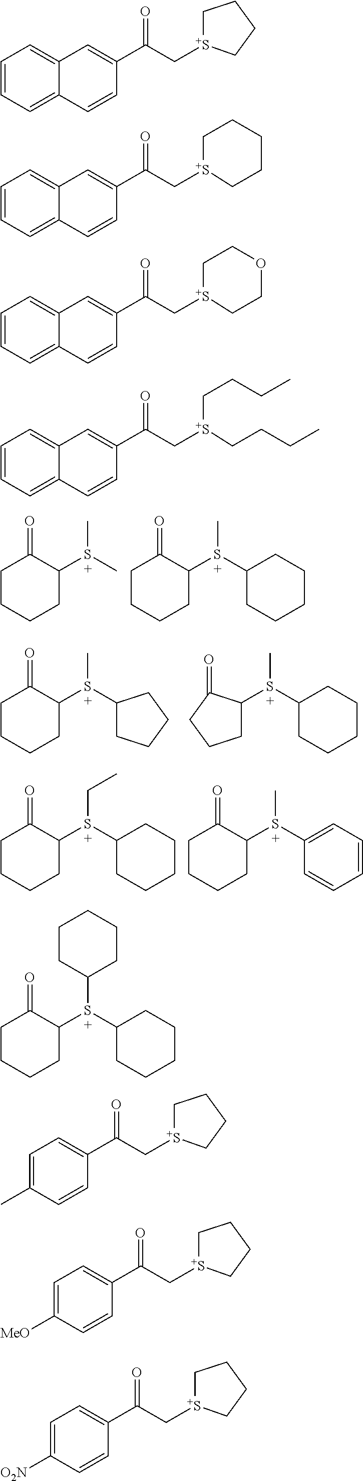

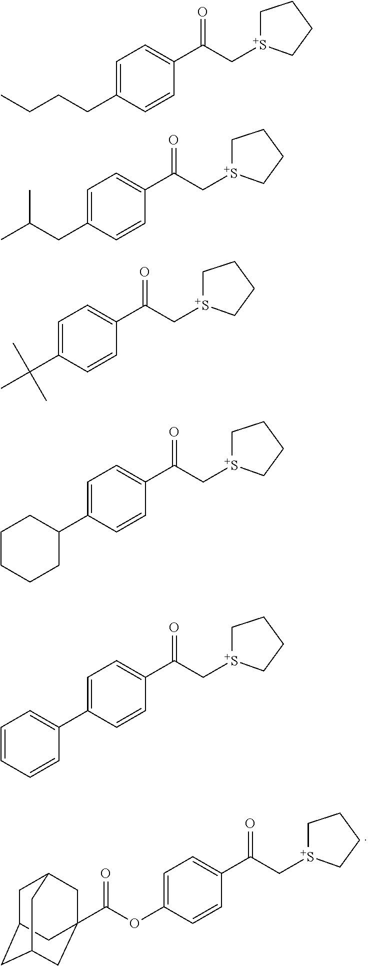

Specific examples of the cation A⁺ of the formula (IId) include cations represented by the following formulae.

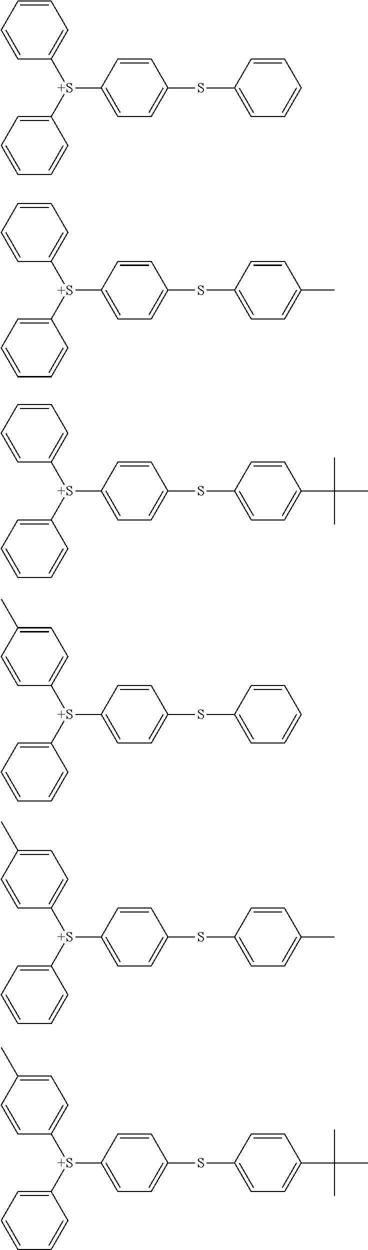

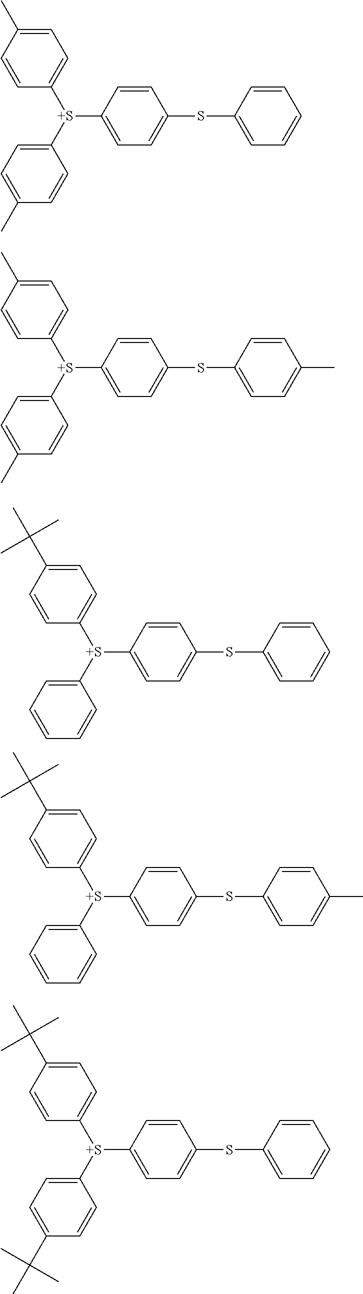

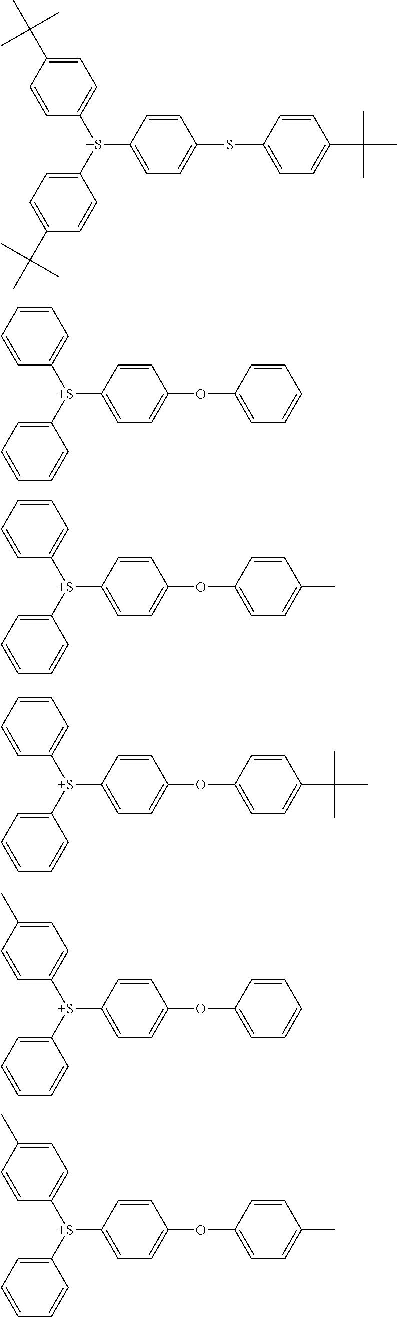

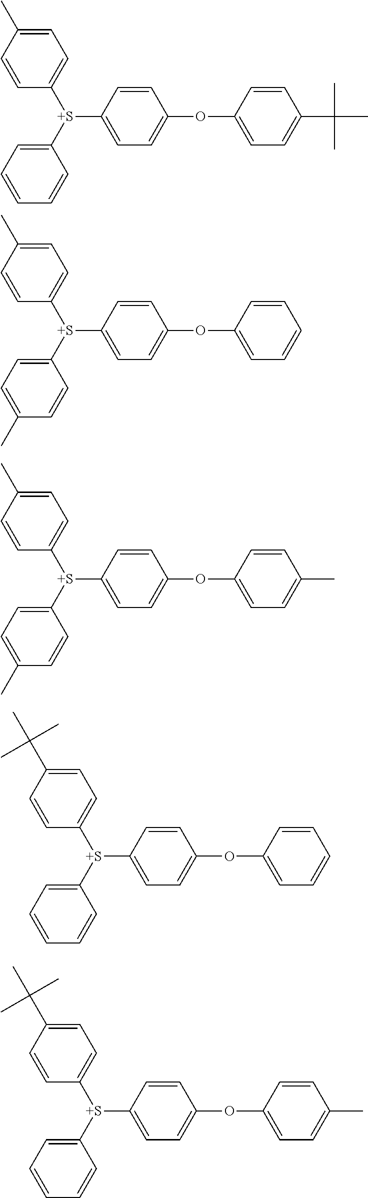

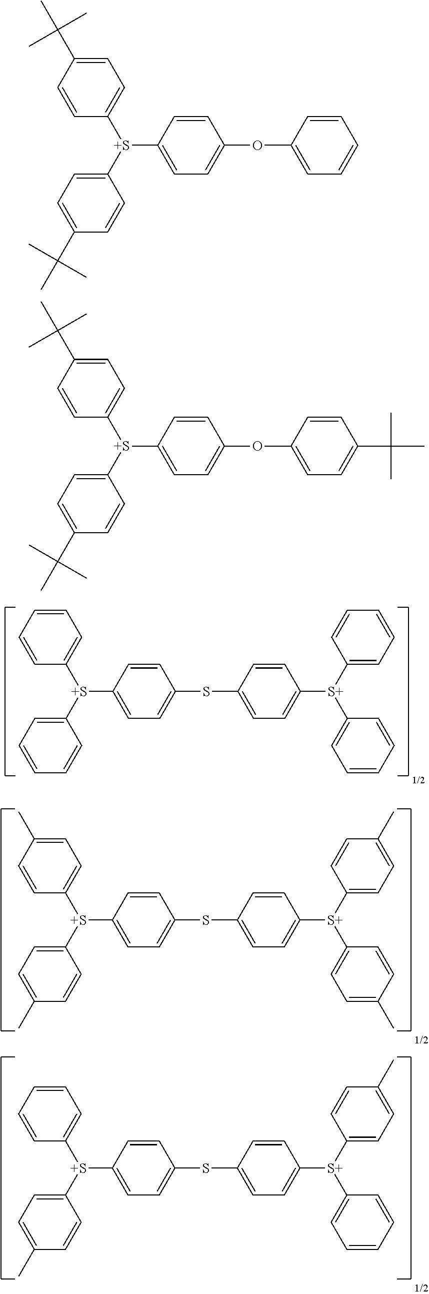

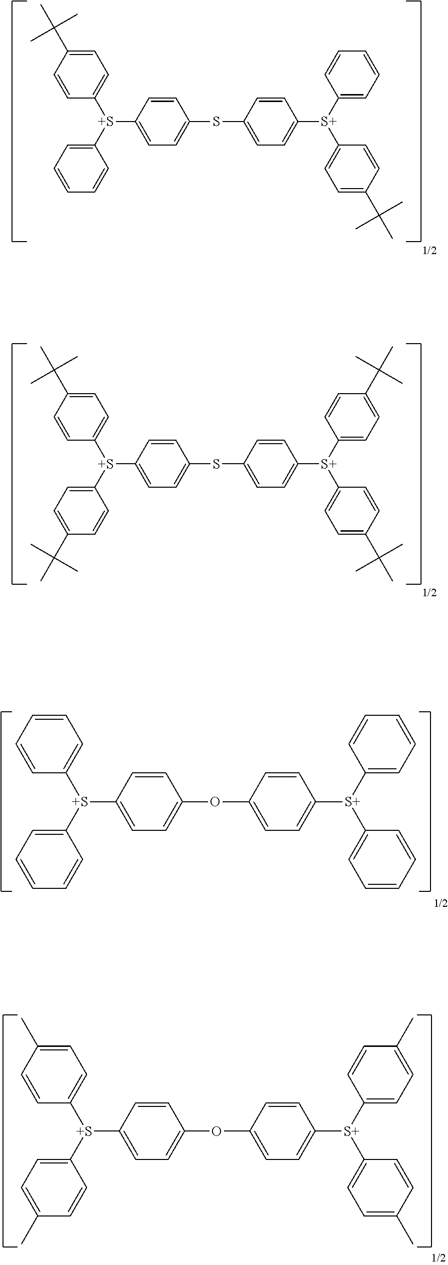

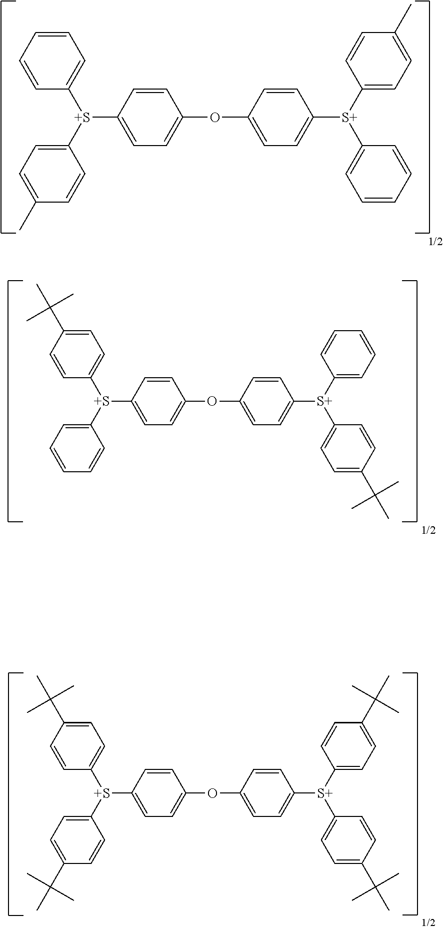

Examples of the cation A⁺ of the compound represented by the formula (I), (III), (V) to (VII) may be a cation represented by the formula (IV).

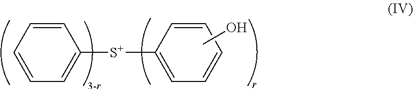

wherein r represents an integer of 1 to 3.

In the formula (IV), r is preferably 1 to 2, and most preferably 2.

There is no particular limitation on the position of bond for a hydroxy group, but it is preferably at 4-position due to their ease of availability and low cost.

Specific examples of the cation of the formula (IV) include cation represented by the following formulae.

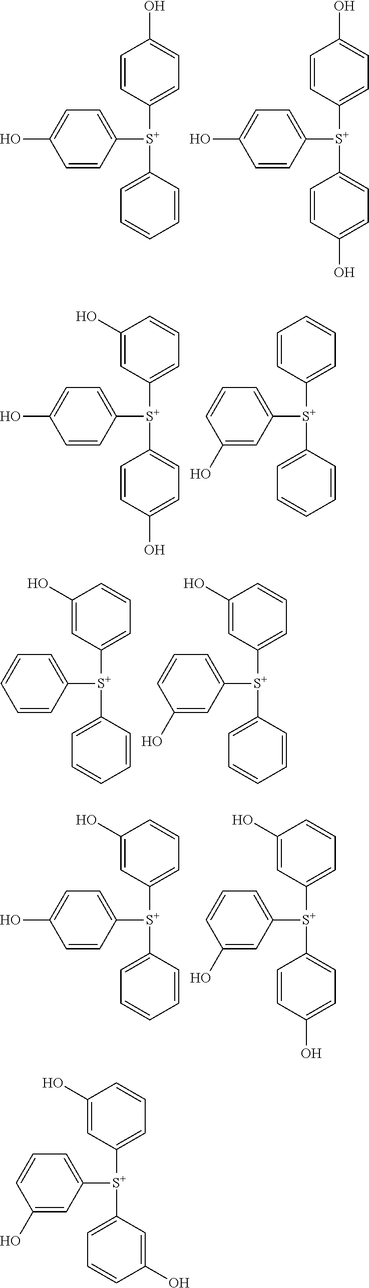

In particular, compounds represented by the formulae (IIXa) to (IXe) are preferred as the compound represented by the formula (I) or (III) of the present invention since they form a photo acid generator giving a chemically-amplified resist having an excellent pattern shape and resolution.

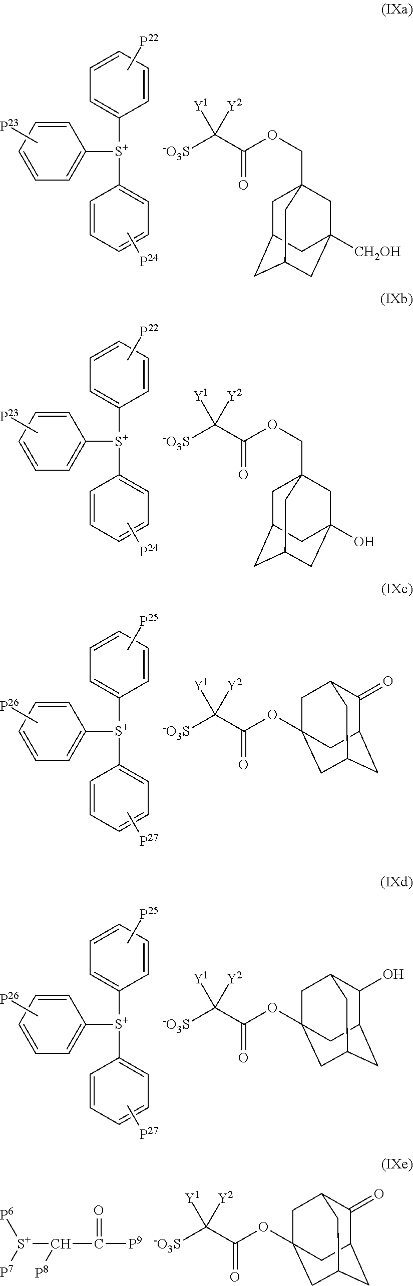

wherein, P⁶ to P⁹ and P²² to P²⁴, Y¹, Y² have the same meaning as defined above, and P²⁵ to P²⁷ independently represent a hydrogen atom or a C₁ to C₄ alkyl group.

Among these, the compounds below are suitably used due to their ease of production.

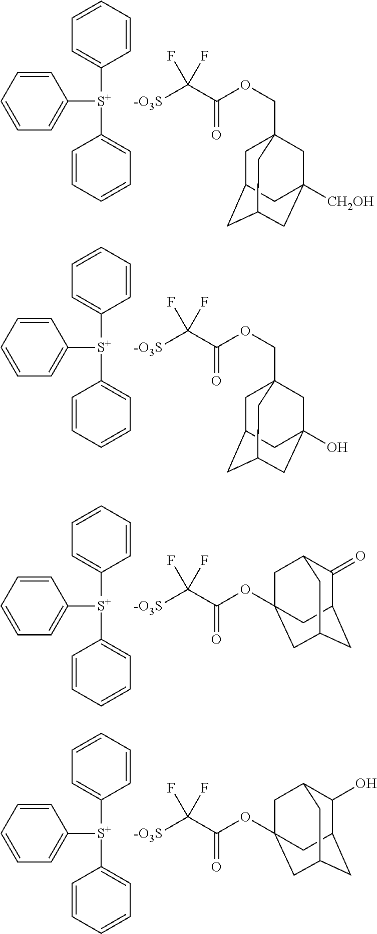

The compounds of the formulae (I), (III), (V) to (VII) can be produced, for example, using a method disclosed in JP-2006-257078-A or an according method.

In particular, the manufacturing method of the compound represented by the formula (V) or the formula (VI) includes a method by reacting a salt represented by the formula (1) or the formula (2) with an onium salt represented by the formula (3) being stirred in an inert solvent such as acetonitrile, water or methanol at a temperature in the range of about 0° C. to 150° C., and preferably 0° C. to 100° C.

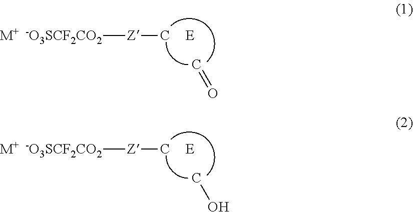

wherein Z′ and E have the same meaning as defined above, and

M represents Li, Na, K or Ag.

A⁺Z⁻ (3)

wherein A⁺ has the same meaning as defined above, and

Z represents F, Cl, Br, I, BF₄, AsF₆, SbF₆, PF₆ or ClO₄.

The onium salt of the formula (3) is generally used in an amount of about 0.5 to 2 mol with respect to 1 mol of the salt represented by the formula (1) or the formula (2).

The compound represented by the formula (V) or the formula (VI) may be purified by recrystallization or washing with water.

The salt represented by the formula (1) or the formula (2) that is used to produce the compound represented by the formula (V) or the formula (VI) can be produced, for example, by first esterification-reacting between an alcohol represented by the formula (4) or the formula (5) with a carboxylic acid represented by the formula (6).

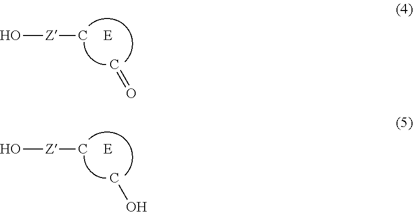

wherein E and Z′ have the same meaning as defined above.

M⁺⁻O₃SCF₂COOH (6)

wherein M has the same meaning as defined above.

As another method, the salt represented by the formula (1) or the formula (2) can be also produced, for example, by first esterification-reacting between an alcohol represented by the formula (4) or the formula (5) with a carboxylic acid represented by the formula (7), and then hydrolyzing with MOH wherein M has the same meaning as defined above.

FO₂SCF₂COOH (7)

The esterification reaction may usually be carried out by stirring in an aprotic solvent such as dichloroethane, toluene, ethyl benzene, monochlorobenzene and acetonitrile at a temperature in the range of about 20° C. to 200° C., and preferably about 50° C. to 150° C. An organic acid such as p-toluenesulfonic acid and/or an inorganic acid such as sulfuric acid is usually added as an acid catalyst during the esterification reaction.

The esterification reaction is also preferably carried out along with dehydration using a Dean-Stark device, etc., because the reaction time tends to be shorter.

The carboxylic acid represented by the formula (6) in the esterification reaction is generally used in an amount of about 0.2 to 3 mol, and preferably about 0.5 to 2 mol, with respect to 1 mol of the alcohol represented by the formula (4) or the formula (5). The amount of the acid catalyst in the esterification reaction may be a catalytic amount or an amount corresponding to the solvent, and is usually about 0.001 to 5 mol.

There are also methods for obtaining salts represented by the formula (VI) or the formula (2) by reducing the salt represented by the formula (V) or the formula (1).

The reducing reaction can be brought about using a reducing agent, including borohydrides such as sodium borohydride, zinc borohydride, lithium tri-sec-butyl borohydride and borane; aluminum hydrides such as lithium tri-t-butoxyaluminum hydride and diisobutylaluminum hydride; organosilicon hydrides such as Et₃SiH and Ph₂SiH₂; or organotin hydrides such as Bu₂SnH, in a solvent such as water, alcohol, acetonitrile, N,N-dimethyl formamide, diglyme, tetrahydrofuran, diethyl ether, dichloromethane, 1,2-dimethoxyethane, or benzene. The reaction may be brought about while stirred at a temperature in the range from about −80° C. to 100° C., and preferably about −10° C. to 60° C.

Photo acid generators shown in (B1) and (B2) below may be used as the photo acid generator (B).

(B1) is not particularly limited as long as a hydroxy group is present in the cation and an acid is produced by exposure. Such cations include those represented by formula (IV) above.

The anion in (B1) is not particularly limited and for example known anions as an onium salt type acid generator may be suitably used.

For example, an anion represented by the formula (X-1), formula (X-2), (X-3) or (X-4).

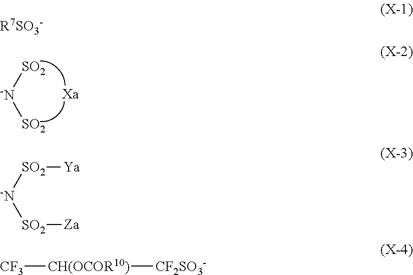

wherein R⁷ is a linear or branched chain, or cyclic alkyl group or a fluoroalkyl group;

Xa represents a C₂ to C₆ alkylene group in which at least one hydrogen atom is substituted by a fluorine atom;

Ya and Za independently represent a C₁ to C₁₀ alkyl group in which at least one hydrogen atom is substituted by a fluorine atom;

R¹⁰ is a substituted or non-substituted linear or branched chain, or cyclic C₁ to C₂₀ alkyl group, or a substituted or non-substituted C₆ to C₁₄ aryl group can be used.

The linear or branched chain alkyl group preferably has 1 to 10 carbon atoms, more preferably 1 to 8 carbon atoms, and most preferably 1 to 4 carbon atoms.

The cyclic alkyl group, R⁷ preferably has 4 to 15 carbon atoms, more preferably 4 to 12 carbon atoms, and still more preferably 4 to 10, 5 to 10, and 6 to 10 carbon atoms.

The fluoroalkyl group preferably has 1 to 10 carbon atoms, more preferably 1 to 8 carbon atoms, and most preferably 1 to 4 carbon atoms.

The rate of fluorination of the fluoroalkyl group (the proportion of the number of fluorine atoms substituted by fluorination relative to the total number of hydrogen atoms in the alkyl group prior to fluorination, same hereafter) is preferably 10 to 100%, and more preferably 50 to 100% and, in particular, all hydrogen atoms substituted by fluorine atoms is preferred since the strength of the acid is increased.

R⁷ is more preferably a linear chain or cyclic alkyl group, or a fluorinated alkyl group.

In the formula (X-2), Xa represents a linear or branched chain alkylene group in which at least one hydrogen atom is substituted by a fluorine atom. The number of carbon atoms in the alkylene group is preferably 2 to 6, more preferably 3 to 5 carbon atoms, and most preferably 3 carbon atoms.

In the formula (X-3), Ya, Za independently represent a linear or branched chain alkyl group in which at least one hydrogen atom is substituted by a fluorine atom. The number of carbon atoms in the alkyl group is preferably 1 to 10, more preferably 1 to 7 carbon atoms, and most preferably 1 to 3 carbon atoms.

The number of carbon atoms in the alkylene group Xa or the number of carbon atoms in the alkyl group Ya, Za is preferably as small as possible within the above scope of the carbon atoms due reasons such as a preferred effect on the solubility in the resist solvent and the like.

The strength of the acid is increased as the number of hydrogen atoms substituted by fluorine atoms increases in the alkylene group Xa or the alkyl group Ya, Za, and is preferred due to an improvement in transparency to high-energy light of 200 nm or less or an electron beam. The fluorination rate of the alkylene group or the alkyl group is preferably 70 to 100%, more preferably 90 to 100% and most preferably is a perfluoroalkylene group or a perfluoroalkyl group in which all hydrogen atoms are substituted by fluorine atoms.

Examples of the aryl group include phenyl, tolyl, xylyl, cumenyl, mesityl, naphthyl, biphenyl, anthryl and phenanthryl.

Examples of the substituent which may be substituted alkyl or aryl group include, for example, one or more substituent selected from a group consisting of a hydroxy group, a C₁ to C₁₂ alkyl group, a C₁ to C₁₂ alkoxy group, an ether group, an ester group, a carbonyl group, a cyano group, an amino group, an amino group substituted with a C₁ to C₄ alkyl group and an amide group.

The anion of (B1) includes the anion represented by A⁺ in formula (I) or the like.

(B1) is preferably has an anion represented by the formula (X-1) described above, and in particular, one in which R⁷ is a fluorinated alkyl group is preferred.

For example, specific examples of the formula (B1) include the photo acid generator represented by the following formula.

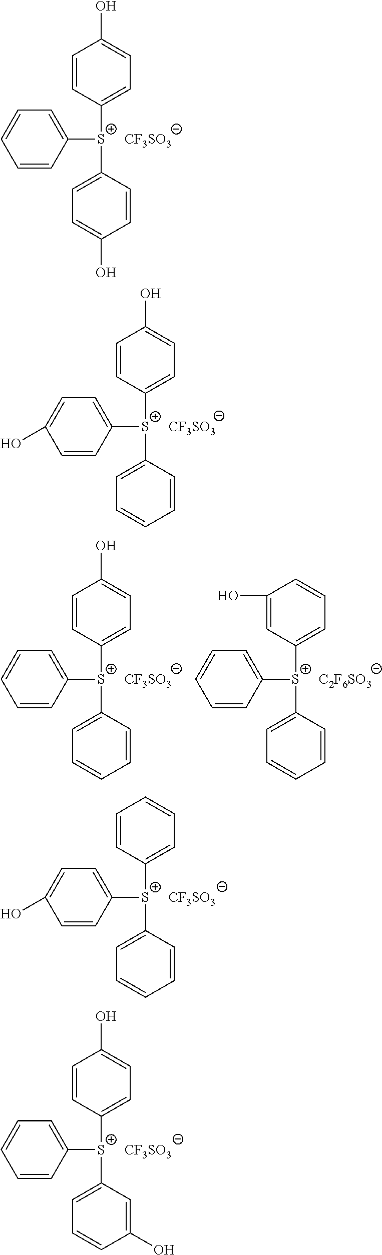

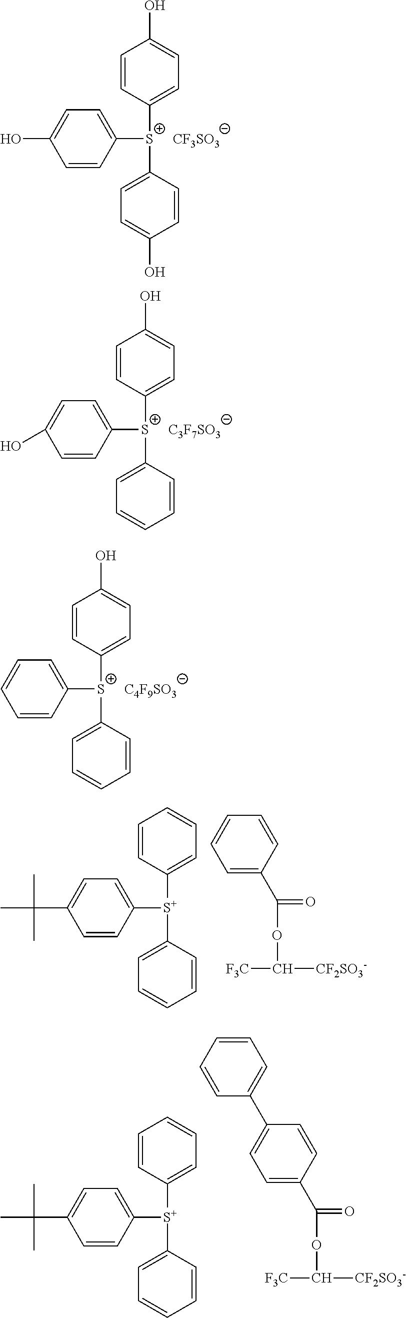

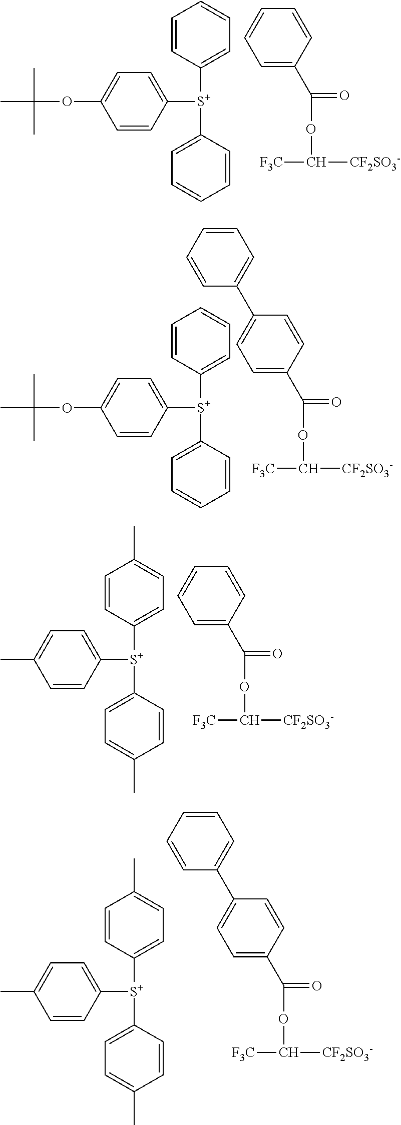

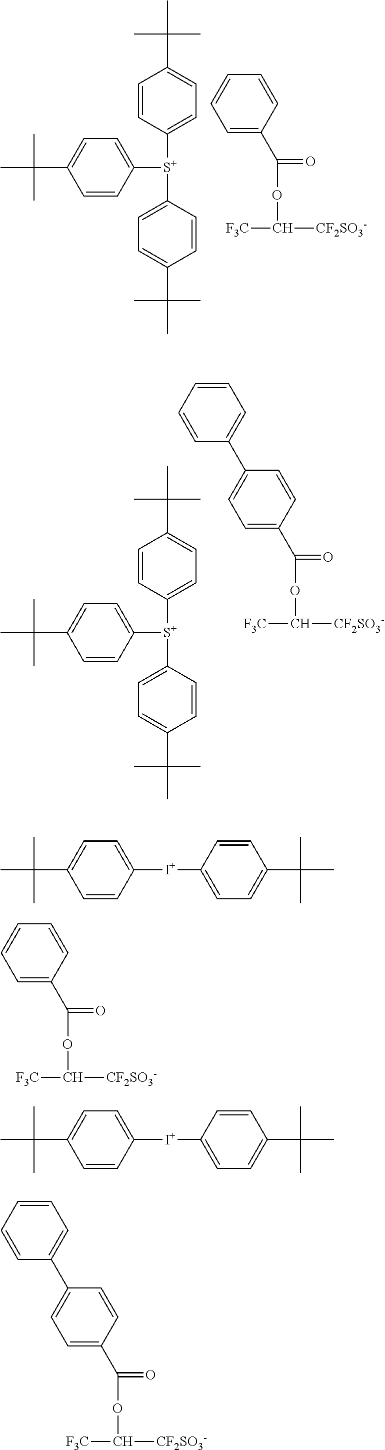

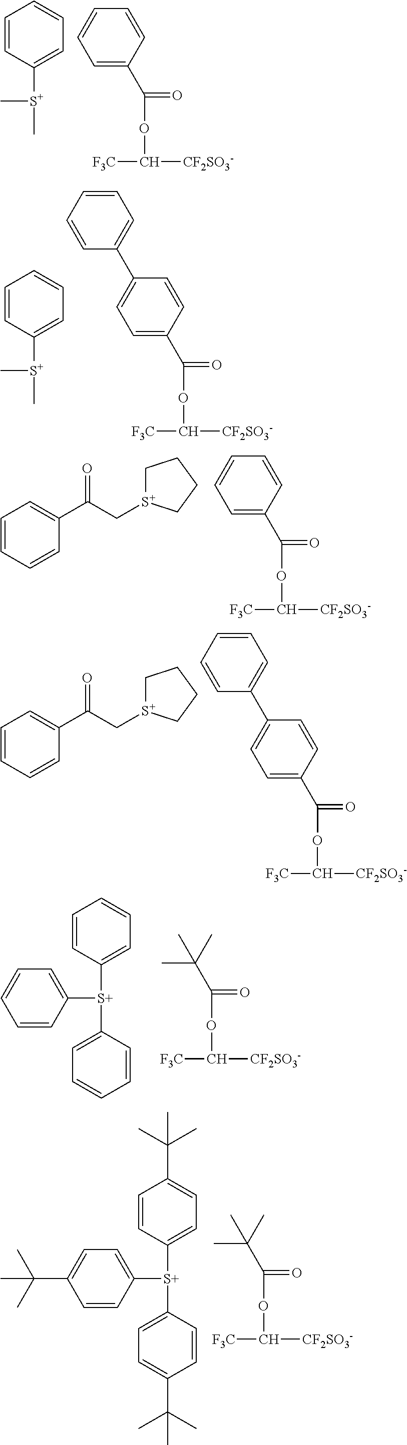

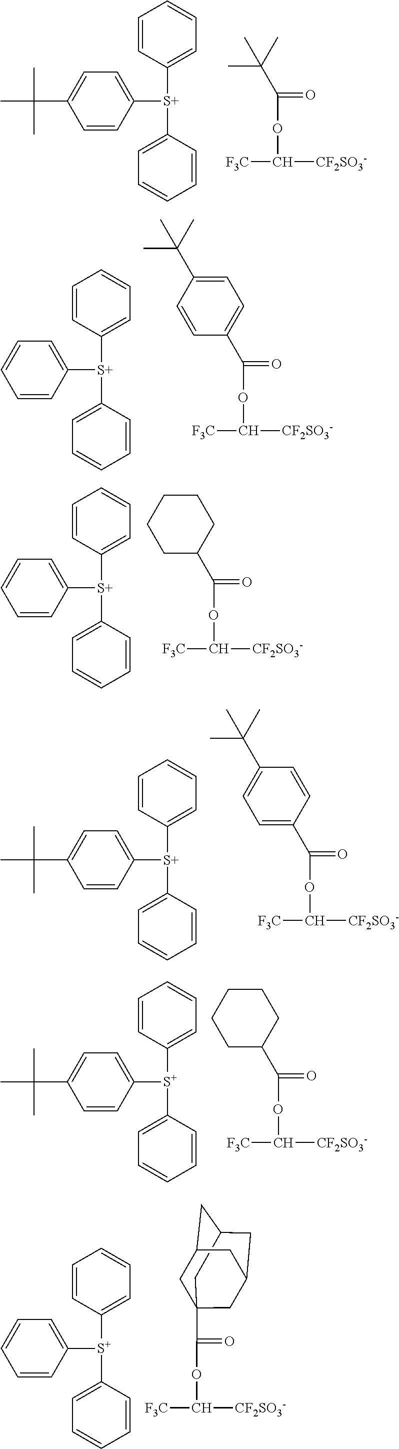

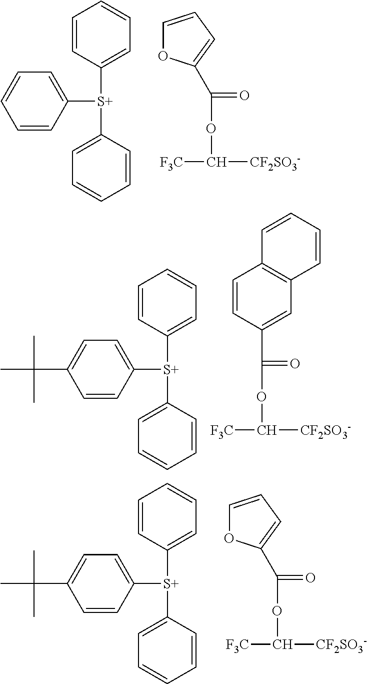

There is no particular limitation on (B2) as long as the cation does not include a hydroxy group, and any compound proposed as an acid generator for a chemically-amplified resist may be used.

Examples of such acid generator includes a variety of acid generators, an onium salt type acid generator such as an iodonium salt and a sulfonium salt; an oxime sulfonate type add generator; a diazomethane type acid generator such as bisalkyl or bisaryl sulfonyl diazomethane or poly(bis-sulfonyl)diazomethane; a nitrobenzyl sulfonate acid generator, an iminosulfonate acid generator and a disulfone acid generator.

An onium salt acid generator for example may preferably used an acid generator as represented by the formula (XI).

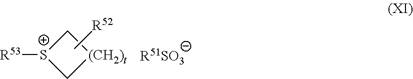

wherein R⁵¹ represents a linear or branched chain, or cyclic alkyl group or a linear or branched chain, or cyclic fluoroalkyl group;

R⁵² represents a hydrogen atom, a hydroxy group, a halogen atom, a linear or branched chain alkyl group, a linear or branched chain halogenated alkyl group, or a linear or branched chain alkoxy group;

R⁵³ represents an optionally substituted aryl group;

t represents an integer of 1 to 3.

In the formula (XI), R⁵¹ can have the same carbon atom number and fluorination rate as the substituent R⁷ described above.

R⁵¹ is most preferably a linear chain alkyl group or a fluoroalkyl group.

Examples of the halogen atom include fluorine atom, bromine atom, chlorine atom or iodine atom, and fluorine atom is preferred.

In R⁵², the alkyl group is a group in which it is linear or branched chain and preferably has 1 to 5 carbon atoms, and in particular 1 to 4, and more preferably 1 to 3.

In R⁵², the halogenated alkyl group is a group in which a part or all of the hydrogen atoms in the alkyl group are substituted by halogen atoms. The alkyl group and the substituting halogen atoms are the same examples as the above. In the halogenated alkyl group, 50 to 100% of all of the hydrogen atoms are preferably substituted by halogen atoms, and substitution of all atoms is more preferred.

In R⁵², the alkoxy group is a group in which it is linear or branched chain and preferably has 1 to 5 carbon atoms, and in particular 1 to 4, and more preferably 1 to 3.

Among these, R⁵² is preferably a hydrogen atom.

From the point of view of absorption of exposure light such as an ArF excimer laser, R⁵³ is preferably a phenyl group.

Examples of the substituent in the aryl group include a hydroxy group, a lower alkyl group (linear or branched chain, for example, with 1 to 6 carbon atoms, more preferably 1 to 4 carbon atoms, and in particular a methyl group is preferred), a lower alkoxy group.

The aryl group of R⁵³ more preferably does not include a substituent

t is an integer of 1 to 3, 2 or 3 are preferred and in particular, 3 is desirable.

Specific examples of the acid generator represented by the formula (XI) include the following compounds.

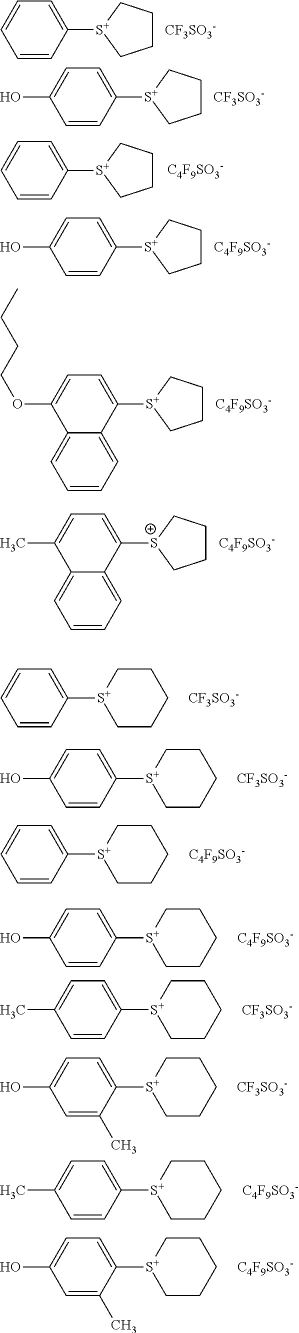

Acid generators represented by the formula (XII) and (XIII) may be used as the onium salt acid generator.

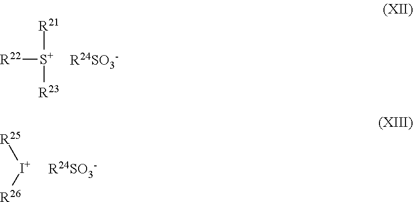

wherein R²¹ to R²³ and R²⁵ to R²⁶ independently represent an aryl group or an alkyl group;

R²⁴ represents a linear or branched chain, or cyclic alkyl group or fluorinated alkyl group;

at least one of R²¹ to R²³ is an aryl group, at least one of R²⁵ to R²⁶ is an aryl group.

Two or more of R²¹ to R²³ are preferably aryl groups, and it is most preferred that all of R²¹ to R²³ are aryl groups.

The aryl group of R²¹ to R²³ is, for example, a C₆ to C₂₀ aryl group. A part or all of the hydrogen atoms in the aryl group may be substituted with an alkyl group, an alkoxy group or a halogen atom. The aryl group is preferably a C₆ to C₁₀ aryl group in view of cost-effective synthesis. Specific examples include a phenyl group and naphtyl group.

The alkyl group which may substitute for the hydrogen atom in the aryl group is preferably a C₁ to C₅ alkyl group, and most preferably methyl group, ethyl group, propyl group, n-butyl group and tert-butyl group.

The alkoxy group which may substitute for the hydrogen atom in the aryl group is preferably a C₁ to C₅ alkoxy group, and most preferably methoxy group or ethoxy group.

The halogen atom which may substitute for the hydrogen atom in the aryl group is preferably a fluorine atom.

The alkyl group in R²¹ to R²³ is, for example, a C₁ to C₁₀ linear or branched chain, or cyclic alkyl group. From the point of view of excellent resolution characteristics, C₁ to C₅ is preferred. Specific examples include methyl group, ethyl group, n-propyl group, iso-propyl group, n-butyl group, isobutyl group, n-pentyl group, cylopentyl group, hexyl group, cyclohexyl group, nonyl group and decanyl group. The methyl group is preferably in view of excellent resolution and cost-effective synthesis.

Among these, R²¹ to R²³ are most preferably a phenyl group or a naphtyl group, respectively.

R²⁴ includes the same groups as mentioned in the above R⁷.

It is preferred that all of R²⁵ to R²⁶ are aryl groups.

Among these, it is most preferred that all of R²⁵ to R²⁶ are phenyl groups.

Example of the onium salt type acid generator represented by the formula (XII) and the formula (XIII) include;

diphenyliodonium trifluoromethanesulfonate or nonafluorobutanesulfonate,

bis(4-tert-butylphenyl)iodonium trifluoromethanesulfonate or nonafluorobutanesulfonate,

triphenylsulfonium trifluoromethanesulfonate, its heptafluoropropanesulfonate or its nonafluorobutanesulfonate,

tri(4-methylphenyl)sulfonium trifluoromethanesulfonate, its heptafluoropropanesulfonate or its nonafluorobutanesulfonate,

dimethyl(4-hydroxynaphtyl)sulfonium trifluoromethanesulfonate, its heptafluoropropanesulfonate or its nonafluorobutanesulfonate,

monophenyldimethylsulfonium trifluoromethanesulfonate, its heptafluoropropanesulfonate or its nonafluorobutanesulfonate,

diphenylmonomethylsulfonium trifluoromethanesulfonate, its heptafluoropropanesulfonate or its nonafluorobutanesulfonate,

(4-methylphenyl)diphenylsulfonium trifluoromethanesulfonate, its heptafluoropropanesulfonate or its nonafluorobutanesulfonate,

(4-methoxyl phenyl)diphenylsulfonium trifluoromethanesulfonate, its heptafluoropropanesulfonate or its nonafluorobutanesulfonate,

tri(4-tert-butyl)phenylsulfonium trifluoromethanesulfonate, its heptafluoropropanesulfonate or its nonafluorobutanesulfonate,

diphenyl(1-(4-methoxy)naphtyl)sulfonium trifluoromethanesulfonate, its heptafluoropropanesulfonate or its nonafluorobutanesulfonate,

di(1-naphtyl)phenylsulfonium trifluoromethanesulfonate, its heptafluoropropanesulfonate or its nonafluorobutanesulfonate,

1-(4-n-butoxynaphtyl)tetrahydrothiophenium perfulorooctanesulfonate, its 2-bicyclo[2.2.1]hept-2-yl-1,1,2,2-tetrafuluoroethanesulfonate, and

N-nonafluorobutansulfonyloxybicyclo[2.2.1]hept-5-ene-2,3-dicarboxylmide.

These onium salts in which an anion is replaced by methansulfonate, n-propanesurfonate, n-butanesulfonate, n-octanesulfonate can be also used.

In the formula (XII) or (XIII), an onium salt type acid generator in which anion is replaced by an anion represented by the formulae (X-1) to (X-3) can be also used.

The following compounds may be also used.

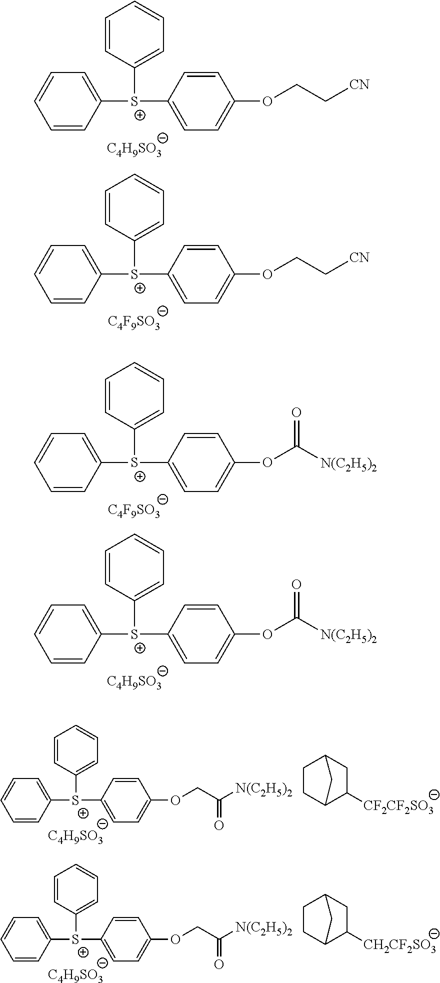

An oxime sulfonate type acid generator is a compound having at least one group represented by the formula (XIV) and is characterized by producing an acid as a result of irradiation with radiation. This type of oxime sulfonate type acid generator, which is often used as a composition for a chemically-amplified resist, may optionally be also used.

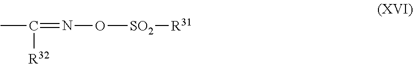

Wherein, R³¹ and R³² independently represent an organic group.

The organic groups of R³¹, R³² are groups which contain carbon atoms, and may include atoms other than carbon atoms, for example, a hydrogen atom, an oxygen atom, a nitrogen atom, a sulfur atom, a halogen atom.

The organic group R³¹ is preferably a linear or branched chain, or cyclic alkyl or aryl group. The alkyl and aryl groups may include a substituent. There is no particular limitation on the substituent, and for example, it may be a fluorine atom, a C₁ to C₆ linear or branched chain, or cyclic alkyl group.

The alkyl group preferably includes 1 to 20 carbon atoms, more preferably 1 to 10 carbon atoms, still more preferably 1 to 8 carbon atoms, yet more preferably 1 to 6 carbon atoms, and most preferably 1 to 4 carbon atoms. It is particularly preferred that the alkyl group is a partially or completely halogenated alkyl group (hereafter, this may be referred to as a halogenated alkyl group). A partially halogenated alkyl group means an alkyl group in which a part of the hydrogen atoms are substituted by halogen atoms, and a completely halogenated alkyl group means an alkyl group in which all the hydrogen atoms are substituted by halogen atoms. The halogen atom includes a fluorine atom, a chlorine atom, a bromine atom, and an iodide atom, and a fluorine atom is particularly preferred. In other words, the halogenated alkyl group is preferably a fluorinated alkyl group.

The aryl group preferably includes 4 to 20 carbon atoms, more preferably 4 to 10 carbon atoms, and most preferably 6 to 10 carbon atoms. It is particularly preferred that the aryl group is a partially or completely halogenated aryl group.

It is particularly preferred that the R³¹ is a non-substituted C₁ to C₄ alkyl group or a C₁ to C₄ fluorinated alkyl group.

The organic group of R³² is preferably a linear and branched chain, or cyclic alkyl group, aryl group or cyano group. The alkyl or aryl group of R³² is the same as the alkyl or aryl group of R³¹.

It is particularly preferred that the R³² is a cyano group, a non-substituted C₁ to C₈ alkyl or a C₁ to C₈ fluorinated alkyl group.

The oxime sulfonate type acid generator is more preferably a compound represented by the formula (XVII) or (XVIII).

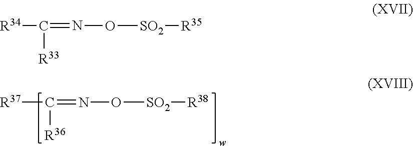

In the formula (XVII), R³³ represents a cyano group, a non-substituted alkyl group or a halogenated alkyl group. R³⁴ represents an aryl group. R³⁵ represents a non-substituted alkyl group or a halogenated alkyl group.

In the formula (XVIII), R³⁶ represents a cyano group, a non-substituted alkyl group or a halogenated alkyl group. R³⁷ represents a divalent or trivalent aromatic hydrocarbon group. R³⁸ represents a non-substituted alkyl group or a halogenated alkyl group. w is 2 or 3, and preferably is 2.

In the formula (XVII), the non-substituted alkyl group or the halogenated alkyl group of R³³ preferably has 1 to 10 carbon atoms, more preferably 1 to 8 carbon atoms and most preferably 1 to 6 carbon atoms.

R³³ is preferably a halogenated alkyl group, and more preferably a fluorinated alkyl group.

In the fluorinated alkyl group of R³³, it is preferred that 50% or more of the hydrogen atoms in the alkyl groups are fluorinated, more preferably 70% or more, and further preferably 90% or more. It is most preferred that it is a completely fluorinated alkyl group in which 100% of the hydrogen atoms are substituted. This is in order to increase the strength of the resulting acid.

The aryl group of R³⁴ includes a group in which one hydrogen atom is removed from an aromatic hydrocarbon ring such as phenyl group, biphenyl group, fluorenyl group, naphthyl group, anthracenyl group, phenanthrenyl group, and a heteroaryl group in which a part of the carbon atoms forming the ring of such groups is replaced by a hetero atom such as an oxygen atom, a sulfur atom, or a nitrogen atom. Among these, a fluorenyl group is preferred.

The aryl group of R³⁴ may include substituent such as a C₁ to C₁₀ alkyl group, a halogenated alkyl group or an alkoxy group. The alkyl group or the halogenated alkyl group in the substituent preferably has 1 to 8 carbon atoms, and more preferably 1 to 4 carbon atoms. The halogenated alkyl group is preferably a fluorinated alkyl group.

The non-substituted alkyl group or the halogenated alkyl group in R³⁵ is exemplified by the same examples as described in above R³³.

In the formula (XVIII), the non-substituted alkyl group or the halogenated alkyl group in R³⁶ is the same examples as described in above R³³.

The divalent or trivalent aromatic hydrocarbon group in R³⁷ includes a group in which a further one or two hydrogen atoms are removed from the aryl group in above R³⁴.

The non-substituted alkyl group or the halogenated alkyl group in R³⁸ is the same as described in above R³⁵.

The oxime sulfonate type acid generator includes a compound discussed in paragraph [0122] of JP2007-286161-A, the oxime sulfonate type acid generators disclosed in [Chem. 18] to [Chem. 19] in paragraphs [0012] to [0014] of JPH09-208554-A, and the oxime sulfonate type acid generators disclosed in Examples 1 to 40 on pages 65 to 85 of WO2004/074242A2.

The following examples are preferred.

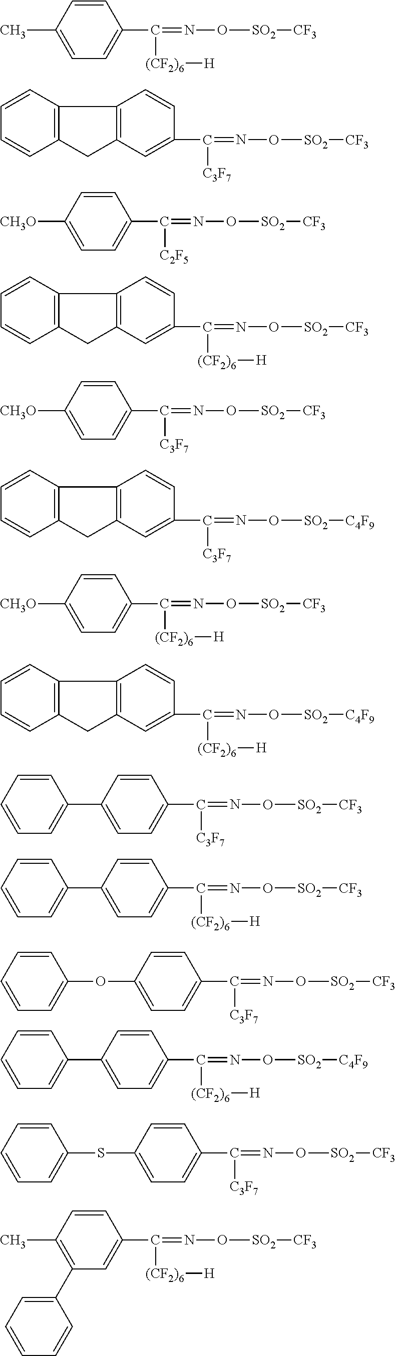

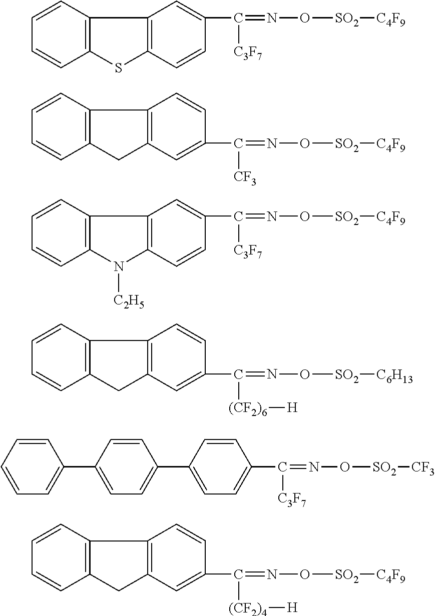

Types of bisalkyl or bisaryl sulfonyl diazomethane among the diazomethane acid generators include bis(isopropylsulfonyl)diazomethane, bis(p-toluene sulfonyl)diazomethane, bis(1,1-dimethylethyl sulfonyl)diazomethane, his (cyclohexyl sulfonyl)diazomethane and bis(2,4-dimethylphenyl sulfonyl)diazomethane.

The diazomethane type acid generators disclosed in JPH11-035551-A, JPH11-035552-A, and JPH11-035573-A may also be suitably used.

Types of poly(bis-sulfonyl)diazomethane include, for example, 1,3-bis (phenylsulfonyl diazomethylsulfonyl)propane, 1,4-bis(phenylsulfonyl diazomethylsulfonyl)butane, 1,6-bis(phenylsulfonyl diazomethylsulfonyl)hexane, 1,10-bis(phenylsulfonyl diazomethylsulfonyl)decane, 1,2-bis(cyclohexylsulfonyl diazomethylsulfonyl)ethane, 1,3-bis(cyclohexylsulfonyl diazomethylsulfonyl)propane, 1,6-bis(cyclohexylsulfonyl diazomethylsulfonyl)hexane, 1,10-bis(cyclohexylsulfonyl diazomethylsulfonyl)decane, as disclosed in JPH11-322707-A.

Among these, an onium salt having an anion formed from a fluorinated alkyl sulfonic acid ion is preferably used as a component of (B2).

in the present invention, the photo acid generator may be used singly or in a mixture of two or more agents.

The resist composition used in the present invention with reference to total solid content preferably contains about 70 to 99.9 wt % of the resin (A), about 0.1 to 30 wt %, preferably about 0.1 to 20 wt %, and more preferably about 1 to 10 wt % of the photo acid generator. This range enables sufficient execution of pattern forming in addition to obtaining homogenous solution and excellent storage stability.

There is no particular limitation on the cross-linking agent (C) and the agent may be suitably selected from cross-linking agents used in this field.

Examples include a compound produced by reacting formaldehyde, or formaldehyde and a lower alcohol with a compound containing an amino group such as acetoguanamine, benzoguanamine, urea, ethylene urea, propylene urea, and glycoluril, and replacing hydrogen atoms in the amino group by a hydroxymethyl group or a lower alkoxy methyl group; or an aliphatic hydrocarbon having two or more ethylene oxide structural moiety. A compound using urea is hereinafter termed a urea cross-linking agent, a compound using an alkylene urea such as ethylene urea and propylene urea is hereinafter termed an alkylene urea cross-linking agent, and a compound using glycoluril is hereinafter termed a glycoluril cross-linking agent. Among these, urea cross-linking agents, alkylene urea cross-linking agents and glycoluril cross-linking agents are preferred, and glycoluril cross-linking agents are more preferred.

A urea cross-linking agent includes a compound in which urea is reacted with formaldehyde, and the hydrogen atoms in the amino group are replaced by a hydroxymethyl group, or a compound in which urea, formaldehyde and a lower alcohol are reacted, and the hydrogen atoms in the amino group are replaced by a lower alkoxy methyl group. Specific examples include bis(methoxymethyl)urea, bis(ethoxymethyl)urea, bis(propoxymethyl)urea, and bis(butoxymethyl)urea. Among these, bis(methoxymethyl)urea is preferred.

The alkylene urea cross-linking group includes a compounds represented by the formula (XIX).

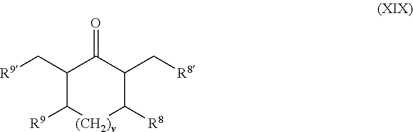

wherein R⁸ and R⁹ independently represent a hydroxyl group or a lower alkoxy group, R^{8′} and R^{9′} independently represent a hydrogen atom, a hydroxy group or a lower alkoxy group, and v is 0 or an integer of 1 to 2.

When R^{8′} and R^{9′} are a lower alkoxy group, the alkoxy group preferably has 1 to 4 carbon atoms and may be linear or branched chain. R^{8′} and R^{9′} may be the same, or may be different. It is more preferred that R^{8′} and R^{9′} are the same.

When R⁸ and R⁹ are a lower alkoxy group, the alkoxy group preferably has 1 to 4 carbon atoms and may be linear of branched chain. R⁸ and R⁹ may be the same, or may be different. It is more preferred that R⁸ and R⁹ are the same.

v is 0 or an integer of 1 to 2, and is preferably 0 or 1.

It is particularly preferred that the alkylene urea cross-linking agent is a compound in which v is 0 (an ethylene urea cross-linking agent) and/or a compound in which v is 1 (a propylene urea cross-linking agent).

A compound represented by the formula (XIII) above can be obtained by condensation-reacting alkylene urea with formalin, or by reacting the resulting product with a lower alcohol.

Specific examples of the alkylene urea cross-linking agent include ethylene urea cross-linking agents such as mono- and/or di-hydroxymethylated ethylene urea, mono- and/or di-methoxymethylated ethylene urea, mono- and/or di-ethoxymethylated ethylene urea, mono- and/or di-propoxymethylated ethylene urea, and mono- and/or di-butoxymethylated ethylene urea; and propylene urea cross-linking agents such as mono- and/or di-hydroxymethylated propylene urea, mono- and/or di-methoxymethylated propylene urea, mono- and/or di-ethoxymethylated propylene urea, mono- and/or di-propoxymethylated propylene urea, and mono- and/or di-butoxymethylated propylene urea; 1,3-di(methoxymethyl)-4,5-dihydroxy-2-imidazolidinone and 1,3-di(methoxymethyl)-4,5-dimethoxy-2-imidazolidinone.

Examples of the glycoluril cross-linking agent include a glycoluril derivative in which the N-position is substituted with either or both a hydroxyalkyl group and/or a C₁ to C₄ alkoxyalkyl group. The glycoluril derivative can be obtained by subjecting a glycoluril and formalin to a condensation reaction, or by further reacting the product of this reaction with a lower alcohol.

Specific examples of the glycoluril cross-linking agent include mono-, di-, tri- or tetra-hydroxymethylated glycoluril, mono-, di-, and/or tetra-methoxymethylated glycoluril, mono-, di-, tri- and/or tetra-ethoxymethylated glycoluril, mono-, di-, tri- and/or tetra-propoxymethylated glycoluril, and mono-, di-, tri- and/or tetra-butoxymethylated glycoluril.

The cross-linking agent (C) may be used singly or in a combination of two or more agents.

The content of the cross-linking agent (C) is preferably 0.5 to 30 parts by weight relative to 100 parts by weight of the resin (A) component, and more preferably 0.5 to 10 parts by weight, and still more preferably 1 to 5 parts by weight. Within this range, the formation of cross-linking is sufficiently promoted and obtains a superior resist pattern, as well as storage stability of the resist coating liquid is superior and deterioration over time of its sensitivity can be suppressed.

There is no particular limitation on the acid amplifier (D) as long as it is decomposed by acid to generate strong acid on its own and functions so as to accelerate the acid catalyst reaction. Any acid amplifier used in this technical field can be suitably selected. Examples thereof include the known acid amplifier disclosed in JP2007-052182A, JP2003-280198A, JP2002-207300 A, JP2002-122987 A, JP2002-122986 A, JP2001-081138 A, JP2001-022069 A, JPH11-158118A or the like. Among these, an acid amplifier represented by the formula (D1) or the formula (D2) (hereinafter referred to as “compound (D1)” or “compound (D2)”) is preferably used for the resist composition of the present invention.

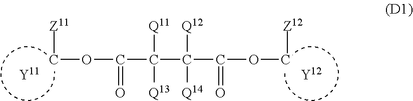

wherein Z¹¹ and Z¹² independently represent a hydrogen atom, a C₁ to C₁₂ alkyl group or a C₃ to C₁₂ cyclic saturated hydrocarbon group, provided that at least one of Z¹¹ and Z¹² represent a C₁ to C₁₂ alkyl group or a C₃ to C₁₂ cyclic saturated hydrocarbon group;

ring Y¹¹ and ring Y¹² independently represents an optionally substituted C₃ to C₂₀ alicyclic hydrocarbon group; and

Q¹¹, Q¹², Q¹³ and Q¹⁴ independently represent a fluorine atom or a C₁ to C₆ perfluoroalkyl group;

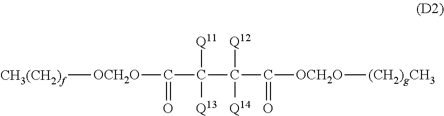

wherein Q¹¹, Q¹², Q¹³ and Q¹⁴ independently represent a fluorine atom or a C₁ to C₆ perfluoroalkyl group; and

f and g independently represent an integer of 0 to 5.

There is no particular limitation on the carbon number of Z¹¹ and Z¹², but it suitably has 1 to 12 carbon atoms. Examples thereof include that as described above.

There is no particular limitation on the carbon number in the cyclic saturated hydrocarbon, but it suitably has 1 to 12 carbon atoms. Examples thereof include the cyclic saturated hydrocarbon as described above.

There is no particular limitation on the carbon number of the alicyclic hydrocarbon group of the ring Y¹¹ and the ring Y¹², but it suitably has 3 to 20 carbon atoms. Examples thereof include a divalent substituent which has bonds at any position of the compound represented by the formula below. Among these, a divalent substituent which has 2 bonds at the position represented by asterisk is preferable.

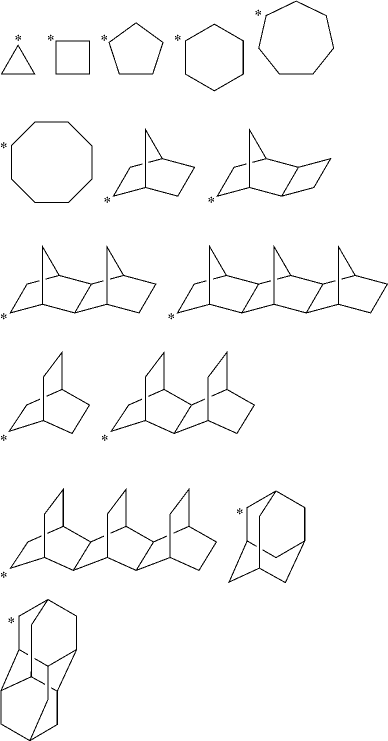

A substituent which may be substituted to an alicyclic hydrocarbon group is not limited to, and may be an inactive substituent to a reaction for the production of the compound (D1). Examples thereof include alkyl and alkoxyl groups. These substituents suitably have one to six carbon atoms.

There is no particular limitation on the carbon number of the perfluoroalkyl group in Q¹¹, Q¹², Q¹³ and Q¹⁴, but it suitably has 1 to 6 carbon atoms. Examples thereof include trifluoromethyl, pentafluoroethyl, heptafluoropropyl, nonafluorobutyl, perfluoropenthyl and perfluorohexyl groups.

Z¹¹ and Z¹² are preferably methyl, ethyl, isopropyl, n-butyl, cyclopentyl or cyclohexyl group, and more preferably methyl, ethyl or isopropyl group.

The ring Y¹¹ and ring Y¹² are preferably cyclopentyl, cyclohexyl, or adamantyl group, and more preferably adamantyl group.

Q¹¹, Q¹², Q¹³ and Q¹⁴ are preferably fluorine atom or trifloromethyl group, and more preferably fluorine atoms.

Thus, examples of preferable compounds (D1) include a compound which is obtained by optionally combining these preferable substituents.

Examples of compound (D1) include the following compounds.

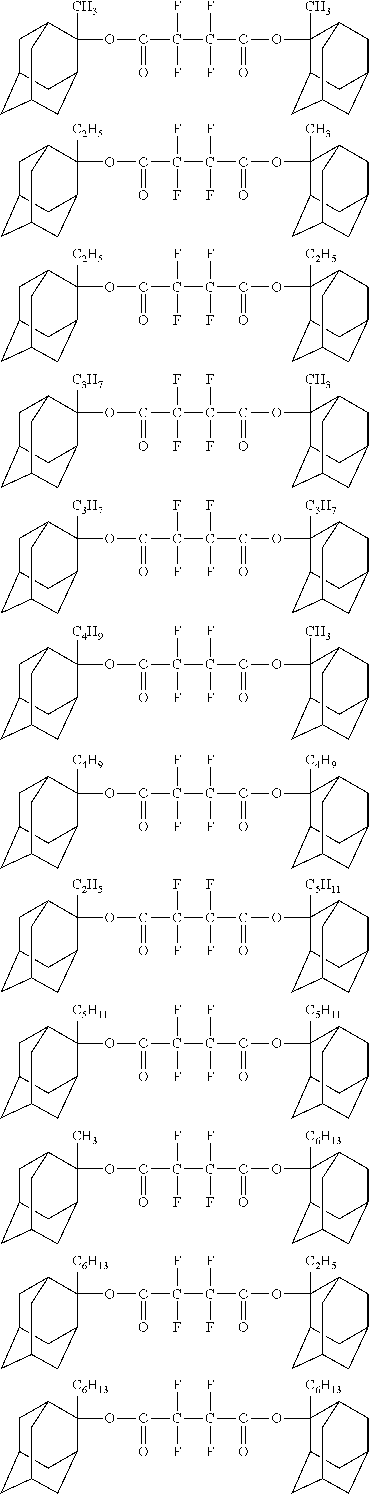

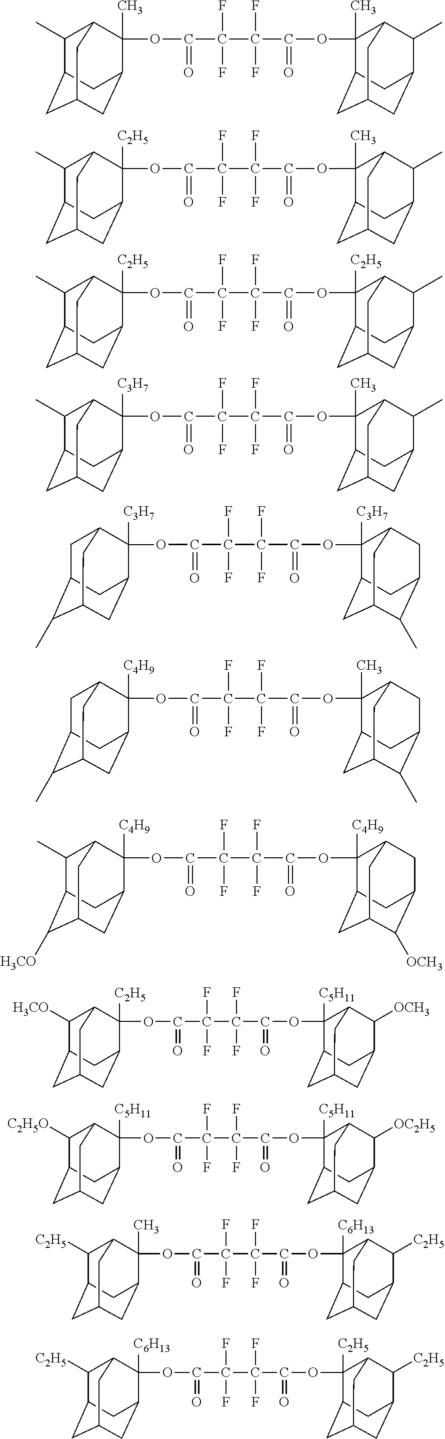

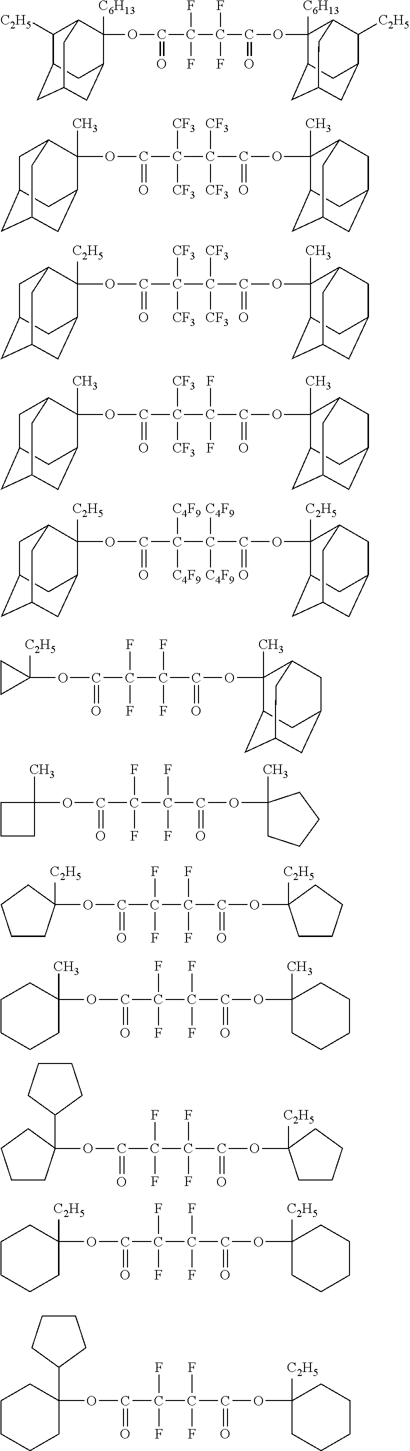

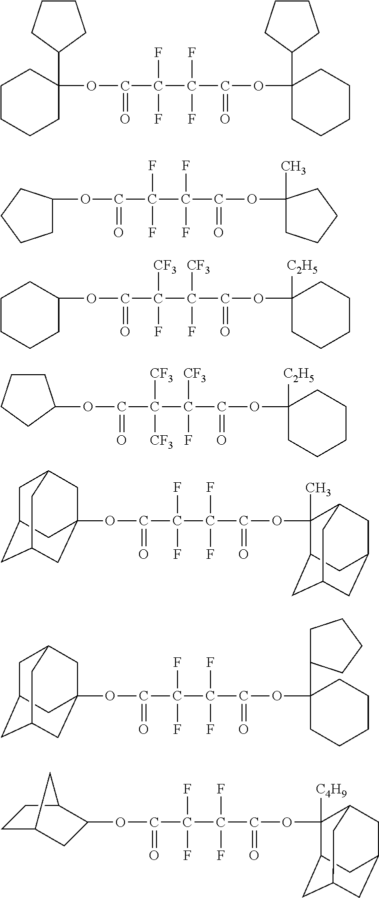

Examples of compound (D2) include the following compounds.

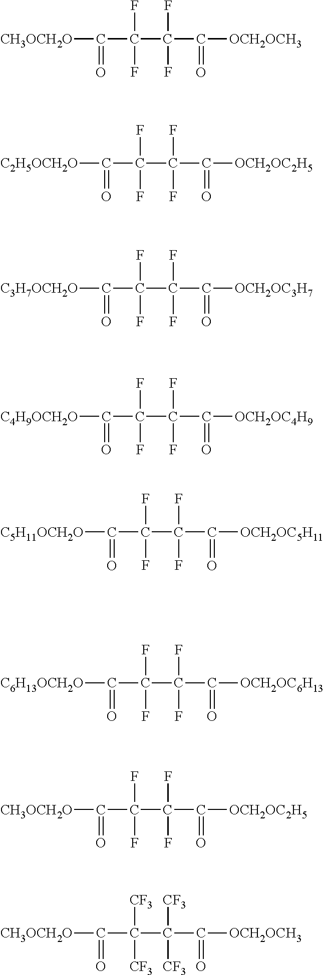

The compound (D1) can be produced by reacting a compound represented by the formula (DII) with a compound represented by the formula (DIII) and a compound represented by the formula (DIV) as follows.

Also, the compound (D1) can be produced by dehydration-reacting a compound represented by the formula (DV) with a compound represented by the formula (DIII) and a compound represented by the formula (DIV) as follows.

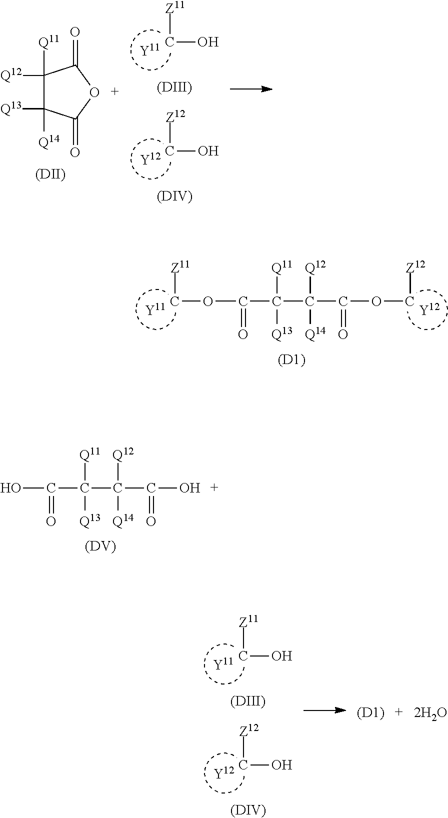

wherein Z¹¹, Z¹², ring Y¹¹, ring Y¹², Q¹¹, Q¹², Q¹³ and Q¹⁴ are the same meaning as defined above.

These reactions can be carried out in the presence of a solvent that is inactive in the reaction, or in the absence of a solvent, and in the presence or in the absence of a catalyst.

Examples of such solvents include hydrocarbons such as hexane, cyclohexane, and toluene; halogenated hydrocarbons such as methylene chloride, 1,2-dichloroethane, chloroform, carbon tetrachloride, and chlorobenzene; chain or cyclic ethers such as diethyl ether, dimethoxyethane, tetrahydrofuran, and dioxane; nitriles such as acetonitrile and benzonitrile; esters such as ethyl acetate; amides such as N,N-dimethyl formamide; ketones such as acetone and methyl ethyl ketone; nitro compounds such as nitromethane and nitrobenzene; and sulfur-containing compounds such as dimethyl sulfoxide and sulforane; and a mixtures of two or more of the above may be used.

Examples of the catalyst used when producing the compound (D1) by reaction between the compound represented by the formula (DII), the compound represented by the formula (DIII) and the compound represented by the formula (DVI), preferably include a basic compound, specifically, pyridine, triethylamine, dimethyl aniline, 4-dimethyl amino pyridine, etc., or a mixture thereof. The reaction may also be carried out in the presence of a Lewis acid (FeBr₃, AlBr₃, etc.). The amount of the catalyst is usually a catalytic amount or more, and preferably a catalytic amount to 4 times mole relative to the compound represented by the formula (II).

Examples of dehydrating agents used when producing a compound (D1) by the reaction between the compound represented by the formula (DII), and compounds represented by the formula (DIII) and formula (DV) include dicyclohexylcarbodiimide (DCC), 1-alkyl-2-halopyridinium salts, 1,1-carbonyldiimidazole, bis(2-oxo-3-ozazolidinyl)phosphinic chloride, 1-ethyl-3-(3-dimethylaminopropyl)carbodiimide hydrochloride, di-2-pyridyl carbonate, di-2-pyridylthionocarbonate, and 6-methyl-2-nitrobenzoic anhydride/4-(dimethylamino)pyridine (catalyst). The amount of the dehydrating agent is usually 2 times mole or more, and preferably 2 times mole to 4 times mole relative to the compound represented by the formula (V).

The alcohols represented by the formula (DIII) and the formula (DIV) can be reacted with about 0.1 to 10 mol relative to the compound represented by the formula (DII) or the formula (DV)

When the compound (D1) is produced by the reaction between the compound represented by the formula (DII), and compounds represented by the formula (DIII) and the formula (DIV), the reaction temperature is usually −70 to 100° C., preferably −50 to 80° C., and more preferably about −20 to 50° C.

When the compound (D1) is produced by the reaction between the compound represented by the formula (DV), and compounds represented by the formula (DIII) and the formula (DIV), the reaction temperature is usually −50 to 200° C., preferably −20 to 150° C., and more preferably about −10 to 120° C.

Within this temperature range, the reaction rate will not decrease, and the reaction time will not be too long.

The reaction pressure is usually in the range between 0.01 MPa and 10 MPa absolute pressure, and preferably normal pressure to 1 MPa. Within this pressure range, a special pressure-resistant apparatus is not required, there is no safety hazard, and there will be industrially-advantageous.

The reaction time is usually in the range of 1 minute to 24 hours, and preferably 5 minutes to 12 hours.

The reaction product is preferably purified after completion of the reaction. A suitable method is preferably selected, for example, from common methods of separation and purification, such as adjustment of liquid property, filtration, concentration, crystallization, washing, recrystallization, distillation, and column chromatography, depending on the properties of the product, the type of impurities, and so forth.

The resulting compound can be identified using gas chromatography (GC), liquid chromatography (LC), gas chromatography-mass spectrometry (GC-MS), nuclear magnetic resonance (NMR), infrared spectroscopy (IR), a melting point analyzer, or the like.

The compound (D2) of the present invention can also be produced by a reaction between the compound represented by the formula (DV), and the compounds represented by the formula (DVII) and the formula (DVIII), as shown below.

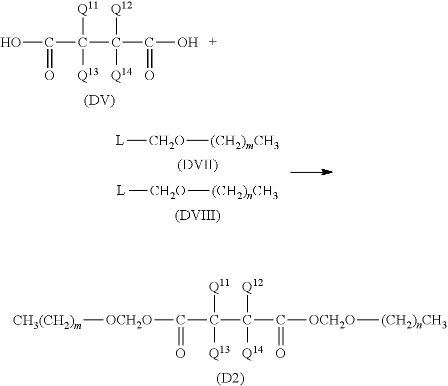

wherein Q¹¹, Q¹², Q¹³ and Q¹⁴, m, and n are the same meaning as defined above; and

L represents a halogen atom.

The reaction is suitably conducted in the presence of an inert solvent. Examples of the inert solvent include aprotic solvents such as dichloroethane, toluene, ethyl benzene, monochlorobenzene, diethyl ether, tetrahydrofuran, dioxane, acetone, methyl ethyl ketone, ethyl acetate, dimethyl sulfoxide and N,N-dimethyl formamide.

The reaction is preferably carried out while stirred at a temperature in the range from about −70° C. to 200° C., and preferably about −50° C. to 150° C.

A deacidifying agent is preferably used in the reaction.

Examples of the deacidifying agent include organic bases such as triethylamine and pyridine, or inorganic bases such as sodium hydroxide, potassium carbonate, and sodium hydride. The amount of a base used may be an amount corresponding to the solvent, and is usually about 0.001 to about 5 mots, and preferably about 1 to 3 mols relative to 1 mol of the compound of the formula (DV).

Examples of halogen atoms L in the formula (DVII) and the formula (DVIII) include fluorine, chlorine, bromine, and iodine atoms, and is preferably chlorine, bromine, or iodine atom, and more preferably chlorine or bromine atom.

The acid amplifier (D) of the present invention functions as so-called acid amplifier, which is decomposed by acid to generate strong acid on its own. It is therefore preferably blended with a resist composition in order to function as such effectively. In such cases, the acid amplifier (D) may be used singly or in combinations of two or more.

The amount of the acid amplifier (D) is preferably about 0.5 to 30 parts by weight, more preferably 0.5 to 10 parts by weight, and still more preferably 1 to 5 parts by weight relative to 100 parts by weight of the resin (A). The use thereof in this range will accelerate the acid catalyst reaction in the resist composition, and thereby increase sensitivity to allow a good resist pattern to be obtained.

The resist composition used in the present invention preferably contains a thermal acid generator (E). The thermal acid generator as used herein refers a compound which is stable at a temperature which is lower than a hard bake temperature (as described hereafter) for a resist which uses the thermal acid generator, but decomposes at greater than or equal to the hard bake temperature and thereby produces adds. In contrast, the photo acid generator is stable at a pre-bake temperature (as described hereafter) or a post-exposure bake temperature (as described hereafter) and produces acids as a result of exposure. This distinction can be obtained fluidly depending on the aspect in which the present invention is used. That is to say, it can function as both the thermal acid generator and the photo acid generator depending on the applied processing temperature, or may only function as a photo acid generator, in the same resist. Although it does not function as the thermal add generator in a certain resist, it may function as the thermal acid generator in another resist.

The thermal acid generator includes, for example, various known thermal acid generators such as benzoin tosylate, nitrobenzyl tosylate (in particular, 4-nitrobenzyl tosylate), and other alkylesters of organic sulfonic acids.

The content of the thermal acid generator (E) preferably be 0.5 to 30 parts by weight, more preferably 0.5 to 15 parts by weight, and most preferably 1 to 10 parts by weight relative to 100 parts by weight of the resin (A).

The resist composition of the present invention may include a basic compound, preferably a basic nitrogen-containing organic compound, in particular, an amine or an ammonium salt is preferable. The basic compound can be added to function as a quencher, whereby to improve performance from being compromised by the inactivation of the add while the material is standing after exposure. When the basic compound is used, the content thereof is preferably 0.01 to 1 weight % with reference to total solid content of the resist composition.

The examples of such basic compounds include those represented by the following formulae.

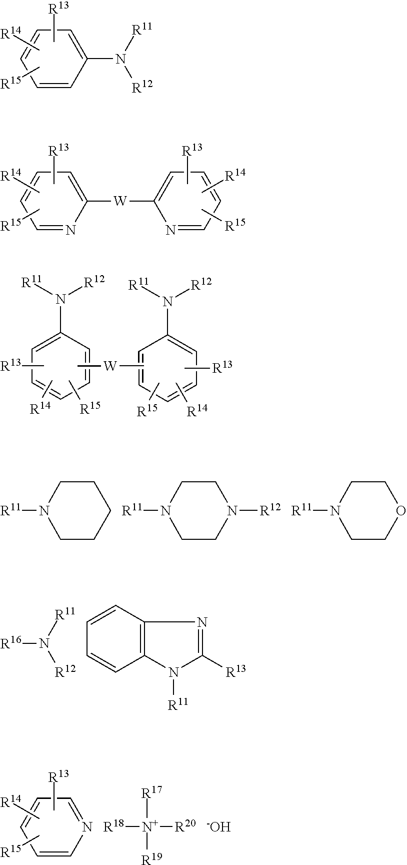

wherein R¹¹ and R¹² independently represent a hydrogen atom, an alkyl group, a cycloalkyl group or an aryl group, the alkyl group preferably has about 1 to 6 carbon atoms, the cycloalkyl group preferably has about 5 to 10 carbon atoms, the aryl group preferably has about 6 to 10 carbon atoms;

R¹³, R¹⁴ and R¹⁵ independently represent a hydrogen atom, an alkyl group, a cycloalkyl group, an aryl group or an alkoxy group, the alkyl group, the cycloalkyl group, and the aryl group are the same as described in R¹¹ and R¹², the alkoxy group preferably has 1 to 6 carbon atoms.

R¹⁶ represents an alkyl group or a cycloalkyl group, the alkyl group and the cycloalkyl group are the same as described in R¹¹ and R¹².

R¹⁷, R¹⁸, R¹⁹ and R²⁰ independently represent an alkyl group, a cycloalkyl group or an aryl group, the alkyl group, the cycloalkyl group and the aryl group are the same as described in R¹¹, R¹² and R¹⁷.

Further, at least one hydrogen atom in the alkyl group, the cycloalkyl group and the alkoxy group may be independently replaced by a hydroxy group, an amino group or a C₁ to C₆ alkoxy group. At least one hydrogen atom in the amino group may be replaced by a C₁ to C₄ alkyl group.

W represents an alkylene group, a carbonyl group, an imino group, a sulfide group or a disulfide group. The alkylene group preferably has about 2 to 6 carbon atoms.

In R¹¹ to R²⁰, if the group may be linear or branched chain, either one is included.

Examples of such compounds include a compound disclosed in JP-2006-257078-A.

Furthermore, hindered amine compounds with a piperidine skeleton such as those disclosed in JP-H11-52575-A can be used as a quencher.

The resist composition used in the present invention may also include various additives known in this field such as sensitizers, dissolution inhibitors, other resins, surfactants, stabilizers and dyes, as needed.

The resist composition used in the present invention is normally used as a resist liquid composition in a state in which each component is dissolved in a solvent. This type of resist composition is used at least as a first resist composition. In this manner, it is possible to use a so-called double imaging method. In the double imaging method, a fine resist pattern can be obtained that has half the pattern pitch by twice repeating the process of resist coating, exposure and development. This type of process may be repeated a plurality of three or more times (N times). In this manner, a finer resist pattern having a pattern pitch of 1/N can be obtained. The present invention can be suitably applied to this type of double, triple imaging method and multi-imaging method.

The above resist composition may be used as a second resist composition. In this case, there is no necessity for the composition to always be the same as the first resist composition.

In the resist processing method of the present invention, firstly the resist liquid composition described above (hereafter may be referred to as the first resist composition) is applied onto a substrate and dried to thereby obtain a first resist film. There is no particular limitation on the thickness of the first resist film as used herein, and the thickness may be suitably set with reference to a direction of film thickness to substantially equal to or less than a level sufficiently enabling exposure and developing during following steps, and for example, may be of the level of several tenths of micrometers to several millimeters.

There is no particular limitation on the substrate and for example various materials such as a semiconductor substrate such as a silicon wafer, a plastic, metal or ceramic substrate, a substrate having an insulating film or conducting layer thereon can be used.

There is no particular limitation on the method of coating the composition and a method used in normal industrial processing such as spin coating may be used.

Any substance can be used as a solvent used to obtain the resist liquid composition as long as the substance dissolves each component, has a suitable drying speed and obtains a flat uniform coating after evaporation of the solvent. Normally-used general solvents in this area may be applied.

Examples thereof include glycol ether esters such as ethylcellosolve acetate, methylcellosolve acetate and propylene glycol monomethyl ether acetate; glycol ethers such as propylene glycol monomethyl ether; esters such as ethyl lactate, butyl acetate, amyl acetate and ethyl pyruvate; ketones such as acetone, methyl isobutyl ketone, 2-heptanone and cyclohexanone; and cyclic esters such as γ-butyrolactone. These solvents can be used alone or in combination of two or more.

The drying process includes natural drying, draft drying, and reduced pressure drying. The specific heating temperature may be about 10 to 120° C., and more preferably about 25 to 80° C. The heating period is about 10 seconds to 60 minutes and preferably about 30 seconds to 30 minutes.

Next, the resulting first resist film is pre-baked. The pre-baking is conducted for example in a temperature range of about 80 to 140° C. and in the range of about 30 seconds to 10 minutes.

Then an exposure process for patterning is executed. The exposure is preferably carried out using any exposure device that is conventionally used in this field, such as a scanning exposure type, i.e. a scanning stepper type projection exposure device (exposure device). Various types of exposure light source can be used, for example, irradiation with ultraviolet lasers such as KrF excimer laser (wavelength: 248 nm), ArF excimer laser (wavelength: 193 nm), F₂ laser (wavelength: 157 nm), or irradiation with harmonic laser light of far-ultraviolet wavelength or vacuum ultraviolet wavelength which is converted from a solid-state laser source (YAG or semiconductor laser or the like).

Thereafter, the resulted first resist film is post-exposure baked. This heating process can promote a protection deblocking reaction. The heating process, for example, is executed in a temperature range of about 70 to 140° C. and for a range of about 30 seconds to 10 minutes.

Then, a first resist pattern is obtained by developing with a first alkali developer. The alkali developer includes various types of aqueous alkali solutions used in this field, and normally an aqueous solution such as tetramethylammonium hydroxide(2-hydroxyethyl)trimethylammonium hydroxide (common name: choline) is used.

Thereafter, the obtained first resist pattern is hard-baked. This heating process promotes cross-linking reactions. The heating process herein, for example, is executed in a relatively high temperature range of about 120 to 250° C. and for a range of about 30 seconds to 10 minutes.

Furthermore, a second resist composition is coated on the first resist pattern formed using the resist composition above and then dried to thereby form a second resist film. This is pre-baked, and subjected to exposure processing for patterning. An arbitrary heating process, and a usual post-exposure bake are performed. Thereafter, a second resist pattern can be formed by developing with a second alkali developer.

The conditions for coating, drying, pre-baking, exposure and post-exposure baking with respect to the second resist composition are the same as those conditions described with reference to the first resist composition.

There is no particular limitation on the second resist composition, and either a negative or a positive resist composition may be used and any known composition used in this field may be used. Any of the resist compositions described above may be used and, in that case, it is not necessary for the second resist composition to be the same as the first resist composition.

In the present invention, even with a double imaging method including at least two exposures and developing processes and multiple heating processes, a first resist film which retains an original shape and does not cause deformation of the pattern is used and, therefore, it is possible to create an extremely fine pattern.

### Examples

The present invention will be described more specifically by way of examples. All percentages and parts expressing the content or amounts used in the Examples are based on weight, unless otherwise specified. The weight average molecular weight is a value determined by gel permeation chromatography, the conditions thereof describes below.

Column: TSKgel Multipore HXLM×3+guardcolumn (manufactured by Tosoh Co. ltd.)

Eluant tetrahydrofran

Flow rate: 1.0 mL/min

Detecting device: RI detector

Column temperature: 40° C.

Injection amount: 100 μL

Standard material for calculating molecular weight: standard polysthylene (manufactured by Tosoh Co. ltd.)

<Resin>

The monomers used in synthesis of resin are follows.

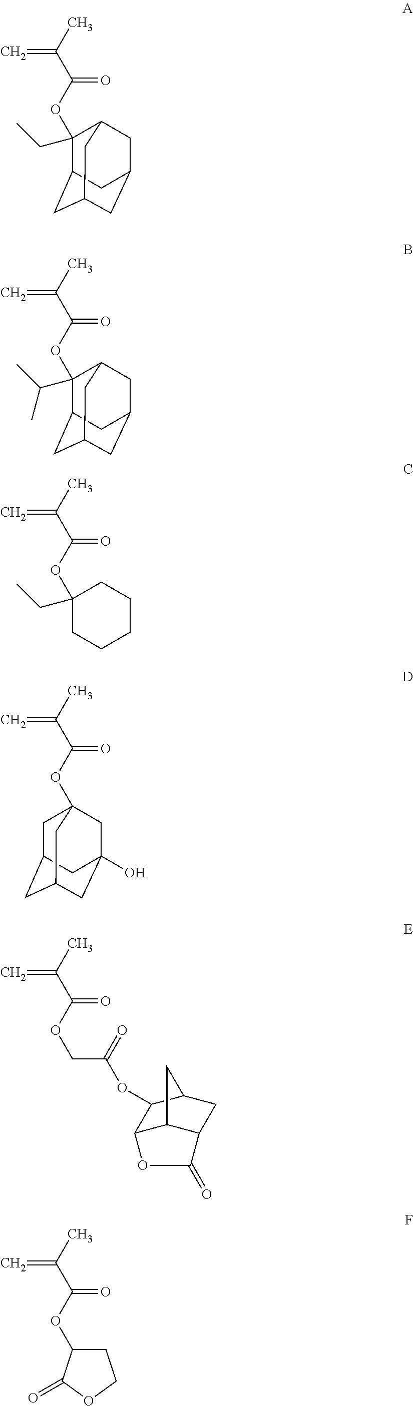

Example of Resin Synthesis 1: Synthesis of Resin 1

Into a four-neck flask provided with a thermometer and a reflux condenser, 24.36 parts of methyl isobutylketone was charged and bubbling with a nitrogen gas was performed for 30 minutes. The temperature was increased to 72° C. under a nitrogen seal, a solution being a mixture of 16.20 parts of monomer A, 11.56 parts of D, 8.32 parts of F described above, 0.27 parts of azobisisobutyronitrile, 1.22 parts of azobis-2,4-dimethylvaleronitrile and 29.77 parts of isobutylketone was added dropwise over 2 hours while maintaining a temperature of 72° C. After completion of dropwise addition, a temperature of 72° C. was maintained for 5 hours. After cooling, the reaction solution was diluted with 39.69 parts of isobutylketone. The diluted mass was poured into 469 parts of methanol while stirring and a precipitated resin was collected by filtrating. The filtrated material was placed into a liquid being 235 parts of methanol, stirred and filtration was conducted. The operation of placing the resulting filtrated material in the similar liquid, stirring and filtrating was repeated twice. Thereafter, reduced pressure drying was performed to obtain 22.7 parts of resin. The resin is represented as Resin 1. Yield: 63%, Mw: 10124 and Mw/Mn: 1.40.

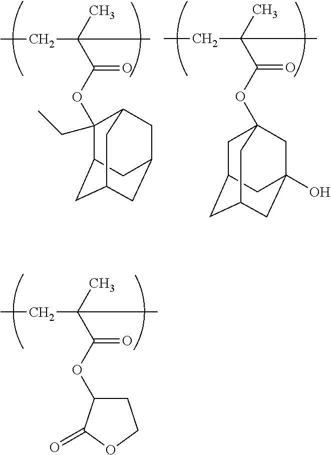

Example of Resin Synthesis 2: Synthesis of Resin 2

Into a four-neck flask provided with a thermometer and a reflux condenser, 24.45 parts of 1,4-dioxane was charged and bubbling with a nitrogen gas was performed for 30 minutes. The temperature was increased to 73° C. under a nitrogen seal, a solution being a mixture of 15.50 parts of monomer A, 2.68 parts of C, 8.30 parts of D, 14.27 parts of F described above, 0.32 parts of azobisisobutyronitrile, 1.45 parts of azobis-2,4-dimethylvaleronitrile and 36.67 parts of 1,4-dioxane was added dropwise over 2 hours while maintaining a temperature of 73° C. After completion of dropwise addition, a temperature of 73° C. was maintained for 5 hours. After cooling, the reaction solution was diluted with 44.82 parts of 1,4-dioxane. The diluted mass was poured into a mixed solvent of 424 parts of methanol and 106 parts of an ion exchange water while stirring and a precipitated resin was collected by filtrating. The filtrated material was placed into a liquid being 265 parts of methanol and stirred, and filtration was conducted. The operation of placing the resulting filtrated material in the similar liquid, stirring and filtrating was repeated twice. Thereafter, reduced pressure drying was performed to obtain 31 parts of resin. The resin is represented as Resin 2. Yield: 75%, Mw: 15876 and Mw/Mn: 1.551.

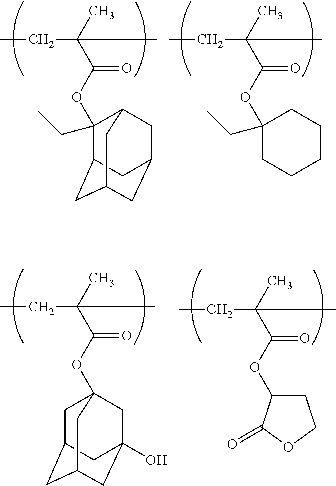

Example of Resin Synthesis 3: Synthesis of Resin 3

Into a four-neck flask provided with a thermometer and a reflux condenser, 27.78 parts of 1,4-dioxane was charged and bubbling with a nitrogen gas for 30 minutes was performed. After increasing the temperature to 73° C. under a nitrogen seal, a solution being a mixture of 15.00 parts of B, 5.61 parts of C, 2.89 parts of D, 12.02 parts of E, 10.77 parts of F described above, 0.34 parts of azobisisobutyronitrile, 1.52 parts of azobis-2,4-dimethylvaleronitrile and 63.85 parts of 1,4-dioxane was added dropwise over 2 hours while maintaining a temperature of 73° C. After completion of dropwise addition, a temperature of 73° C. was maintained for 5 hours. After cooling, the reaction solution was diluted with 50.92 parts of 1,4-dioxane. The diluted mass was poured into 481 parts of methanol and 120 parts of ion-exchanged water while stirring, and a precipitate resin was collected by filtrating. The filtrated material was placed into a liquid being 301 parts of methanol and filtration was performed after stirring. The operation of placing the resulting filtrated material in the same liquid, stirring and filtrating was repeated twice. Thereafter reduced pressure drying was performed to obtain 37.0 parts of resin having structure units below. The resin is represented as Resin 3. Yield: 80%, Mw: 7883, Mw/Mn: 1.96.

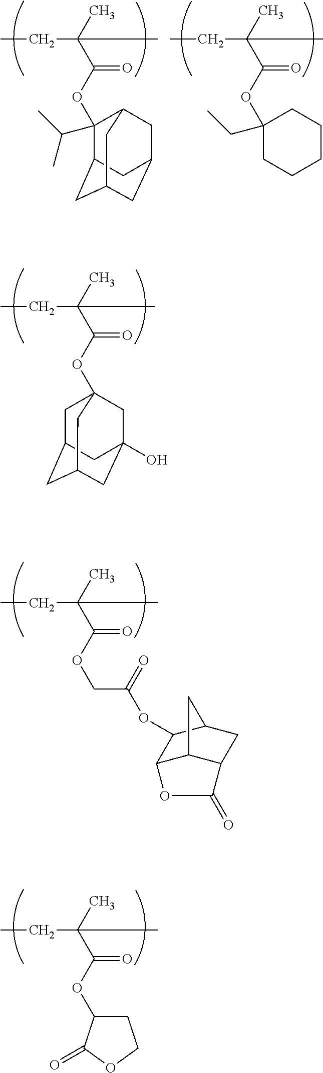

<Acid Amplifier>

### Example of acid amplifier Synthesis: Synthesis of Bis(2-methyladamantyl-2-yl) tetrafluorosuccinate

2-methyl-2-adamantanol (9.71 g, 58 mmol, RN=702-98-7), triethylamine (7.06 g, 70 mmol) and 4-dimethyl aminopylidine (1.43 g, 12 mmol) were dissolved in anhydride tetrahydrofrane (97.1 g, THF). A THT solution (20.0 g) of anhydrous tetrafluorosuccinic add (10.0 g, 58 mmol, RN=699-30-9) was added dropwise to this solution at a temperature of 5° C. or less.

The reaction solution was stirred for 3 hours at 5° C. or less. The reaction solution was concentrated under reduced pressure, diluted with ethyl acetate, and then made it acidic (pH 5) with 5% hydrochloric add. An organic layer was separated and washed with an ion exchange water. The organic layer was dried with magnesium sulfate, and concentrated to thereby obtain crude product (20 g).

The crude product (11 g) was purified with silica gel chromatography (chloroform development) to obtain bis(2-methyladamantyl-2-yl)tetrafluorosuccinate (5.37 g, Yield: 34.6%).

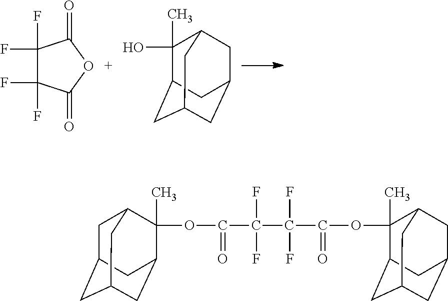

¹H-NMR (CDCl₃): δ=2.35 (4H, s), 2.06-2.04 (4H), 1.90-1.78 (12H), 1.73 (4H, s), 1.69 (6H, s), 1.62-1.59 (4H)

¹⁹F-NMR (CDCl₃): δ=−115.1

¹³C-NMR (CDCl₃): δ=157.92 (t), 110.27 (t), 108.17 (t), 106.07 (t), 94.00, 37.90, 36.14, 34.61, 32.62, 27.12, 26.37, 21.93

FD-MS:486 (M⁺)

### EXAMPLES AND COMPARATIVE EXAMPLE

Each of resist compositions was prepared by mixing and dissolving each of the components below, and then filtrating through a fluororesin filter having 0.2 μm pore diameter.

TABLE 1

| | | Photo acid | Cross-linking | Acid | |
|---|---|---|---|---|---|
| | Resin | Generator | agent | Amplifier | |
| Ex. | (A) | (B) | (C) | (D) | Quencher |
| Ex. 1 | Resin 1 = | Photo acid | 0.2 parts | 0.6 parts | Quencher 1 = |
| | 10 parts | Generator 1 = | | | 0.01 parts |
| | | 0.6 parts | | | |
| Ex. 2 | Resin 2 = | Photo acid | 0.1 parts | 0.2 parts | Quencher 2 = |
| | 10 parts | Generator 2 = | | | 0.16 parts |
| | | 0.85 parts | | | |
| Ex. 3 | Resin 2 = | Photo acid | 0.1 parts | 0.6 parts | Quencher 2 = |
| | 10 parts | Generator 2 = | | | 0.16 parts |
| | | 0.85 parts | | | |
| Comp. | Resin 2 = | Photo acid | 0.1 parts | — | Quencher 2 = |
| Ex. 1 | 10 parts | Generator 2 = | | | 0.16 parts |
| | | 0.85 parts | | | |
| Ref. Ex. | Resin 3 = | Photo acid | — | | Quencher 1 = |
| | 10 parts | Generator 2 = | | | 0.105 parts |
| | | 1.5 parts | | | |

The components used in Table 1 were shown below.

<Photo Acid Generator>

Photo acid generator 1: triphenylsulfonium 4-oxo-1-adamantyloxycarbonyl difluoromethanesulfonate (synthesized according to a method described in JP 2007-224008 A)

Photo acid generator 2: triphenylsulfonium 1-[(3-hydroxy-1-adamantyl)methoxycarbonyl]difluoromethanesulfonate (synthesized according to a method described in JP 2006-257078 A)

<Cross-Linking Agent>

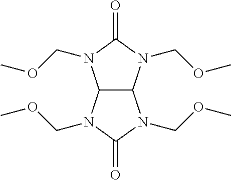

<Quencher>

Quencher 1: 2,6-diisopropylaniline

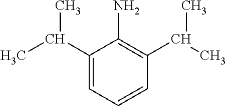

Quencher 2: trimethoxyethoxy ethylamine (TMEA)

<Solvent>

PMGE solvent 1:

| | |
|---|---|
| Propylene glycol monomethyl ether | 240 parts |
| 2-Heptanone | 35 parts |
| Propylene glycol monomethyl ether acetate | 20 parts |
| γ-butyrolactone | 3 parts |

PMGE solvent 2:

| | |
|---|---|
| Propylene glycol monomethyl ether | 255 parts |
| 2-Heptanone | 35 parts |
| Propylene glycol monomethyl ether acetate | 20 parts |
| γ-butyrolactone | 3 parts |

### Example 1

A composition for an organic antireflective film, “ARC-29A-8”, manufactured by Brewer Co. Ltd., was applied onto silicon wafers and baked for 60 seconds at 205° C. to form a 78 nm thick organic antireflective film. The resist liquid in which the resist composition shown in Example 1 of Table 1 was dissolved in the PMEG solvent 1 described above was spin-coated thereon as the first resist composition so that the thickness of the resulted film became 0.08 μm after drying.

Thereafter, 60 seconds of pre-baking at 90° C. was performed on a direct hot plate.

A pattern was exposed on the obtained resist film at the exposure amount of 35 mJ/cm² by using an ArF excimer stepper (“FPA5000-AS3” manufactured by Canon: NA=0.75, 2/3 Annular) and a mask having 1:1 line and space pattern with line width of 100 nm.

Then, post-exposure baking was performed on a hotplate at 95° C. for 60 seconds.

Further, puddle development with 2.38 wt % tetramethylammonium hydroxide aqueous solution was performed for 60 seconds to form a desired pattern.

Then, hard-baking was performed for 60 seconds at the temperature of 170° C.

When the resulted first line and space pattern was observed using a scanning electron microscope, it was confirmed that a good and precise pattern was formed.

Then, as a second resist liquid, a resist liquid in which the resist composition of Reference Example A in Table 1 was dissolved in the above PMEG solvent 2 was applied on the obtained first line and space pattern so that the thickness of the resulted film became 0.08 μm after drying.

Thereafter, 60 seconds of pre-baking at 85° C. was performed on a direct hot plate.

A second line and space pattern was exposed on thus obtained second resist film at the exposure amount of 29 mJ/cm² by using an ArF excimer stepper (“FPA5000-AS3” manufactured by Canon: NA=0.75, 2/3 Annular) so as to be in a direction perpendicular to the first line and space pattern by rotating the pattern by 90°.

Then, post-exposure baking was performed on a hotplate at 85° C. for 60 seconds.

Further, puddle development with 2.38 wt % tetramethylammonium hydroxide aqueous solution was performed for 60 seconds to eventually form a lattice-shaped pattern.

When the resulted first and second line and space patterns were observed using a scanning electron microscope, the second line and space pattern was formed with a good shape on the first line and space pattern and, in addition, the shape of the first line and space pattern was retained. It was confirmed that overall, a good pattern was formed. Further, the shape of the cross-section thereof was also good.

### Example 2

A composition for an organic antireflective film, “ARC-29A-8”, manufactured by Brewer Co. Ltd., was applied onto silicon wafers and baked for 60 seconds at 205° C. to form a 78 nm thick organic antireflective film. The resist liquid in which the resist composition shown in Example 2 of Table 1 was dissolved in the PMSG solvent 1 described above was spin-coated thereon as the first resist composition so that the thickness of the resulted film became 0.09 μm after drying.

Thereafter, 60 seconds of pre-baking at 105° C. was performed on a direct hot plate.

The whole surface of the obtained resist film on each wafer was exposed at the exposure amount of 3.0 mJ/cm² by using an ArF excimer stepper (“FPA5000-AS3” manufactured by Canon: NA=0.75, 2/3 Annular). Then, a pattern was exposed on the obtained resist film at the exposure amount of 18 mJ/cm² by using an ArF excimer stepper (“FPA5000-AS3” manufactured by Canon: NA=0.75, 2/3 Annular) and a mask having 1:1 line and space patterns having a line width of 85 nm.

Then, post-exposure baking was performed on a hotplate at 105° C. for 60 seconds.

Further, puddle development with 2.38 wt % tetramethylammonium hydroxide aqueous solution was performed for 60 seconds to form a desired pattern.

Then, hard-baking was performed for 60 seconds at 155° C., and then for 60 seconds at 170° C.

When the resulted first line and space pattern was observed using a scanning electron microscope, it was confirmed that a good and precise pattern was formed.

A second line and space pattern is formed substantially in the same manner as in the Example 1 on the first line and space pattern.

### Example 3

A composition for an organic antireflective film, “ARC-29A-8”, manufactured by Brewer Co. Ltd., was applied onto silicon wafers and baked for 60 seconds at 205° C. to form a 78 nm thick organic antireflective film The resist liquid in which the resist composition shown in Example 3 of Table 1 was dissolved in the PMEG solvent 1 described above was spin-coated thereon as the first resist composition so that the thickness of the resulted film became 0.09 μm after drying.

Thereafter, 60 seconds of pre-baking at 105° C. was performed on a direct hot plate.

The whole surface of the obtained resist film on each wafer was exposed at the exposure amount of 3.0 mJ/cm² by using an ArF excimer stepper (“FPA5000-AS3” manufactured by Canon: NA=0.75, 2/3 Annular). Then, a pattern was exposed on the obtained resist film at the exposure amount of 16 mJ/cm² by using an ArF excimer stepper (“FPA5000-AS3” manufactured by Canon: NA=0.75, 2/3 Annular) and a mask having 1:1 line and space patterns having a line width of 85 nm.

Then, post-exposure baking was performed on a hotplate at 105° C. for 60 seconds.

Further, puddle development with 2.38 wt % tetramethylammonium hydroxide aqueous solution was performed for 60 seconds to form a desired pattern.

Then, hard-baking was performed for 60 seconds at 155° C., and then for 60 seconds at 170° C.

When the resulted first line and space pattern was observed using a scanning electron microscope, it was confirmed that a good and precise pattern was formed.

A second line and space pattern is formed substantially in the same manner as in the Example 1 on the first line and space pattern.

### Comparative Example 1

A composition for an organic antireflective film, “ARC-29A-8”, manufactured by Brewer Co. Ltd., was applied onto silicon wafers and baked for 60 seconds at 205° C. to form a 78 nm thick organic antireflective film. The resist liquid in which the resist composition shown in Comparative Example 1 of Table 1 was dissolved in the PMEG solvent 1 described above was spin-coated thereon as the first resist composition so that the thickness of the resulted film became 0.09 μm after drying.

Thereafter, 60 seconds of pre-baking at 105° C. was performed on a direct hot plate.

The whole surface of the obtained resist film on each wafer was exposed at the exposure amount of 3.0 mJ/cm² by using an ArF excimer stepper (“FPA5000-AS3” manufactured by Canon: NA=0.75, 2/3 Annular). Then, a pattern was exposed on the obtained resist film at the exposure amount of 20 mJ/cm² by using an ArF excimer stepper (“FPA5000-AS3” manufactured by Canon: NA=0.75, 2/3 Annular) and a mask having 1:1 line and space patterns having a line width of 85 nm.

Then, post-exposure baking was performed on a hotplate at 105° C. for 60 seconds.

Further, puddle development with 2.38 wt % tetramethylammonium hydroxide aqueous solution was performed for 60 seconds to form a desired pattern.

Then, hard-baking was performed for 60 seconds at 155° C., and then for 60 seconds at 170° C.

When the resulted first line and space pattern was observed using a scanning electron microscope, it was confirmed that a good and precise pattern was formed.

A second line and space pattern is formed substantially in the same manner as in the Example 1 on the first line and space pattern.

(First Line and Space Patterns Evaluation of Example 2, 3 and Comparative Example 1)

The wafer after forming first line and space patterns is treated using 3.75 cc of a mixture solution with 3:7 of propylene glycol monomethyl ether:propylene glycol monomethyl ether acetate while rotating wafer with revolution speed of 1000 rpm.

Pattern of Example 2

No reducing thickness was observed, and no erosion pattern due to dissolution by the above mixture solution was observed on the surface of the resist film.

Pattern of Example 3

No reducing thickness was observed, and no erosion pattern due to dissolution by the above mixture solution was observed on the surface of the resist film.

Pattern of Comparative Example 1

Reducing thickness was observed, and erosion radial pattern due to dissolution by the above mixture solution was observed on the surface of the wafer.

### INDUSTRIAL APPLICABILITY

According to the resist processing method of the present invention, an extremely fine and highly accurate resist pattern can be formed which is obtained using the resist composition for forming a first resist pattern in a multi-patterning method or a multi-imaging method such as a double patterning method, double imaging method.

1. A resist processing method comprising the steps of:
(1) forming a first resist film by applying a first resist composition comprising:
a resin (A) having an acid-labile group, being insoluble or poorly soluble in alkali aqueous solution, and being rendered soluble in alkali aqueous solution through the action of an acid,
a photo acid generator (B),
a cross-linking agent (C) and
an acid amplifier (D)
onto a substrate and drying;
(2) prebaking the first resist film;
(3) exposing to the first resist film;
(4) post-exposure baking of the first resist film;
(5) developing with a first alkali developer to obtain a first resist pattern;
(6) hard-baking the first resist pattern,
(7) obtaining a second resist film by applying a second resist composition onto the first resist pattern, and drying;
(8) pre-baking the second resist film;
(9) exposing the second resist film;
(10) post-exposure baking the second resist film; and
(11) developing with a second alkali developer to obtain a second resist pattern.

2. The resist processing method according to claim 1, wherein the cross-linking agent (C) is at least one selected from the group consisting of a urea cross-linking agent, an alkylene urea cross-linking agent and a glycoluril cross-linking agent.

3. The resist processing method according to claim 1, wherein the content of the cross-linking agent (C) is 0.5 to 30 parts by weight relative to 100 parts by weight of the resin.

4. The resist processing method according to claim 1, wherein the acid-labile group of the resin (A) is a group having an alkyl ester group or lactone ring, in which a carbon atom that bonds to an oxygen atom of —COO— is a quaternary carbon atom, or a group having a carboxylate.

5. The resist processing method according to claim 1, wherein the photo acid generator (B) is a compound represented by the formula (I). 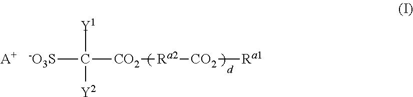
wherein, R^{a1} and R^{a2} independently represent a C₁ to C₃₀ linear or branched chain, or cyclic hydrocarbon, a 5 to 9 member heterocyclic group containing oxygen atom, or a group —R^{a1′}—O—R^{a2′}— (here, R^{a1′} and R^{a2′} independently represent a C₁ to C₂₉ linear or branched chain, or cyclic hydrocarbon, a 5 to 9 member heterocyclic group containing oxygen atom), the R^{a1}, R^{a2}, R^{a1′} and R^{a2′} may be substituted with at least one selected from the group consisting of an oxo group, a C₁ to C₆ alkyl group, a C₁ to C₆ alkoxy group, a C₁ to C₄ perfluoroalkyl group, a C₁ to C₆ hydroxylalkyl group, a hydroxy group and a cyano group;
A⁺ represents an organic counter ion;
Y¹ and Y² independently represent a fluorine atom or a C₁ to C₆ perfluoroalkyl group;
d represents 0 or an integer of 1.

6. The resist processing method according to claim 1, wherein the photo acid generator (B) is a compound represented by the formula (V) or the formula (VI). 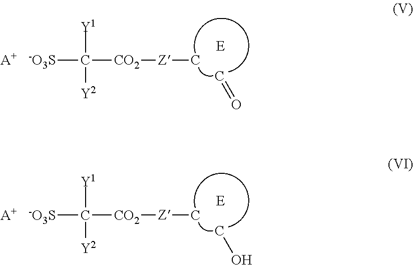
wherein a ring E represents an C₃ to C₃₀ cyclic hydrocarbon group, the ring E may be substituted with at least one selected from the group consisting of a C₁ to C₆ alkyl group, a C₁ to C₆ alkoxy group, a C₁ to C₄ perfluoroalkyl group, a C₁ to C₆ hydroxyalkyl group, a hydroxy group and a cyano group;
Z′ represents a single bond or a C₁ to C₄ alkylene group;
A⁺, Y¹ and Y² have the same meaning as defined above.

7. The resist processing method according to claim 1, wherein the photo acid generator (B) is a compound containing one or more cations selected from the group consisting of the formulae (IIa), (IIb), (IIc), (IId) and (IV). 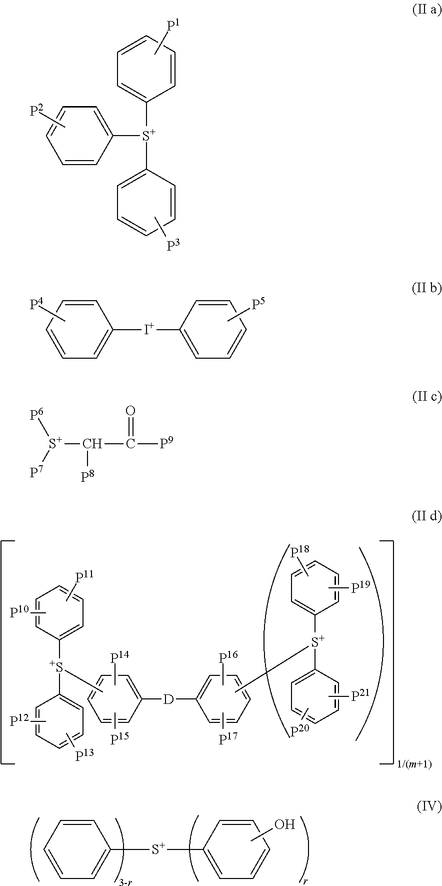
wherein P¹ to P⁵ and P¹⁰ to P²¹ independently represent a hydrogen atom, a hydroxy group, a C₁ to C₁₂ alkyl group or a C₁ to C₁₂ alkoxy group;
P⁶ and P⁷ independently represent a C₁ to C₁₂ alkyl group or a C₃ to C₁₂ cycloalkyl group, or P⁶ and P⁷ are bonded to form a C₃ to C₁₂ divalent hydrocarbon group;
P⁸ represents a hydrogen atom;
P⁹ represents a C₁ to C₁₂ alkyl group, a C₃ to C₁₂ cycloalkyl group or an optionally substituted aromatic group, or P⁸ and P⁹ are bonded to form a C₃ to C₁₂ divalent hydrocarbon group;
D represents a sulfur atom or an oxygen atom;
m represents 0 or 1;
r represents an integer of 1 to 3.

8. The resist processing method of according to claim 1, wherein the acid amplifier (D) is a compound represented by the formula (D1) or the formula (D2). 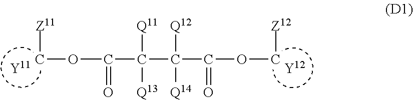
wherein Z¹¹ and Z¹² independently represent a hydrogen atom, a C₁ to C₁₂ alkyl group or a C₃ to C₁₂ cycloalkyl group, provided that at least one of Z¹¹ and Z¹² represent a C₁ to C₁₂ alkyl group or a C₃ to C₁₂ cycloalkyl group;
ring Y¹¹ and ring Y² independently represents an optionally substituted C₃ to C₂₀ alicyclic hydrocarbon group; and
Q¹¹, Q¹², Q¹³ and Q¹⁴ independently represent a fluorine atom or a C₁ to C₆ perfluoroalkyl group; 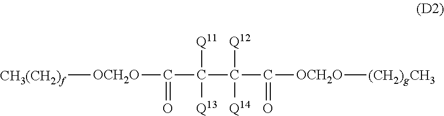
wherein Q¹¹, Q¹², Q¹³ and Q¹⁴ have the same meaning as defined above; and
f and g independently represent an integer of 0 to 5.

9. The resist processing method according to claim 1, wherein the first resist composition further comprised a thermal acid generator.
